(19) United States
(12) Patent Application Publication
(10) Pub. No.: US 2026/0182239 A1
(43) Pub. Date: Jun. 25, 2026

(54) STABILIZED PEROVSKITE STRUCTURE, ITS PREPARATION AND USE IN SOLAR CELL

(71) Applicant: City University of Hong Kong, Kowloon (HK)

(72) Inventors: Alex Kwan Yue Jen, Kowloon (HK); Xiaofeng Huang, Kowloon (HK)

(21) Appl. No.: 19/388,082

(22) Filed: Nov. 13, 2025

Related U.S. Application Data
(60) Provisional application No. 63/737,927, filed on Dec. 23, 2024.

(51) Int. Cl. H10K 85/50; H10K 30/40; H10K 30/84; H10K 85/10; H10K 85/20; H10K 85/60

(52) U.S. Cl. CPC H10K 85/50; H10K 30/40; H10K 85/113; H10K 85/115; H10K 85/151; H10K 85/211; H10K 85/657; H10K 85/6572; H10K 30/84

(57) ABSTRACT

A stabilized perovskite-containing structure for use as a photoactive layer in a solar cell includes a halide perovskite structure and a polyoxometalate (POM) cluster arranged to stabilize the halide perovskite structure. The method for preparing the stabilized perovskite-containing structure and the use of the stabilized perovskite-containing structure are also addressed.

### TECHNICAL FIELD

The present invention relates to a stabilized perovskite-containing structure, for example, particularly, but not exclusively, a stabilized perovskite-containing structure comprising a halide perovskite structure and a polyoxometalate (POM) cluster that includes an ammonium compound for use as a photoactive layer in solar cells. The present invention also relates to the preparation of the stabilized perovskite-containing structure and the use of said structure in solar cells.

### BACKGROUND OF THE INVENTION

It is believed that metal halide perovskite has garnered significant research attention as a promising light-absorbing material for energy conversion. Reports on related applications may include single-junction, all-perovskite tandem, perovskite-organic tandem, silicon-perovskite tandem solar cells and the like. The wide application of the metal halide perovskite may be attributed to its defect tolerance (corner-shared [PbI₆]⁴⁻ octahedral unit) and its unique band structures. It is believed that the bandgaps of perovskites derive from their antibonding orbitals at both the valence band maximum (VBM) and conduction band minimum (CBM). Consequently, breaking these bonds produces states away from the bandgap, resulting in either shallow defects or states within the valence band. Although high defect tolerance may allow polycrystalline perovskite films to have 10⁶ times higher defect densities than the single-crystal silicon while achieving comparable device performance, high defect densities (e.g., antisites, interstitials, vacancies) may reduce the energy required for ion migration through the bulk and grain boundaries. It is believed that this will lead to defect propagation and irreversible degradation of the perovskite phase in long term.

The present invention thus seeks to eliminate or at least mitigate such shortcomings by providing a new or otherwise improved perovskite-containing structure for photovoltaics/perovskite solar cells (PSCs).

### SUMMARY OF THE INVENTION

In a first aspect of the present invention, there is provided a stabilized perovskite-containing structure for use as a photoactive layer in a solar cell comprising a halide perovskite structure and a polyoxometalate (POM) cluster arranged to stabilize the halide perovskite structure; wherein the POM cluster includes an ammonium compound having a formula selected from the group consisting of:

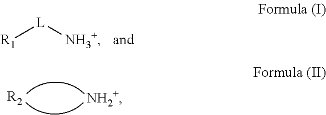

wherein: R₁ is selected from the group consisting of a hydrogen, an ammonium cation and a halogen; L is an aliphatic alkyl or an aromatic linker structure having 1 to 26 carbons; R₂ is selected from the group consisting of amine, substituted or unsubstituted methylene and nitrenium cation; and the ring in Formula (II) represents an aliphatic 6-membraned to 8-membraned ring, including the R₂ and NH₂⁺.

Optionally, R₁ is selected from the group consisting of a hydrogen, an ammonium cation, F, Br, Cl, and I; L has a structure of

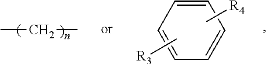

wherein R₃ and R₄ each independently being a point of attachment for R₁ or NH₃⁺, and each of the R₃ and R₄ has a structure of

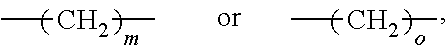

and wherein n is an integer of 1 to 12, m and o each independently being an integer of 0 to 12; R₂ is selected from the group consisting of amine and nitrenium cation; and the ring in Formula (II) represents an aliphatic 6-membraned ring, including the substituent R₂ and NH₂⁺.

It is optional that the ammonium compound has a formula selected from the group consisting of:

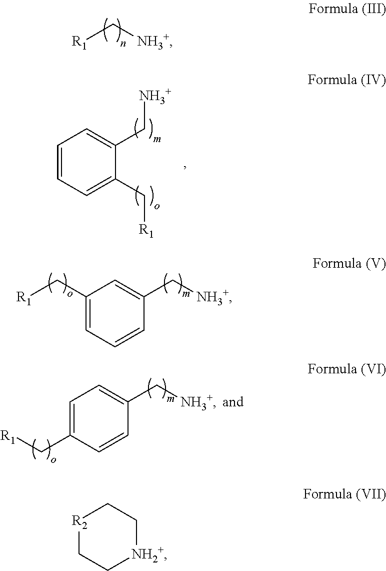

wherein: R₁ is selected from the group consisting of a hydrogen, an ammonium cation, F, Br, Cl, and I; n is an integer of 1 to 10; m and o each independently being an integer of 0 to 10; and R₂ is selected from the group consisting of amine and nitrenium cation.

In an optional embodiment, the ammonium compound is selected from the group consisting of:

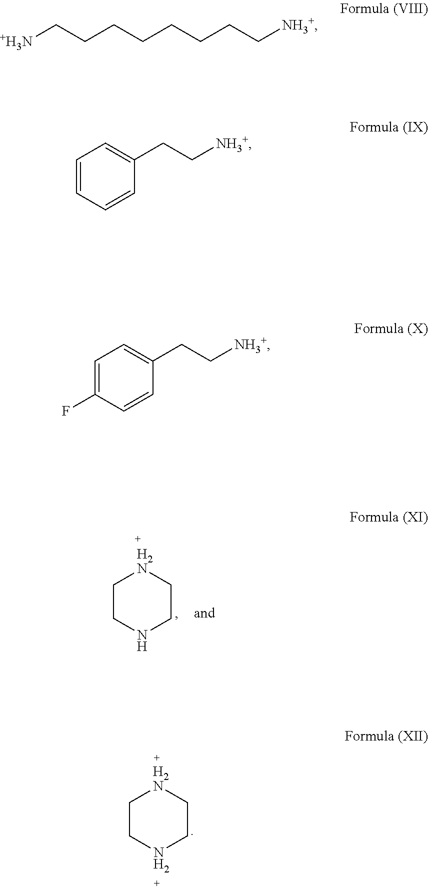

Optionally, the POM cluster is a Keggin-type POM or a Dawson-type POM.

It is optional that the Keggin-type POM has a formula of (X)ₐ(YMₙM′₁₂₋ₙO₄₀)^{b}, and wherein X is a cation with a charge of +1 or +2 and is selected from one or more of the ammonium compound of Formula (VIII) to Formula (XII), or a combination of H⁺ and one or more of the ammonium compound of Formula (VIII) to Formula (XII); a is a positive integer of 2 to 4, b is a negative integer of (−2) to (−4), and a+b=0; Y is selected from the group consisting of Si and P; M and M′ are selected from the group consisting of W and Mo; and n is 0-12.

Optionally, the Dawson-type POM has a formula of (X)_{c}(Y₂M_{n′}M′_{18-n′}O₆₂)^{d}, and wherein X is a cation with a charge of +1 or +2 and is selected from one or more of the ammonium compound of Formula (VIII) to Formula (XII), or a combination of H⁺ and one or more of the ammonium compound of Formula (VIII) to Formula (XII); c is a positive integer of 3 to 8, b is a negative integer of (−3) to (−8), and a+b=0; Y is selected from the group consisting of Si and P; M and M′ are selected from the group consisting of W and Mo; and n′ is 0-18.

It is optional that the Keggin-type POM has a formula of (X)₃(PW₁₂O₄₀)³⁻ or (X)₄(SiW₁₂O₄₀)⁴⁻, and wherein X is a cation with a charge of +1 or +2 and is selected from one or more of the ammonium compound of Formula (VIII) to Formula (XII), or a combination of H⁺ and one or more of the ammonium compound of Formula (VIII) to Formula (XII).

In an optional embodiment, the Keggin-type POM has a formula selected from the group consisting of (PP)₃PW₁₂O₄₀, H(PPD)PW₁₂O₄₀, (PEA)₃PW₁₂O₄₀, (4F-PEA)₃PW₁₂O₄₀, H(ODA)PW₁₂O₄₀, and (PPD)₂SiW₁₂O₄₀.

Optionally, the halide perovskite structure has a general formula of ABZ₃, with A being an A-site monovalent cation, B being a B-site divalent cation, and Z being a halide anion.

It is optional that the A-site monovalent cation is selected from the group consisting of formamidinium (FA⁺), methylammonium (MA⁺), ethylammonium (EA⁺), guanidinium (GA⁺), Cs⁺, Rb⁺ and a combination thereof, the B-site divalent cation is selected from the group consisting of Pb²⁺, Sn²⁺, Ge²⁺ and a combination thereof, and the halide anion is selected from the group consisting of I⁻, Br⁻, Cl⁻ and a combination thereof.

In an optional embodiment, the halide perovskite structure has a formula selected from Cs_{0.05}FA_{0.95}PbI₃ and FA_{0.8}MA_{0.1}Cs_{0.1}Pb(I_{0.6}Br_{0.4})₃.

Optionally, the stabilized perovskite-containing structure comprises about 0.1 mg/mL to about 0.7 mg/mL of the POM cluster.

It is optional that the stabilized perovskite-containing structure comprises about 0.01 mol % to about 0.03 mol % of the POM cluster.

In an optional embodiment, the halide perovskite structure and the POM cluster are separated by an interlayer.

Optionally, the POM cluster is adapted to form the interlayer by way of interaction with the halide perovskite structure.

It is optional that the POM cluster is a layer in direct contact with a layer of the halide perovskite structure and the interlayer is located therebetween.

In an optional embodiment, the POM cluster is distributed within the layer of the halide perovskite structure.

In a second aspect of the present invention, there is provided a method for preparing the stabilized perovskite-containing structure in accordance with the first aspect, comprising the steps of: (a) providing a first solution containing a POM cluster including an ammonium compound having a formula selected from the group consisting of:

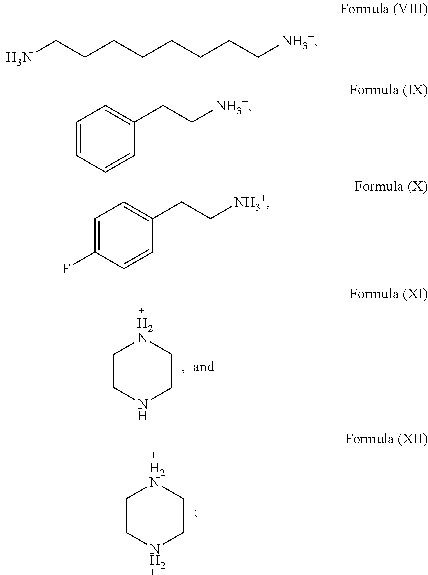

(b) providing a halide perovskite precursor solution comprising halides of formamidinium, methylammonium, cesium, and lead; (c) spin-coating the first solution and the halide perovskite precursor solution on a substrate; and (d) annealing the spin-coated solutions to form the stabilized perovskite-containing structure.

Optionally, step (a) is carried out by cation substitution of a precursor POM cluster with an ammonium salt corresponding to the ammonium compound.

In an optional embodiment, the precursor POM cluster is selected from H₃PW₁₂O₄₀ and H₄SiW₁₂O₄₀.

It is optional that the ammonium salt is selected from the group consisting of PI, PDAI₂, PEAI, 4F-PEAI, and ODAI₂.

Optionally, the precursor POM cluster and the ammonium salt have a molar ratio from about 1:1 to about 1:4.

In an optional embodiment, the precursor POM cluster is H₃PW₁₂O₄₀ and it has a molar ratio with the ammonium salt from about 1:1 to about 1:3.

Optionally, the precursor POM cluster is H₄SiW₁₂O₄₀ and it has a molar ratio with the ammonium salt from about 1:2 to about 1:4.

It is optional that the first solution contains about 0.05 mg/mL to about 5 mg/mL of the POM cluster.

In an optional embodiment, the halides in step (b) comprise CsI, FAI, MAI, PbI₂, and PbBr₂, and are provided in accordance with a formula Cs_{0.05}FA_{0.95}PbI₃ or FA_{0.8}MA_{0.1}Cs_{0.1}Pb(I_{0.6}Br_{0.4})₃.

It is optional that the first solution and the halide perovskite precursor solution in step (c) are sequentially spin-coated on the substrate.

Optionally, step (d) is carried out after the first solution is spin-coated on the substrate, and after the halide perovskite precursor solution is spin-coated on the annealed substrate with the spin-coated first solution.

In a third aspect of the present invention, there is provided with a solar cell comprising: a hole transport layer; an electron transport layer; and a stabilized perovskite-containing structure disposed between the hole transport layer and the electron transport layer; wherein the stabilized perovskite-containing structure includes a halide perovskite structure; and a polyoxometalate (POM) cluster which includes an ammonium compound having a formula selected from the group consisting of:

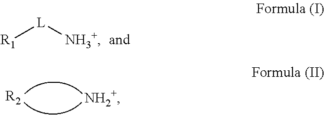

wherein: R₁ is selected from the group consisting of a hydrogen, an ammonium cation and a halogen; L is an aliphatic alkyl or an aromatic linker structure having 1 to 26 carbons; R₂ is selected from the group consisting of amine, substituted or unsubstituted methylene and nitrenium cation; the ring in Formula (II) represents an aliphatic 6-membraned to 8-membraned ring, including the R₂ and NH₂⁺.

Optionally, the POM cluster is disposed between the halide perovskite structure and the hole transport layer.

In an optional embodiment, the stabilized perovskite-containing structure comprises the POM cluster dispersed within the halide perovskite structure, the stabilized perovskite-containing structure is disposed on the hole transport layer.

Optionally, the hole transport layer is in contact with an additional POM cluster, said additional POM cluster is in the form of a layer disposed between the stabilized perovskite-containing structure and the hole transport layer.

Optionally, the solar cell further comprises a transparent conductive layer in contact with both a transparent substrate and the hole transport layer; a metal layer and a blocking layer arranged sequentially with the electron transport layer.

Optionally, the transparent substrate is selected from the group consisting of glass, PC (polycarbonate), PET (polyethylene glycol terephthalate), PEN (polyethylene naphthalate), PA (polyamide), PMMA (polymethyl methacrylate), PS (polystyrene), ABS (acrylonitrile butadiene styrene copolymer), PDMS (polydimethylsiloxane), and a combination thereof.

It is optional that the transparent conductive layer is selected from the group consisting of Indium Tin Oxide (ITO), Aluminum Zinc Oxide (AZO), graphene, PH1000 poly(3,4-ethylenedioxythiophene):poly(styrene sulfonate) (PH1000 PEDOT:PSS), Ag nanowire and a combination thereof.

Optionally, the hole transport layer is a self-assembled monolayer (SAM) of CbzNaph or Me-4PACZ.

It is optional that the electron transport layer is selected from the group consisting of C₆₀, and its derivatives such as PCBM ([6,6]-phenyl-C61-butyric acid methyl ester) and ICBA (indene-C60 bisadduct); the blocking layer is selected from bathocuproine (BCP), SnO₂, and MoOₓ.

It is optional that the metal layer is selected from the group consisting of Ag, Cu, Au, Al, Pt and a combination thereof.

Optionally, the solar cell further comprises an anti-reflection layer in contact with the transparent substrate.

It is optional that the anti-reflection layer comprises MgF₂.

In an optional embodiment, the solar cell is configured as a subcell that is arranged in contact with an additional subcell, thereby forming a tandem structure. Optionally, the additional subcell is in contact with the metal layer of the subcell.

Optionally, the additional subcell comprises: a hole transport layer; an electron transport layer; and an organic photovoltaic material disposed between the hole transport layer and the electron transport layer of the additional subcell.

It is optional that the hole transport layer of the additional subcell is in contact with an additional POM cluster.

Optionally, the additional POM cluster comprises H₃PW₁₂O₄₀.

It is optional that the organic photovoltaic material comprises PM6:BTP-eC9; the electron transport layer comprises PNDIT-F3N.

Optionally, the hole transport layer is disposed on a blocking layer in the additional subcell.

It is optional that the blocking layer in the subcell is in contact with the metal layer.

In an optional embodiment, the subcell and the additional subcell has a bandgap of about 1.78 eV and about 1.38 eV, respectively.

In an optional embodiment, the solar cell is a perovskite-organic tandem solar cell.

### BRIEF DESCRIPTION OF DRAWINGS

The patent or application file contains at least one drawing executed in color. Copies of this patent or patent application publication with color drawing(s) will be provided by the Office upon request and payment of the necessary fee.

The invention will now be more particularly described, by way of example only, with reference to the accompanying drawings, in which:

FIG. 1A is a schematic diagram illustrating the Keggin structure of a polyoxometalate (POM) cluster in accordance with an embodiment of the present invention;

FIG. 1B is a schematic diagram illustrating the Dawson structure of a polyoxometalate (POM) cluster in accordance with an embodiment of the present invention;

FIG. 2A is a schematic diagram illustrating the cross-section view of a perovskite solar cell in accordance with an embodiment of the present invention;

FIG. 2B is a schematic diagram illustrating the cross-section view of a perovskite solar cell in accordance with another embodiment of the present invention;

FIG. 2C is a schematic diagram illustrating the cross-section view of a perovskite-organic tandem solar cell in accordance with an embodiment of the present invention;

FIG. 2D is a schematic diagram illustrating the cross-section view of a perovskite-organic tandem solar cell in accordance with another embodiment of the present invention;

FIG. 3 shows the functional POMs designed to stabilize the perovskite structure;

FIG. 4A shows the XRD patterns of H₃PW₁₂O₄₀ powder;

FIG. 4B shows the XRD patterns of H₃PW₆Mo₆O₄₀;

FIG. 4C shows the XRD patterns of H₃PMo₁₂O₄₀;

FIG. 5A shows the cyclic voltammetry curves of H₃PW₁₂O₄₀;

FIG. 5B shows the cyclic voltammetry curves of H₃PW₆Mo₆O₄₀;

FIG. 5C shows the cyclic voltammetry curves of H₃PMo₁₂O₄₀;

FIG. 6 shows the standard electrode potential of POMs, Pb⁰/Pb²⁺ and I⁰/I⁻;

FIG. 7 shows the POM-involved electron shuttling process between Pb⁰ and I⁰;

FIG. 8A shows the XRD pattern of PbI₂ powders. The undefined peaks below 12.7° were attributed to the adducts formed from the reaction between PbI₂ and DMF. The higher crystallinity PbI₂ and PbI₂-solvated adducts indicated a facilitated electron transfer reaction with the addition of POM mediator;

FIG. 8B shows the XRD pattern of the reaction products from electron shuttling reaction of Pb⁰ and I⁰ without POM(W) addition. H-terminated POMs were used; The undefined peaks below 12.7° were attributed to the adducts formed from the reaction between PbI₂ and DMF. The higher crystallinity PbI₂ and PbI₂-solvated adducts indicated a facilitated electron transfer reaction with the addition of POM mediator.

FIG. 8C shows the XRD pattern of the reaction products from electron shuttling reaction of Pb⁰ and I⁰ with POM(W) addition. H-terminated POMs were used; The undefined peaks below 12.7° were attributed to the adducts formed from the reaction between PbI₂ and DMF. The higher crystallinity PbI₂ and PbI₂-solvated adducts indicated a facilitated electron transfer reaction with the addition of POM mediator.

FIG. 9A shows the XRD patterns of POM powders with different ammonium cations: PP⁺;

FIG. 9B shows the XRD patterns of POM powders with different ammonium cations: PPD²⁺;

FIG. 9C shows the XRD patterns of POM powders with different ammonium cations: PEA⁺;

FIG. 9D shows the XRD patterns of POM powders with different ammonium cations: 4F-PEA⁺;

FIG. 9E shows the XRD patterns of POM powders with different ammonium cations: DA²⁺;

FIG. 10 shows the PLQY of perovskite films deposited on glass/SAM and glass/SAM/POM substrates;

FIG. 11 is a schematic diagram illustrating the POM-passivated buried surface in perovskite films;

FIG. 12 shows the binding energy of POM on FAI-rich (100) and PbI₂-rich (100) surfaces, along with optimized structures of FAI-rich (100) and PbI₂-rich (100) slabs;

FIG. 13A shows the high resolution XPS spectra of Pb 4f in the perovskite buried films before illumination aging (AM 1.5G, 100 mW cm⁻²) were obtained from ITO/SAM/perovskite. H-terminated POMs were used;

FIG. 13B shows the high resolution XPS spectra of Pb 4f in the perovskite buried films before illumination aging (AM 1.5G, 100 mW cm⁻²) were obtained from ITO/SAM/POM(W)/perovskite. H-terminated POMs were used;

FIG. 13C shows the high resolution XPS spectra of Pb 4f in the perovskite buried films before illumination aging (AM 1.5G, 100 mW cm⁻²) were obtained from ITO/SAM/POM(W/Mo)/perovskite. H-terminated POMs were used;

FIG. 13D shows the high resolution XPS spectra of Pb 4f in the perovskite buried films before illumination aging (AM 1.5G, 100 mW cm⁻²) were obtained from ITO/SAM/POM(Mo)/perovskite samples. H-terminated POMs were used;

FIG. 14A shows the high resolution XPS spectra of Pb 4f in the perovskite buried films after illumination aging (AM 1.5G, 100 mW cm⁻²) were obtained from ITO/SAM/perovskite sample. The perovskite films were sealed in a 20 mL vial (filled with N₂) and illuminated for two days. H-terminated POMs were used;

FIG. 14B shows the high resolution XPS spectra of Pb 4f in the perovskite buried films after illumination aging (AM 1.5G, 100 mW cm⁻²) were obtained from ITO/SAM/POM(W)/perovskite sample. The perovskite films were sealed in a 20 mL vial (filled with N₂) and illuminated for two days. H-terminated POMs were used;

FIG. 14C shows the high resolution XPS spectra of Pb 4f in the perovskite buried films after illumination aging (AM 1.5G, 100 mW cm⁻²) were obtained from ITO/SAM/POM(W/Mo)/perovskite sample. The perovskite films were sealed in a 20 mL vial (filled with N₂) and illuminated for two days. H-terminated POMs were used;

FIG. 14D shows the high resolution XPS spectra of Pb 4f in the perovskite buried films after illumination aging (AM 1.5G, 100 mW cm⁻²) were obtained from ITO/SAM/POM(Mo)/perovskite sample. The perovskite films were sealed in a 20 mL vial (filled with N₂) and illuminated for two days. H-terminated POMs were used;

FIG. 15 shows the atomic ratio of metallic Pb⁰ in the total Pb element of aged perovskite films;

FIG. 16 shows the calculated AG of POM-mediated electron shuttling involving Pb⁰ and I⁰;

FIG. 17 shows the half reactions are presented as follows. For the POM-free case: Pb⁰→Pb²⁺; I⁰→I⁻. For the POM-mediated case: Pb⁰+2POM³⁻→Pb²⁺+2POM⁴⁻; I⁰+2POM⁴⁻→I⁻+2POM³⁻;

FIG. 18 is a table summarizing the calculated formation energy of half reaction;

FIG. 19 shows the UV-vis spectra were recorded for the time-dependent I₂ species in the reaction solution of Pb⁰ and I₂ powders, both with and without POM involvement;

FIG. 20 shows the UV-Vis spectra of I₂, Pb⁰, and PbI₂ in mixed DMF/IPA solvent (volume ratio 10:1);

FIG. 21A shows the UV-Vis spectra obtained for Pb⁰+I₂ solution at different reaction times;

FIG. 21B shows the UV-Vis spectra obtained for Pb⁰+I₂+POM(W) solution at different reaction times;

FIG. 21C shows the UV-Vis spectra obtained for Pb⁰+I₂+POM(W/Mo) solution; at different reaction times FIG. 21D shows the UV-Vis spectra obtained for Pb⁰+I₂+POM(Mo) solution at different reaction times;

FIG. 21E shows the intensity decay of I₂ species (366 nm) as a function of reaction time was analyzed for Pb⁰+I₂ solution. The a value was determined by extracting the slope of the graph plotted on a semi-logarithmic scale (lnI₁₀ vs. Time);

FIG. 21F shows the intensity decay of I₂ species (366 nm) as a function of reaction time was analyzed for Pb⁰+I₂+POM(W) solution. The α value was determined by extracting the slope of the graph plotted on a semi-logarithmic scale (lnI₁₀ vs. Time);

FIG. 21G shows the intensity decay of I₂ species (366 nm) as a function of reaction time was analyzed for Pb⁰+I₂+POM(W/Mo) solution. The α value was determined by extracting the slope of the graph plotted on a semi-logarithmic scale (lnI₁₀ vs. Time);

FIG. 21H shows the intensity decay of I₂ species (366 nm) as a function of reaction time was analyzed for Pb⁰+I₂+POM(Mo) solution. The α value was determined by extracting the slope of the graph plotted on a semi-logarithmic scale (lnI₁₀ vs. Time);

FIG. 22 shows the calculated reaction kinetics between Pb⁰ and I₂;

FIG. 23 shows the physical images of POM(W)- and POM(Mo)-involved Pb⁰ oxidation processes. The solutions were stirred at room temperature. In this experiment, POM and Pb⁰ powders were first dispersed in a DMF solution, and then the stirred solution was recorded. Due to the rapid reaction kinetics between Pb⁰ and POM, the addition of DMF accelerated the reaction, causing the solution to appear slightly blue. Notably, POM(Mo) is a yellow powder, while POM(W) is white, which explains the slight yellowish tint in the POM(Mo) solution. After the reaction, both reduced metal ions exhibited a blue color, indicating the swift reduction of Pb⁰ species upon the addition of POMs;

FIG. 24 is a table summarizing the calculated binding energy between Pb⁰ and POM;

FIG. 25A shows the UV-Vis spectra for Pb⁰+POM(W) solution with addition of I₂ powders;

FIG. 25B shows the UV-Vis spectra for Pb⁰+POM(Mo) solution with addition of I₂ powders;

FIG. 25C shows the UV-vis spectra recorded for the time-dependent I₂ species in the reaction solution of Pb⁰ and I₂ with POM(W) involvement;

FIG. 25D shows the UV-vis spectra recorded for the time-dependent I₂ species in the reaction solution of Pb⁰ and I₂ with POM(Mo) involvement;

FIG. 25E shows the intensity decay of I₂ species (366 nm) as a function of reaction time of the reaction solution of Pb⁰ and I₂ with POM(W) involvement;

FIG. 25F shows the intensity decay of I₂ species (366 nm) as a function of reaction time of the reaction solution of Pb⁰ and I₂ with POM(Mo) involvement;

FIG. 26A shows the In-situ PL spectra for ITO/SAM/perovskite (left) and ITO/SAM/POM/perovskite (right) films during continuous laser illumination. The incident laser directed from the glass side;

FIG. 26B shows the time evolution of the maximum PL peak. The incident laser directed from the glass side;

FIG. 26C shows the In-situ PL spectra for ITO/SAM/perovskite (left) and ITO/SAM/POM/perovskite (right) films under continuous laser illumination and 85° C. heating. The incident laser directed from the glass side;

FIG. 26D shows the time evolution of the maximum PL peak. The incident laser directed from the glass side;

FIG. 27 shows the In-situ PL spectra of ITO/SAM/perovskite (left) and ITO/SAM/POM/perovskite (right) films. Perovskite component with 1.78-eV bandgap was utilized, with the incident laser directed from the glass side;

FIG. 28A shows the high resolution XPS spectra of Pb 4f in the wide bandgap perovskite buried films after illumination aging (AM 1.5G, 100 mW cm⁻²) obtained from ITO/SAM/perovskite. The perovskite films were sealed in a 20 mL vial (filled with N₂) and illuminated for two days. H-terminated POMs were used;

FIG. 28B shows the high resolution XPS spectra of Pb 4f in the wide bandgap perovskite buried films after illumination aging (AM 1.5G, 100 mW cm⁻²) obtained from ITO/SAM/POM(W)/perovskite. The perovskite films were sealed in a 20 mL vial (filled with N₂) and illuminated for two days. H-terminated POMs were used;

FIG. 28C shows the atomic ratio of metallic Pb⁰ in the total Pb element of aged perovskite films. The perovskite films were sealed in a 20 mL vial (filled with N₂) and illuminated for two days. H-terminated POMs were used;

FIG. 29 is a schematic diagram of POM-mediated electron shuttling process and guidance of selecting suitable redox mediator;

FIG. 30 shows the energy-dispersive X-ray spectroscopy (EDS) elemental mapping of Sn and P for SAM substrate (top row), and Sn, P, W for SAM/POM substrate (bottom row), respectively;

FIG. 31 show the dynamic light scattering measurement was conducted on a POM(PPD) solution with a concentration of 0.5 mg/mL;

FIG. 32 shows the ToF-SIMS analysis of ITO/SAM/PVK sample, where perovskite is denoted as PVK;

FIG. 33 shows the ToF-SIMS analysis of ITO/SAM/POM/PVK sample, where perovskite is denoted as PVK;

FIG. 34 shows the surface ToF-SIMS mapping of SAM signal (i.e., PO₃⁻) (left column) and POM signal (i.e., WO₃⁻) (right column). W-terminated POM with PPD²⁺ as counter cation was utilized;

FIG. 35 shows the contact angle measurement of ITO, ITO/SAM, ITO/SAM/POM, and ITO/POM substrates. The results of contact angle test revealed that the SAM substrate was more hydrophobic than the ITO substrate. Conversely, the ITO/POM substrate displayed hydrophilic properties, suggesting the presence of an intercalated pattern in SAM/POM substrate;

FIG. 36 shows the UPS spectra of ITO, ITO/SAM, ITO/SAM/POM, and ITO/POM substrates. Compared to ITO/SAM substrate, the SAM/POM substrate displayed an increased work function, further confirming the POM/SAM intercalated pattern;

FIG. 37 shows the comparison of PbI₂⁻ signal from ITO/SAM/PVK and ITO/SAM/POM/PVK samples;

FIG. 38 shows the cross-sectional ToF-SIMS mapping of InO₂⁻, PO₃⁻, WO₃⁻, and PbI₂⁻ signals in Control and POM samples;

FIG. 39A shows the ToF-SIMS analysis of ITO/SAM/POM(W/Mo)/PVK sample;

FIG. 39B shows the comparison of PbI₂⁻ signal from ITO/SAM/PVK and ITO/SAM/POM(W/Mo)/PVK samples;

FIG. 40 shows the XRD patterns of perovskite films deposited on POM/SAM substrates using different POM solutions;

FIG. 41 shows the high resolution XPS spectra of W 4f (left) and F is (right) of perovskite buried films, utilizing W-terminated POM with 4F-PEA⁺ as counter cation;

FIG. 42 shows the XRD patterns (left) and ¹H NMR spectra (right) of FAI, POM(4F-PEA), and the product formed by stirring FAI and POM(4F-PEA) powders in IPA;

FIG. 43 shows the XRD pattern of perovskite film with POM addition, utilizing W-terminated POM with PEA⁺ as counter cation;

FIG. 44 shows the preparation of perovskite buried films;

FIG. 45 shows the 2D GIWAXS patterns of perovskite buried films tested with different incident angles;

FIG. 46 shows the azimuthally integrated 1D plots along the out-of-plane directions;

FIG. 47 shows the top-surface SEM images of perovskite films grown from ITO/SAM and ITO/SAM/POM substrates (top row), and the cross-sectional SEM image of perovskite solar cells with POM/SAM as charge selective layer (bottom row);

FIG. 48A shows the UV-vis spectra of perovskite films deposited on various substrates; Eu for the perovskite films was calculated from UV-Vis absorption spectra using the equation a=a₀exp(hν/E_{U}), where a is the absorption coefficient and hv is photon energy. The lower Eu value of the perovskite film on the SAM/POM substrate demonstrated reduced energetic disorder at the band edge;

FIG. 48B shows the calculated Urbach energy. Eu for the perovskite films was calculated from UV-Vis absorption spectra using the equation a=a₀exp(hν/Eu), where a is the absorption coefficient and hv is photon energy. The lower Eu value of the perovskite film on the SAM/POM substrate demonstrated reduced energetic disorder at the band edge;

FIG. 48C shows the PL spectra of perovskite films deposited on different substrates;

FIG. 49 shows the PL mapping images of the top surface and the bottom surface in perovskite films deposited on ITO/SAM (left column) and ITO/SAM/POM (right column) substrates;

FIG. 50 shows the time-resolution photoluminescence spectra of perovskite films deposited on different substrates;

FIG. 51 shows the J-V curves for the hole-only devices with an ITO/SAM (with and without POM)/perovskite/PTAA/Ag structure;

FIG. 52 shows the J-V curves of POM-based PSCs with optimized concentrations. The POM with PPD²⁺ cation and W⁶⁺ as metal ion was chosen here.

FIG. 53 is a table summarizing the photovoltaic parameters of PSCs with SAM and SAM/POM substrates;

FIG. 54 shows the PCE statistics of PSCs;

FIG. 55 shows the MPP tracking of the POM-based PSCs with optimized concentrations;

FIG. 56 is a table summarizing the photovoltaic parameters of PSCs using various types of SAM and POM;

FIG. 57A shows the XRD patterns of H₄SiW₁₂O₄₀ and PPD₂SiW₁₂O₄₀ powders;

FIG. 57B shows the J-V curves of devices prepared with PPD₂SiW₁₂O₄₀ as POM layer;

FIG. 57C shows the J-V curves of devices prepared with Me-4PACZ as the SAM layer;

FIG. 58 shows the current-voltage (J-V) curves of the champion device;

FIG. 59 is a table summarizing the photovoltaic parameters of POM-based champion PSCs;

FIG. 60 is a table summarizing the normal-bandgap perovskite solar cells using redox mediator to stabilize perovskite layer;

FIG. 61 shows the EQE curves of the champion device (left) and the derivative of EQE curve identifying the perovskite bandgap at 1.55 eV (right);

FIG. 62 shows the J-V curves of perovskite solar modules;

FIG. 63 shows the certification result of a perovskite solar mini-module by the Shanghai Institute of Microsystem and Information Technology, Chinese Academy of Sciences (SIMIT);

FIG. 64A shows the J-V curves of devices prepared with POM added to the perovskite precursor solution;

FIG. 64B is a table summarizing the photovoltaic parameters of SAM/POM-based PSCs with POM additive;

FIG. 65A shows the intrinsic stability of unencapsulated devices aged at 65±5° C. in a N₂-filled glovebox;

FIG. 65B shows the maximum power point (MPP) tracking of encapsulated PSCs measured at 85° C. under LED illumination;

FIG. 66 shows the cross-sectional SEM images of aging devices using SAM (top row) and SAMIPOM (bottom row) substrates. The poor interfacial contact in the POM sample between the perovskite and the underlying substrate is attributed to the variations in sample preparation, specifically the manual cutting of the substrate, which resulted in partial peeling of the perovskite;

FIG. 67A shows the J-V curves of 1.68-eV PSCs;

FIG. 67B shows the EQE curves of the champion device;

FIG. 67C shows the derivative of EQE curve identifying the perovskite bandgap at 1.68 eV;

FIG. 68A shows the J-V curves of 1.78-eV PSCs;

FIG. 68B shows the EQE curves of the champion device;

FIG. 68C shows the derivative of EQE curve identifying the perovskite bandgap at 1.78 eV;

FIG. 69A shows the J-V curves of 1.38-eV OSCs;

FIG. 69B shows the EQE curves of the champion device;

FIG. 69C shows the derivative of EQE curve identifying the perovskite bandgap at 1.38 eV;

FIG. 70A is a schematic diagram illustrating the structure of the PO-TSC, along with the corresponding cross-sectional image. The interconnecting layer includes C₆₀, SnO₂, Au and MoOₓ. The scale bar is 1 μm;

FIG. 70B shows the J-V curves of champion PO-TSC;

FIG. 70C shows the EQE spectra of PSC and OSC in PO-TSC; and

FIG. 70D shows the continuous MPP tracking of the unencapsulated PO-TSC under simulated AM 1.5G illumination (100 mW cm⁻², without UV filter) in an N₂-filled glovebox without temperature control.

### DETAILED DESCRIPTION OF OPTIONAL EMBODIMENT

As used herein, the forms “a”, “an”, and “the” are intended to include the singular and plural forms unless the context clearly indicates otherwise.

The words “example” or “exemplary” used in this invention are intended to serve as an example, instance, or illustration. Any aspect or design described in this disclosure as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise or clear from context, “X employs A or B” is intended to mean any of the natural inclusive permutations. That is, if X employs A, X employs B, or X employs both A and B, then “X employs A or B” is satisfied under any of the foregoing instances.

As used herein, the phrase “about” is intended to refer to a value that is slightly deviated from the value stated herein. Examples have been described throughout the present disclosure.

It is believed that there are two primary factors influencing the stability of perovskite films in photovoltaics: (1) the presence of vacancy defects (˜10¹⁷ cm⁻³), which result from interrupted growth of the [PbI₆]⁴⁻ units at surfaces and grain boundaries, as well as thermal-induced cation evaporation during perovskite formation; (2) the significant phase instability of the corner-shared [PbI₆]⁴⁻ structure, which can decompose ABX₃ into BX₂ and AX under external forces, leading to further degradation and the breakdown of BX₂ into metallic B⁰ and X₂ gas. Although there are reports attempted to address the aforementioned factors, the effectiveness of the reported approaches appears to be limited.

Without wishing to be bound by theory, the inventors have, through their own researches, trials and experiments devised that the halide perovskite structure may be stabilized by polyoxometalates (POM) (or POM cluster). In particular, it is devised that the POMs may be incorporated with appropriate metal substitutions to regulate their redox potential, thereby facilitating efficient redox kinetics to repair Pb⁰ and I⁰ defects in [PbI₆]⁴⁻ unit. It is also devised that the cationic portion of the POMs may be modified/functionalized with ammonium groups for passivating the A-site defects, thus creating a robust POM/perovskite interlayer to stabilize the [PbI₆]⁴⁻ unit. With the aforementioned synergistic effect of the appropriate metal substitutions and the ammonium groups functionalization, the solar cells incorporated with the stabilized perovskite structure may be capable of delivering, for example, 97.2% of its initial power conversion efficiency (PCE) after 1500 hours of shelf-life test at 65° C., a high PCE of about 24.86% to about 25.21%, etc.

In a first aspect of the present invention, there is provided a stabilized perovskite-containing structure for use as a photoactive layer in a solar cell comprising a halide perovskite structure and a polyoxometalate (POM) cluster arranged to stabilize the halide perovskite structure; wherein the POM cluster may include an ammonium compound having a formula selected from the group consisting of:

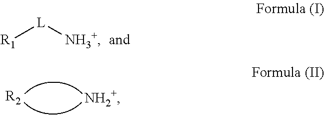

wherein: R₁ may be selected from the group consisting of a hydrogen, an ammonium cation and a halogen; L may be an aliphatic alkyl or an aromatic linker structure having 1 to 26 carbons; R₂ may be selected from the group consisting of amine, substituted or unsubstituted methylene and nitrenium cation (NH₂⁺); and the ring in Formula (II) may represent an aliphatic 6-membraned to 8-membraned ring, including the R₂ and NH₂⁺.

The aliphatic alkyl may be a linear or a branched alkyl. Examples of linear alkyl may include methyl, ethyl, propyl, butyl, pentyl, hexyl, heptyl, octyl, nonyl, decyl, undecyl, dodecyl and the like. The branched alkyl may be defined by replacing one or more the hydrogen along the (principal) linear alkyl chain with an alkyl side chain. Examples of branched alkyl may include isopropyl, tert-butyl, 2-methyldodecyl and the like.

The aromatic linker structure as described herein may be a 6-membered aromatic ring such as a benzene ring. The benzene ring may be unsubstituted or substituted with one or more substituents such as alkyl, halogen and the like.

The methylene (—CH₂—) may be unsubstituted or substituted with a substituent such as alkyl, halogen and the like.

The aliphatic 6-membered to 8-membered ring as used herein generally describes a non-aromatic cyclic structure with 6 to 8 atoms, including the atom of R₂ and the N atom of NH₂⁺. For example, an aliphatic 6-membered ring of Formula (II) may have a ring structure similar/resemble to cyclohexane and the like.

In some particular embodiments, Ri may be selected from the group consisting of a hydrogen, an ammonium cation, F, Br, Cl, and I; L may have a structure of

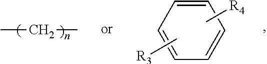

wherein R₃ and R₄ each may be independently a point of attachment for R₁ or NH₃⁺, and each of the R₃ and R₄ may have a structure of

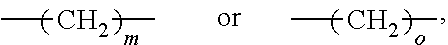

and wherein n is an integer of 1 to 12, m and o may be each independently an integer of 0 to 12; R₂ may be selected from the group consisting of amine and nitrenium cation; and the ring in Formula (II) may represent an aliphatic 6-membraned ring, including the substituent R₂ and NH₂⁺.

In some more particular embodiments, the ammonium compound may have a formula selected from the group consisting of:

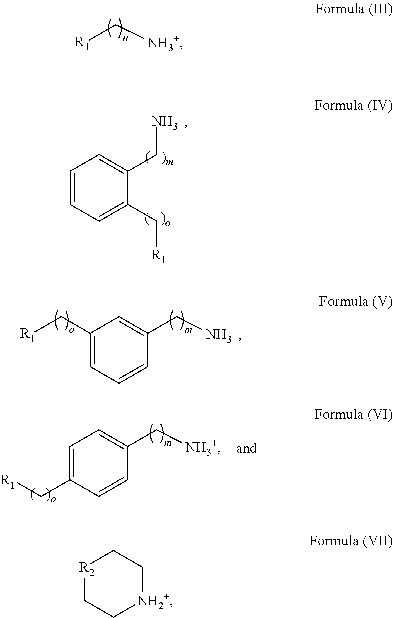

wherein: R₁ is selected from the group consisting of a hydrogen, an ammonium cation, F, Br, Cl, and I; n is an integer of 1 to 10; m and o each independently being an integer of 0 to 10; and R₂ is selected from the group consisting of amine and nitrenium cation.

As some specific embodiments, the ammonium compound is selected from the group consisting of:

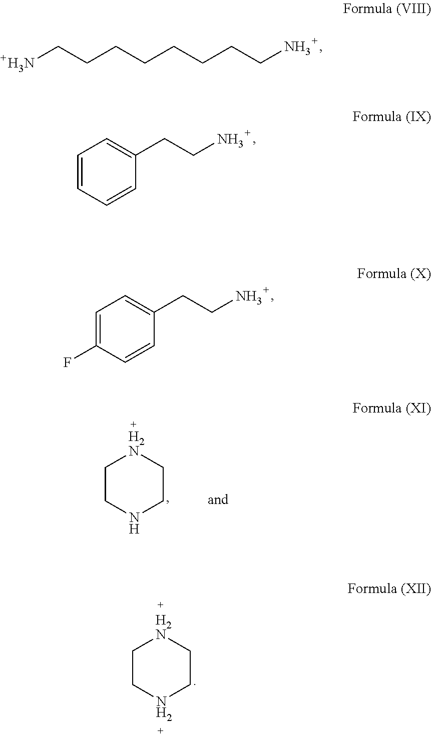

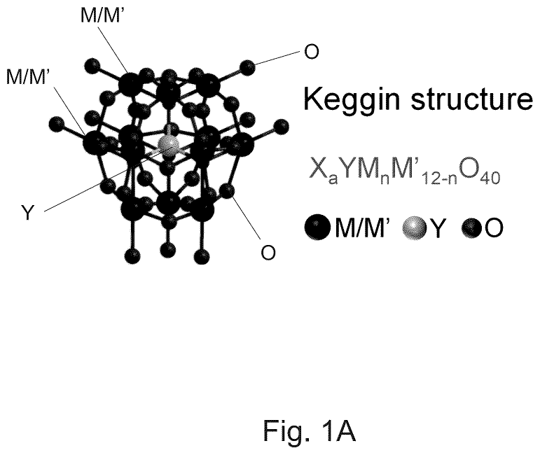

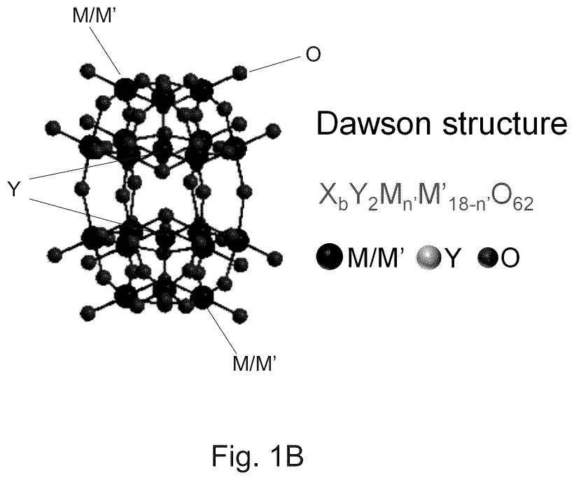

The POM cluster may be a Keggin-type POM or a Dawson-type POM. With reference to FIGS. 1A and 1, there are provided with schematic diagrams illustrating the general structure of a Keggin-type POM and a Dawson-type POM, respectively. The Keggin-type POM may have a full tetrahedral symmetry and may be composed of one heteroatom Y surrounded by four oxygen atoms to form a tetrahedron. The heteroatom Y may be located centrally and caged by 12 octahedral MO₆ and/or M′O₆ units linked to one another by the neighboring oxygen atoms.

The Keggin-type POM may have a formula of (X)ₐ(YMₙM′₁₂₋ₙO₄₀)^{b}, and wherein X may a cation with a charge of +1 or +2 and may be selected from one or more of the ammonium compound of Formula (VIII) to Formula (XII), or may be a combination of H⁺ and one or more of the ammonium compound of Formula (VIII) to Formula (XII); a may be a positive integer of 2 to 4, b may be a negative integer of (−2) to (−4), and a+b=0; Y may be selected from the group consisting of Si and P; M and M′ may be selected from the group consisting of W and Mo; and n may 0-12. In some particular embodiments, the Keggin-type POM may have a formula of (X)₃(PW₁₂O₄₀)³⁻ or (X)₄(SiW₁₂O₄₀)⁴⁻, and wherein X may be a cation with a charge of +1 or +2 and may be selected from one or more of the ammonium compound of Formula (VIII) to Formula (XII), or may be a combination of H⁺ and one or more of the ammonium compound of Formula (VIII) to Formula (XII). As some specific embodiments, the Keggin-type POM may have a formula selected from the group consisting of (PP)₃PW₁₂O₄₀, H(PPD)PW₁₂O₄₀, (PEA)₃PW₁₂O₄₀, (4F-PEA)₃PW₁₂O₄₀, H(ODA)PW₁₂O₄₀, and (PPD)₂SiW₁₂O₄₀.

The Dawson-type POM, on the other hand, may be considered as a fusion of two defect Keggin structures, with three missing octahedra. The Dawson-type POM may have a formula of (X)_{c}(Y₂M_{n′}M′_{18-n′}O₆₂)^{d}, and wherein X may be a cation with a charge of +1 or +2 and may be selected from one or more of the ammonium compound of Formula (VIII) to Formula (XII), or may be a combination of H⁺ and one or more of the ammonium compound of Formula (VIII) to Formula (XII); c may be a positive integer of 3 to 8, b may be a negative integer of (−3) to (−8), and a+b=0; Y may be selected from the group consisting of Si and P; M and M′ may be selected from the group consisting of W and Mo; and n′ is 0-18.

The halide perovskite structure of the stabilized perovskite-containing structure may have a general formula of ABZ₃, with A being an A-site monovalent cation, B being a B-site divalent cation, and Z being a halide anion; and wherein the halide perovskite structure has a formula selected from Cs_{0.05}FA_{0.95}PbI₃ and FA_{0.8}MA_{0.1}Cs_{0.1}Pb(I_{0.6}Br_{0.4})₃. In some particular embodiments, the A-site monovalent cation may be selected from the group consisting of formamidinium (FA⁺), methylammonium (MA⁺), ethylammonium (EA⁺), guanidinium (GA⁺), Cs⁺, Rb⁺ and a combination thereof, the B-site divalent cation may be selected from the group consisting of Pb²⁺, Sn²⁺, Ge²⁺ and a combination thereof, and the halide anion may be selected from the group consisting of I⁻, Br⁻, Cl⁻ and a combination thereof. In some more particular embodiments, the A-site monovalent cation may be selected from the group consisting of formamidinium (FA⁺), methylammonium (MA⁺), Cs⁺ and a combination thereof, the B-site divalent cation may be selected from the group consisting of Pb²⁺, Sn²⁺ and a combination thereof, and the halide anion may be selected from the group consisting of I⁻, Br⁻ and a combination thereof.

The halide perovskite structure may have a bandgap from about 1.25 eV to about 1.94 eV, such as 1.25 eV to 1.94 eV, 1.23 eV to about 1.94 eV, 1.24 eV to about 1.95 eV, 1.25 eV to about 1.92 eV, 1.25 eV to about 1.93 eV and the like. In some embodiments, the halide perovskite structure may have a bandgap of 1.25 eV, 1.55 eV, 1.68 eV, 1.78 eV, 1.94 eV and the like. In other words, the halide perovskite structure may have a normal bandgap (1.5 eV to 1.6 eV) or a wide bandgap (from 1.61 eV to 1.94 eV).

As some specific embodiments, the halide perovskite structure may have a formula selected from Cs_{0.05}FA_{0.95}PbI₃ and FA_{0.8}MA_{0.1}Cs_{0.1}Pb(I_{0.6}Br_{0.4})₃.

In some embodiments, the stabilized perovskite-containing structure may comprise about 0.1 mg/mL to about 0.7 mg/mL (such as 0.1 mg/mL to 0.7 mg/mL, 0.09 mg/mL to 0.7 mg/mL, 0.09 mg/mL to 0.72 mg/mL, 0.1 mg/mL to 0.72 mg/mL, 0.08 mg/mL to 0.72 mg/mL, 0.1 mg/mL to 0.69 mg/mL, 0.09 mg/mL to 0.69 mg/mL, and the like) of the POM cluster.

In some embodiments, the stabilized perovskite-containing structure may comprise about 0.01 mol % to about 0.03 mol % (such as 0.01 mol % to 0.03 mol %, 0.009 mol % to 0.03 mol %, 0.01 mol % to 0.031 mol %, 0.009 mol % to 0.031 mol %, 0.01 mol % to 0.029 mol %, 0.008 mol % to 0.028 mol % and the like) of the POM cluster.

In some embodiments, the POM cluster and the halide perovskite structure may be separated from each other by an interlayer. In particular, the interlayer may be formed by the interaction between the POM cluster and the halide perovskite structure, such that the POM cluster may be in contact with the halide perovskite structure and the interlayer is located therebetween. In an example embodiment, the POM cluster may be a layer in direct contact with a layer of the halide perovskite structure and the interlayer may be located therebetween. For instance, the layer of POM cluster may be in contact with the top or bottom (buried) surface of the layer of the halide perovskite structure. As mentioned, the POM cluster may be advantageous in stabilizing the halide perovskite structure. In particular, the ammonium compound as described herein may interact with the halide perovskite structure to form the interlayer, which may stabilize the [PbI₆]⁴⁻ framework at the top or bottom (buried) surface of the halide perovskite structure; meanwhile the metal-oxide framework in the POM cluster may facilitate electron shuttling, oxidizing Pb⁰ and reducing I⁰ defects generated during aging, thereby synergistically stabilizing the [PbI₆]⁴⁻ framework in a non-equilibrium state.

In some alternative embodiments, the POM cluster may be distributed within the layer of the halide perovskite structure. In other words, the POM cluster may act as an additive being distributed within the layer of the halide perovskite structure.

The method for preparing the stabilized perovskite-containing structure as described herein will now be disclosed. The method as described below will be exemplified with the aid of the POM cluster including an ammonium compound have a formula selected from the group consisting Formula (VIII) to Formula (XII). The method may comprise the steps of:
(a) providing a first solution containing a POM cluster including an ammonium compound having a formula selected from the group consisting of:

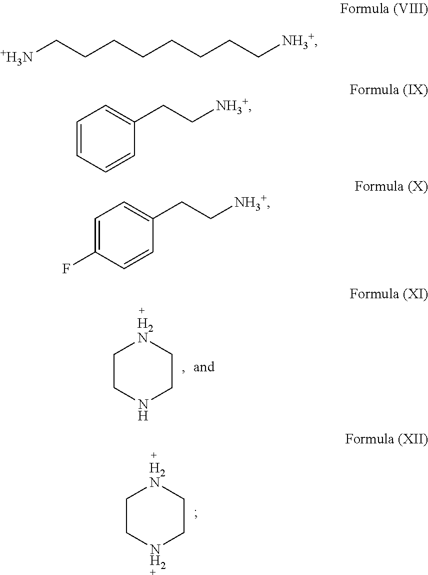

(b) providing a halide perovskite precursor solution comprising halides of formamidinium, methylammonium, cesium, and lead; (c) spin-coating the first solution and the halide perovskite precursor solution in step (b) on a substrate; and (d) annealing the spin-coated solutions to form the stabilized perovskite-containing structure.

Step (a) may be carried out by cation substitution of a precursor POM cluster with an ammonium salt corresponding to the ammonium compound. In these exemplary embodiments, the precursor POM cluster may be selected from H₃PW₁₂O₄₀ and H₄SiW₁₂O₄₀, and the ammonium salt corresponding to the ammonium compound of Formula (VIII), Formula (IX), Formula (X), Formula (XI), and Formula (XII) may be selected from the group consisting of ODAI₂, PEAI, 4F-PEAI, PI, and PPAI₂. The molar ratio between the corresponding ammonium salt (for cation substitution) and the H⁺ (to be substituted) of the precursor POM cluster may vary in accordance with the valence state of the ammonium cation and the charge neutrality of the final POM cluster. In some embodiments, the precursor POM cluster and the ammonium salt have a molar ratio from about 1:1 (e.g., 1:0.98, 1:1, 1:0.99, 0.99:1, 0.98:1, 1:1.02, 1.01:1 and the like) to about 1:4 (e.g., 0.98:4, 0.98:4.1, 1:4, 1.01:4, 0.99:4, 0.99:4.02, and the like). In some example embodiments where the precursor POM cluster may be H₃PW₁₂O₄₀, it may have a molar ratio with the ammonium salt from about 1:1 to about 1:3. In some other example embodiments where the precursor POM cluster may be H₄SiW₁₂O₄₀, it may have a molar ratio with the ammonium salt from about 1:2 to about 1:4.

In particular, the cation substitution may be carried out by slowing adding (e.g., dropwise) a solution of the precursor POM cluster to a solution of the ammonium salt with stirring, resulting a suspension containing the desired POM cluster. The suspension may be stirred for e.g., about 4 hours, and the precipitate may then be collected, e.g., by centrifugation, and dried at e.g., 60° C. for 24 hours. The collected POM cluster precipitate may be dissolved in suitable solvent or solvent mixture to form the first solution for subsequent spin-coating process.

The halides in step (b) may particularly comprise CsI, FAI, MAI, PbI₂, and PbBr₂, and may be provided in accordance with the desired halide perovskite composition. In some example embodiments, the desired halide perovskite composition may be Cs_{0.05}FA_{0.95}PbI₃ or FA_{0.8}MA_{0.1}Cs_{0.1}Pb(I_{0.6}Br_{0.4})₃. In some example embodiments, the halide perovskite precursor solution may have a concentration of about 1M to about 1.8M, and may be prepared by mixing the desired halides of formamidinium, methylammonium, cesium, and lead in a solvent or a solvent mixture (e.g., DMF:DMSO (4:1 v/v)). The halide perovskite precursor solution may be additionally added with one or more of the additives such as about 1% to about 7% of PbI₂, about 1% to about 5% of PbCl₂, about 5% to about 12.5% of MACI, about 1% to about 5% of PEAAc, about 1% to about 5% of 4F-PEAI and the like. The resulting halide perovskite precursor solution may be optionally subjected to filtration before commencing step (c).

The spin-coating processes as described herein may be carried out in an N₂-filled glovebox with O₂ and H₂O levels maintained below 5 ppm at a controlled temperature of about 20° C. In some embodiments, the first solution and the halide precursor solution may be spin-coated separately, particularly sequentially (i.e., in sequential order) onto the substrate. In particular, a first solution containing about 0.05 mg/mL to about 5 mg/mL of the POM cluster in a polar solvent such as methanol, ethanol, isopropanol, nitromethane, N,N-dimethylformamide (DMF) and dimethylsulfoxide (DMSO) may be spin-coated on the substrate at e.g., about 1000 rpm to about 6000 rpm for about 10 seconds to about 60 seconds, followed by annealing substrate spin-coated with the first solution at e.g., about 90° C. to about 120° C. for about 1 minute to about 10 minutes. After that, the halide perovskite precursor solution (e.g., about 30 μL to about 60 μL) may be spin-coated onto the annealed substrate having the spin-coated first solution at e.g., about 3000 rpm to about 5000 rpm for about seconds to about 60 seconds. In particular, about 5 seconds to about 10 seconds before ending of the spin-coating of the halide perovskite precursor solution, CB antisolvent (e.g., about 100 μL to about 300 μL) may be added. After completing the spin-coating of the halide perovskite precursor solution, another annealing may then be carried out at about 90° C. to about 120° C. for about 10 minutes to about 30 minutes to obtain the stabilized perovskite-containing structure. Optionally or additionally, a passivating agent such as PI, EDAI₂ and the like (e.g., about 0.2 mg/mL to about 0.5 mg/mL in IPA) may be spin-coated on the stabilized perovskite-containing structure, followed by annealing at e.g., about 90° C. to about 120° C. for about 1 minute to about 10 minutes.

In some other embodiments, the first solution and the halide precursor solution may be spin-coated onto the substrate simultaneously. In particular, the first solution may be mixed with the halide precursor solution to form a solution mixture before carrying out the spin-coating. Alternatively, the solution mixture may be prepared by dissolving the POM cluster precipitate (e.g., about 0.05 mg/mL to about 5 mg/mL) in the halide precursor solution. The solution mixture (i.e., halide precursor solution containing the POM cluster) may then be spin-coated onto the substrate at e.g., about 3000 rpm to about 5000 rpm for about 40 seconds to about 60 seconds. Similarly, about seconds to about 10 seconds before ending of the spin-coating of the solution, CB antisolvent (e.g., about 100 μL to about 300 μL) may be added, followed by annealing the spin-coated solution mixture at about 90° C. to about 120° C. for about 10 minutes to about 30 minutes to obtain the stabilized perovskite-containing structure. Optionally or additionally, a passivating agent such as PI, EDAI₂ and the like (e.g., about 0.2 mg/mL to about 0.5 mg/mL in IPA) may be spin-coated on this stabilized perovskite-containing structure, followed by annealing at e.g., about 90° C. to about 120° C. for about 1 minute to about 10 minutes.

The substrate may be selected in accordance with practical needs. Examples of said substrate may include a transparent substrate (e.g., glass, PDMS, PET, ITO, FTO, etc.), a hole transport layer (e.g. SAM or SAM including an additional POM cluster), an electron transport layer and the like or a combination thereof.

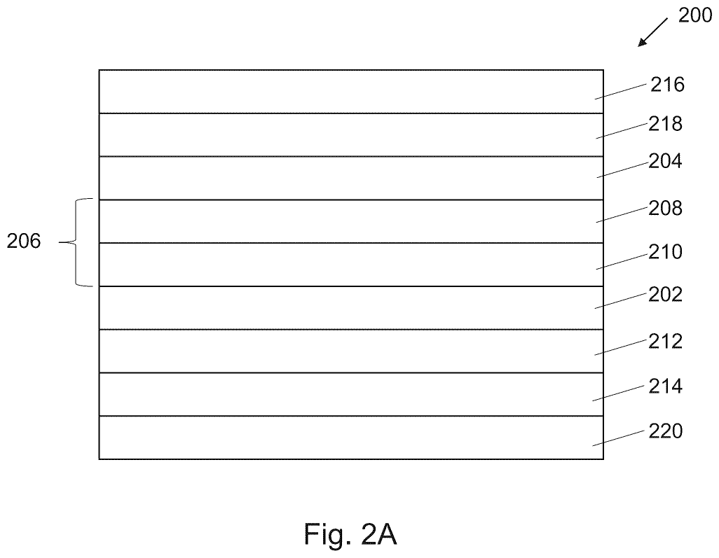

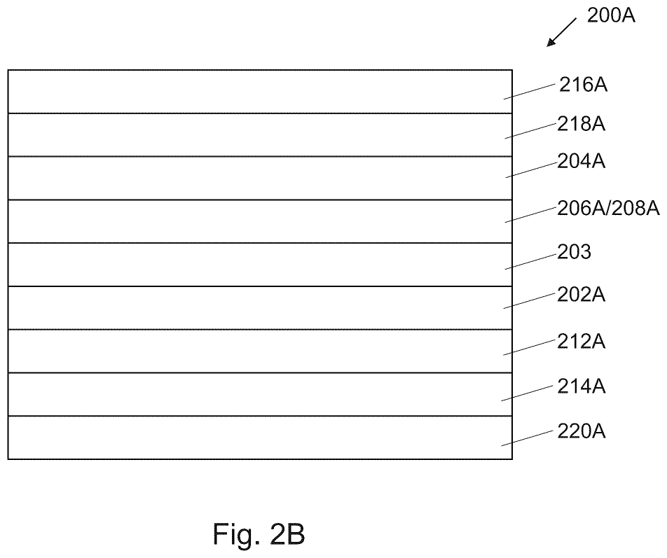

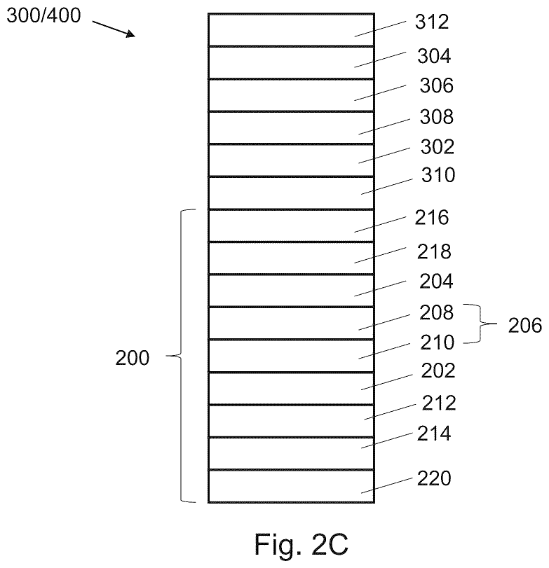

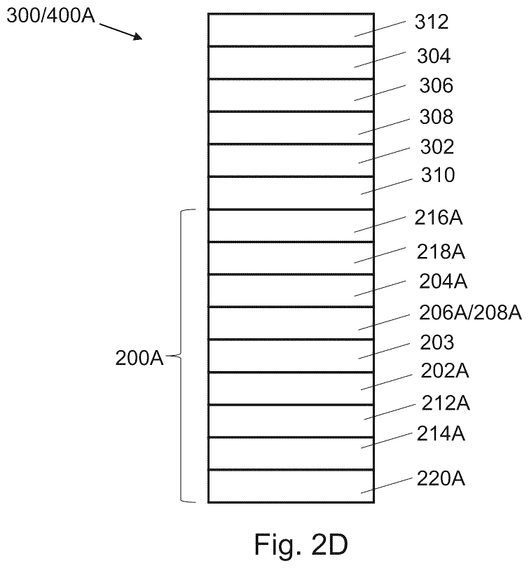

A further aspect of the present invention pertains to a solar cell, in particular a solar cell including the stabilized perovskite-containing structure as described herein as a photoactive layer of said solar cell. With reference to FIG. 2A, there is provided a solar cell 200 in accordance with an exemplary embodiment of the present invention. The solar cell 200 comprises a hole transport layer 202; an electron transport layer 204; and a stabilized perovskite-containing structure 206 disposed between the hole transport layer and the electron transport layer. In particular, the stabilized perovskite-containing structure 206 may be the one including the halide perovskite structure 208 and the ammonium compound-containing POM cluster 210 as described herein.

As illustrated in FIG. 2A, the POM cluster 210 may be disposed between, particularly in contact with the halide perovskite structure 208 and the hole transport layer 202. The solar cell 200 may further comprise a transparent conductive layer 212 in contact with a transparent substrate 214, with the transparent conductive layer 212 being in contact with the hole transport layer 202. The solar cell 200 may further comprise a metal layer 216, and a blocking layer 218 arranged sequentially with the electron transport layer 204. In particular, the block layer 218 may be disposed between and in contact with the electron transport layer 204 and the metal layer 216. The solar cell 200 may further comprise an anti-reflection layer 220 (such as MgF₂ in some embodiments) in contact with the transparent substrate 220.

The solar cell 200 may be a normal bandgap solar cell or a wide bandgap solar cell. In an example embodiment, the solar may be a wide bandgap solar cell with a bandgap of about 1.78 eV.

The hole transport layer 202 may be a self-assembled monolayer (SAM). In some embodiments, the hole transport layer 202 may be a self-assembled monolayer (SAM) of CbzNaph or Me-4PACZ. Without wishing to be bound by theory, the inventors have devised that the POM cluster 210 (of the stabilized perovskite-containing structure 206) may intercalate with the SAM by filling into the (nano)voids of the SAM film. Advantageously, it is believed that during the preparation of the solar cell, said intercalated structural arrangement may minimize the effect of solvent erosion from the halide perovskite structure's solution processing.

The electron transport layer 204 may comprise any suitable electron transport material. For example, in some embodiments, the electron transport layer may be selected from the group consisting of C₆₀, and its derivatives such as PCBM ([6,6]-phenyl-C61-butyric acid methyl ester) and ICBA (indene-C60 bisadduct).

The transparent substrate 214 may be flexible or rigid, and may have an average light transmittance greater than about 80% (at 550 nm). In some embodiments, the transparent substrate may be selected from the group consisting of glass, PC (polycarbonate), PET (polyethylene glycol terephthalate), PEN (polyethylene naphthalate), PA (polyamide), PMMA (polymethyl methacrylate), PS (polystyrene), ABS (acrylonitrile butadiene styrene copolymer), PDMS (polydimethylsiloxane), and a combination thereof.

In some embodiments, the transparent conductive layer 212 may be selected from the group consisting of Indium Tin Oxide (ITO), Aluminum Zinc Oxide (AZO), graphene, PH1000 poly(3,4-ethylenedioxythiophene).poly(styrene sulfonate) (PH1000 PEDOT:PSS), Ag nanowire and a combination thereof.

In some embodiments, the blocking layer 218 may be selected from bathocuproine (BCP), SnO₂, and MoOₓ. In particular, it is appreciated that when the blocking layer is in contact with an electron transport layer, it may be referred as a “hole blocking layer” which is intended to block minority charge carriers such as hole in this case, to cathode. Examples of the hole blocking layer may include BCP, ALD SnO₂, and the like. In contrast, when the blocking layer is contact with a HTL, it may be referred as an “electron blocking layer” which is intended to block minority charge carrier such as electron to anode. Example of the electron blocking layer may include MoOₓ and the like.

The metal layer may comprise a metal with a resistivity less than about 5×10⁻⁷ Ω·m at 25° C. In some embodiments, the metal layer may be selected from the group consisting of Ag, Cu, Au, Al, Pt and a combination thereof.

In some alternative embodiments, the POM cluster 210 may be dispersed within the halide perovskite structure 208, forming a stabilized perovskite-containing structure 206A. With reference to FIG. 2B, there is provided with a solar cell 200A modified from the solar cell 200. The solar cell 200A may have a similar structural components and arrangement as the solar cell 200. For example, the solar cell 200A may have a hole transport layer 202A; an electron transport layer 204A, with the stabilized perovskite-containing structure 206A disposed between the hole transport layer 202A and the electron transport layer 204A. The solar cell 200A may further comprise a transparent conductive layer 212A in contact with a transparent substrate 214A, with the transparent conductive layer 212A being in contact with the hole transport layer 202A; a metal layer 216A, and a blocking layer 218A arranged sequentially with the electron transport layer 204A, with the block layer 218A disposed between and in contact with the electron transport layer 204A and the metal layer 216A; and an anti-reflection layer 220A in contact with the transparent substrate 220A.

The stabilized perovskite-containing structure 206A may be particularly disposed on the hole transport layer 202A, and more particularly in contact with an additional POM cluster 203. The additional POM cluster 203 may be particularly in form of a layer disposed between the stabilized perovskite-containing structure 206A and the hole transport layer 202A. In some embodiments, the additional POM cluster 203 may comprise H₃PW₁₂O₄₀. In some other embodiments, the additional POM cluster 203 may comprise the POM cluster 210 (i.e., the POM cluster including the ammonium compound as described herein).

In some embodiments, the solar cell 200 may be configured as a subcell that is arranged in contact with an additional subcell, forming a tandem structure (or tandem solar cell). The additional subcell, in particular, may be in contact with the metal layer 216 (of the solar cell 200 (or subcell 200)), forming a tandem solar cell. As exemplified in FIG. 2C, an additional subcell 300 may be disposed on and in contact with the metal layer 216 of the solar cell (subcell) 200, forming a tandem solar cell, such as a perovskite-organic tandem solar cell 400. The additional subcell 300 may comprise a hole transport layer 302; an electron transport layer 304; and an organic photovoltaic material 306 disposed between the hole transport layer and the electron transport layer of the additional subcell 300. In particular, the hole transport layer 302 may be in contact with an additional POM cluster 308 as illustrated in FIG. 2C. In some embodiments, the additional POM cluster 308 may comprise H₃PW₁₂O₄₀. In some other embodiments, the additional POM cluster 308 may comprise H₄SiW₁₂O₄₀.

The organic photovoltaic material 306 may be particularly in contact with the hole transport layer 302 and the electron transport layer 304. The organic photovoltaic material 306 may be selected from those with a narrow bandgap as described herein. In an example embodiment, the organic photovoltaic material 306 may comprise PM6:BTP-eC9, which may have a bandgap of about 1.38 eV. In other words, in this example embodiment where the additional subcell 300 including an organic photovoltaic material 306 of PM6:BTP-eC9, said subcell may have a bandgap of about 1.38 eV.

The hole transport layer 302 may be disposed on, particularly in contact with a blocking layer 310. The blocking layer 310 may have a material different from that of the blocking layer in the solar cell 200. For example, in an embodiment, the blocking layer 310 may comprise MoOₓ whereas the blocking layer of the solar cell 200 may comprise ALD SnO₂. The blocking layer 310 may be particularly in contact with the metal layer of the solar cell 200.

The electron transport layer 304 may be disposed between a metal layer 312 and the organic photovoltaic material 306, and particularly in contact with them. The electron transport layer 304 may comprise any suitable electron transport material. For example, in some embodiments, the electron transport layer may comprise PNDIT-F3N.

In an alternative embodiment, there is provided a modified tandem solar cell 400A. As exemplified in FIG. 2D, the tandem solar cell 400A may have the additional subcell 300 described herein disposed on and in contact with the metal layer 216A of the solar cell (subcell) 200A described herein.

The solar cell of the present invention may be fabricated by typical method such as the method as described below.

Typically, the fabrication of solar cell may include the steps of: providing a substrate; depositing the substrate with a transparent conductive layer; optionally cleaning and drying the deposited substrate; spin-coating a hole transport layer onto the transparent conductive layer; spin-coating the stabilized perovskite-containing structure as described herein (as a photoactive layer) onto the hole transport layer; and thermally evaporating an electron transport layer and a metal layer.

The substrate deposited with the transparent conductive layer, such as the substrate 214/214A deposited with the transparent conductive layer 212/212A, may be sequentially cleaned by sonication with detergent, deionized water, acetone, and isopropyl alcohol for about 15 min, respectively. Then, the substrate may be dried at about 80° C. in oven for about 24 h. The cleaned and dry substrate may be treated with oxygen plasma for about 30 minutes and then transferred into a N₂-filled glovebox before subsequent spin-coating process.

The hole transport layer such as the hole transport layer 202/202A may be prepared by spin-coating a SAM solution (about 0.1 mg/mL to about 5.0 mg/mL in polar solvent such as methanol, ethanol, isopropanol and the like) onto the transparent conductive layer at about 1000 rpm to about 6000 rpm for 10 seconds to about 60 seconds, followed by annealing at about 50° C. to about 150° C. for about 1 minute to about 20 minutes. After cooling the annealed hole transport layer, optionally or additionally, the cooled hole transport layer may be rinsed with suitable solvent by way of spin-coating at about 1000 rpm to about 6000 rpm for about 10 seconds to about 60 seconds, followed by another annealing at about 50° C. to about 150° C. for about 1 minute to about 20 minutes.

In the embodiment where the solar cell comprises a layer of additional POM cluster such as the additional POM cluster layer 203 disposed between the hole transport layer 202A and the stabilized perovskite-containing structure 206A, the additional POM cluster layer may be prepared by spin-coating a solution of the additional POM cluster (about 0.05 mg/mL to about 5.0 mg/mL, in a polar solvent such as methanol, ethanol, isopropanol, nitromethane, DMF and DMSO) on the hole transport layer as prepared above at about 1000 rpm to about 6000 rpm for about 10 seconds to about 60 seconds, followed by annealing at about 90° C. to about 120° C. for about 1 minute to about 10 minutes.

The electron transport layer such as the electron transport layer 204/204A, the blocking layer such as the blocking layer 218/218A, the metal layer such as the metal layer 216/216A, and the anti-reflection layer such as the anti-reflection layer 220/220A may be deposited by thermal evaporation under high vacuum (e.g., <about 2×10⁻⁶ Torr). The thickness of these layers may be adjusted in accordance with practical needs. For example, the electron transport layer may have a thickness of about 10 nm to about nm, the blocking layer may have a thickness of about 3 nm to about 8 nm, and the metal layer may have a thickness of about 80 nm to about 150 nm, and the anti-reflection layer may have a thickness of about 100 nm and the like.

Hereinafter, the present invention is described more specifically by way of examples, but the present invention is not limited thereto.

### EXAMPLES

### Materials and Methods

### Materials

All materials were used as received without further purification. These included DMF (99.99%, J&K), dimethyl sulfoxide (DMSO, 99.70%, J&K), isopropanol (IPA, 99.50%, J&K) and chlorobenzene (CB, 99.90%, J&K). CsI, MAI, MACI, PbCl₂, and EDAI₂ were obtained from Xi'an Polymer Light Technology. PbI₂ (99.9985%), PbBr₂ (99.9%), and Me-4PACZ were procured from TCI. FAI was sourced from Dysol. H₃PW₁₂O₄₀ (99.5%), H₃PMo₁₂O₄₀ (99.5%) and MoOₓ were acquired from Sigma-Aldrich. H₄SiW₁₂O₄₀ was acquired from Macklin. PM6 and BTP-eC9 were purchased from Solarmer Materials. PNDIT-F3N was purchased from eFlexPV Limited.

Ammonium salts piperazinium iodide (PI), piperazine dihydriodide (PDAI₂), phenethylamine hydroiodide (PEAI), 2-(4-fluorophenyl)ethylamine hydroiodide (4F-PEAI), and n-octylammonium iodide (ODAI₂) were sourced from Xi'an Polymer Light Technology. Piperazinium iodide (PI) and CbzNaph were synthesized according to reported methods.

### Redox Mediator Experiments in Solution State

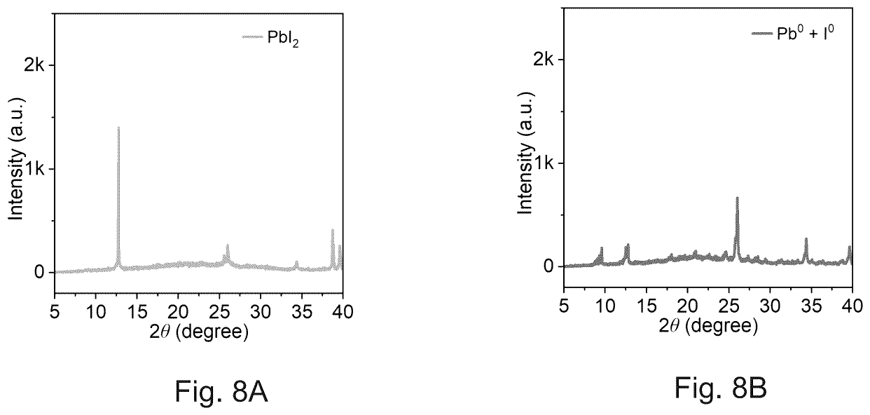

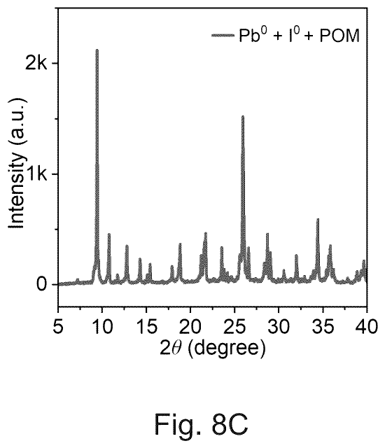

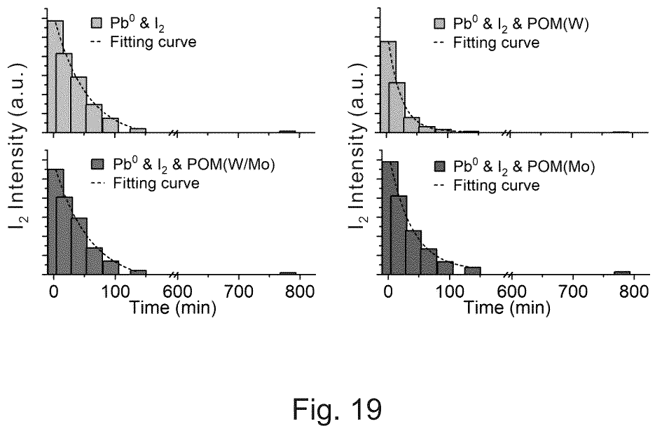

In FIGS. 8A to 8C, I⁰ (25 mg, 0.1 mmol) and Pb⁰ (25 mg, 0.12 mmol) powders were dispersed in 2 ml of mixed DMF/IPA solvent (volume ratio 1:10) without or with redox mediators (0.025 mmol), and the solutions were stirred at 100° C. for 60 minutes. In FIG. 19, I⁰ (25 mg, 0.1 mmol) and Pb⁰ (25 mg, 0.12 mmol) powders were dispersed in 2 ml of mixed DMF/IPA solvent (volume ratio 10:1) without or with redox mediators (0.025 mmol), and the solutions were stirred at room temperature for various reaction durations.

### Device Characterizations

The current density-voltage (J-V) characteristics of devices were measured in a N₂-filled glovebox using a Keithley 2400 Source Meter under simulated sunlight from a solar simulator (SS-F5, EnliTech). To achieve an AM 1.5G (100 mW/cm²) solar simulator light intensity, a National Renewable Energy Laboratory (NREL) calibrated silicon solar cell (with a KG-2 filter) was employed. During testing, perovskite solar cells were covered with a shading mask featuring an aperture area of 0.04 cm² to ensure the current density's accuracy from J-V curves. The J-V measurements were conducted in sweep mode with both reverse and forward scans at a scan rate of 10 mV/s and a step of 0.02 V. Additionally, EQE curves were obtained using an EQE measurement system (QE-R, EnliTech).

Cyclic voltammetry measurements were conducted using a CHI1020D electrochemical workstation. The experiments were carried out at room temperature employing a conventional three-electrode system. This system consisted of a glassy carbon electrode as the working electrode, Pt wire as the counter electrode, and Ag/AgCl (saturated KCl) as the reference electrode.

Steady-state PL, TRPL, and PLQY spectra were measured using an FLS1000 photoluminescence spectrometer system (Edinburgh). Excitation was achieved with a light of 375 nm for PL and a pulsed excitation laser of 375 nm for TRPL, respectively.

XPS analysis was conducted using a Thermo Fisher ESCALAB XI+X-ray photoelectron spectrometer. UV light from non-monochromatic He I with an energy of 21.21 eV was utilized for the measurement. Solution UV-vis absorption spectra were acquired using an Agilent 8454 spectrophotometer. tdPL spectra were gathered using a custom-built facility. This involved introducing an excitation laser (450 nm) to the sample through a fiber, with the resulting PL spectra detected using a detector connected to an Ocean Optics USB2000 spectrometer.

ToF-SIMS measurements were performed on a PHI nanoToFII. For sputtering, pulsed primary ions from an O₂ liquid metal ion gun (1 keV) were employed, while analysis was carried out using a pulsed primary ion beam of Bi³⁺ (30 keV). Grazing-incidence wide-angle X-ray scattering (GIWAXS) was carried out at the BL14B1 beamline of the Shanghai Synchrotron Radiation Facility (SSRF). The X-ray used had a wavelength of 0.6887 A° and energy of 18.00264 keV. Two-dimensional (2D) GIWAXS patterns were captured using a MarCCD 225 detector, with the sample-to-detector distance set at 522.052 mm. Subsequently, the 2D GIWAXS patterns were analyzed using the FIT2D software.

The morphology of the thin-film samples in top view and cross-sectional profile of the tandem cell were examined using SEM (QUATTRO S). Powder and thin-film XRD characterizations were conducted using a D2 Phaser instrument with Cu Karadiation (wavelength of 1.5418 Å).

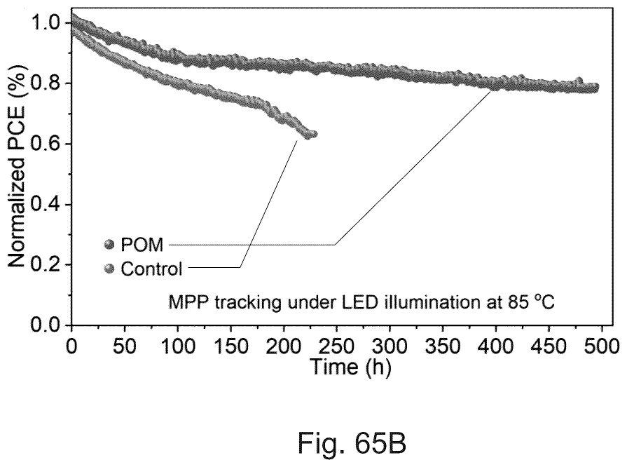

In FIG. 65A, the PSCs were operated at their MPP while being illuminated by a LED source covering wavelengths from 400 to 1,000 nm. Throughout the test, the sample chamber was maintained in ambient air with a continuous N₂ flow.

### DFT Calculations

DFT calculations were performed to understand the molecular and interface structures. To understand the interactions between the POM molecule and perovskite, crystal structure of perovskite (FAPbI₃) was used to build the PbI₂-terminated or FAI-terminated slabs with a POM molecule on the surface. A vacuum layer of ˜15 Å was added to avoid self-interactions. The built systems were then energy minimized using Monkhorst-Pack k-point mesh at Gamma until the total energies converge to 0.02 meV per atom and displacements less than 0.002 Å. All these periodic DFT calculations were conducted using the Cambridge Serial Total Energy Package, CASTEP academic 22.11 release. Generalized gradient approximation (GGA) with Perdew-Burke-Ernzerh (PBE) parametrization with Grimme's DFT-D3 correction was used with on-the-fly generation (OTFG) ultrasoft pseudopotentials. Real-space mesh cut-off of 550 eV is used for all CASTEP calculations. The binding energy, E_{binding}, was calculated from E_{binding}=E_{slab}−(Eₚₑᵣₒᵥₛₖᵢₜₑ+E_{molecule}). To evaluate the effect of POM on redox reaction, DFT calculations were performed based on molecular systems using ORCA 5.0.1. software.^{[7]} Single molecules and interacted molecules in the half reactions were built and optimized at the level of theory of B3LYP-D3/def2-SVP. Then, total energies were further calculated at the level of theory of B3LYP-D3/def2-TZVP based on single-point calculations of the optimized structures.

### Preparation of Keggin POMs

### H₃PW₆Mo₆O₄₀

Disodium hydrogen phosphate (2.15 g, 6 mmol) and sodium molybdate (8.71 g, 36 mmol) were dissolved in 12.5 ml and 25 ml of deionized water, respectively. The solutions were refluxed at 90° C. for 30 minutes. Then, sodium tungstate (11.88 g, 36 mmol) and concentrated H₂SO₄ were added dropwise to adjust the pH to 1.5. The mixture was heated to 90° C. again and stirred for an additional 8 hours. After extraction with diethyl ether three times, the yellow H₃PW₆Mo₆O₄₀ powders were obtained by evaporating to dryness.

### Functional POMs with Cation Substitution

H₃PW₁₂O₄₀ (288 mg) and various ammonium salts (PI: 64.5 mg, PDAI₂: 34.2 mg, PEAI: 74.7 mg, 4F-PEAI: 80.1 mg, ODAI₂: 25.7 mg) were dissolved in 4 mL and 0.5 mL of deionized water, respectively. The solution of H₃PW₁₂O₄₀ was slowly added into the stirring solution of the respective ammonium salt, resulting in the quick precipitation of the mixture. After stirring for 4 hours, the precipitate was collected through centrifuge and dried at 60° C. for 24 hours.

H₄SiW₁₂O₄₀ (288 mg) and PDAI₂ salts (68.4 mg) were dissolved in 4 mL and 0.5 mL of deionized water, respectively. The solution of H₄SiW₁₂O₄₀ was slowly added into the stirring solution of the ammonium salt, resulting in the quick precipitation of the mixture. After stirring for 4 hours, the PPD₂SiW₁₂O₄₀ precipitate was collected through centrifuge and dried at 60° C. for 24 hours.

Calculation of elemental analysis (%): PP₃PW₁₂O₄₀ (3138.46 g/mol): C, 4.59, H 1.05, N, 2.68; Found: C, 4.28, H, 1.22, N, 2.35. H(PPD)PW₁₂O₄₀ (2937.17 g/mol): C, 1.63, H, 0.41, N, 0.95; Found: C, 1.46, H, 0.47, N, 0.87.

### Device Fabrication

### Single-Junction Normal Bandgap Perovskite Solar Cells (PSCs)

The pre-patterned ITO glass substrates underwent thorough cleaning by sonication with a detergent, deionized water, acetone and IPA successively, each for 15 min. Subsequently, the cleaned ITO glass substrates were dried in an oven at 80° C. for 24 h and treated with O₂ plasma for 30 min before use.

The CbzNaph hole-selective SAM (100 mg/mL in DMF) was diluted by IPA solvent to a concentration of 1.5 mg/mL. The resulting solution was spin-coated onto the ITO glass substrates at 3,000 rpm for 30 s and subsequently annealed at 100° C. for 10 min.

The POM solution (5 mg/mL in DMF) was diluted by IPA solvent, spin-coated onto the SAM substrate at 3,000 rpm for 30 s, and annealed at 100° C. for 10 min.

Next, the normal bandgap perovskite was prepared as follows: 1.4 M perovskite precursor solutions were constructed by mixing FAI, PbI₂, and CsI in DMF:DMSO solvent (volume ratio 4:1) with the chemical formula Cs_{0.05}FA_{0.95}PbI₃. Excessive 5% PbI₂, 3% PbCl₂, 10% MACI, and 1.4 mg of 4F-PEAI additives were added to the precursor solution, and no filtration was required before use. 40 μL of the perovskite precursor was then spin-coated at 4,000 rpm for 50 s, with 180 μL of CB antisolvent added to the center of the wetted film 5 s before the end of the process. This was followed by annealing at 100° C. for 30 min. Subsequently, PI (a passivating agent) solution (0.3 mg/ml in IPA) was spin-coated onto the formed perovskite at 3,000 rpm for 30 s and annealed at 100° C. for 10 min. All the spin-coating processes were conducted in an N₂-filled glovebox with the contents of O₂ and H₂O below 5 ppm at a controlled temperature of approximately 20° C.

Finally, a 25-nm C₆₀, 6-nm BCP and 100-nm Ag were thermally evaporated in a high-vacuum chamber (<2×10⁻⁶ torr) through a metal shadow mask (aperture area 0.04 cm²), followed by thermal evaporation of 100 nm of MgF₂ onto the glass side of the devices as an antireflection layer.

### 1.68-eV and 1.78-eV Single-Junction Wide-Bandgap PSCs

The fabrication process is similar to the single-junction normal bandgap PSCs except for the followings:

To prepare the 1.68-eV WBG perovskite, CsI (31.2 mg), MAI (19.1 mg), FAI (165.1 mg), PbI₂(369.0 mg), PbBr₂(146.6 mg), PEAAc (0.6 mg), MACI (1.7 mg), and PbCl₂ (6.7 mg) were dissolved in 1 mL of mixed DMF/DMSO solvent (volume ratio 4:1) with the chemical formula FA_{0.8}MA_{0.1}Cs_{0.1}Pb(I_{0.6}Br_{0.4})₃. The solutions were stirred overnight at room temperature, and no filtration was required before use.

To prepare the 1.78-eV WBG perovskite, CsI (31.2 mg), MAI (19.1 mg), FAI (165.1 mg), PbI₂(221.3 mg), PbBr₂(264.2 mg), PEAAc (0.6 mg), MACI (1.7 mg), and PbCl₂ (6.7 mg) were dissolved in 1 mL of mixed DMF/DMSO solvent (volume ratio 4:1) with the chemical formula FA_{0.8}MA_{0.1}Cs_{0.1}Pb(I_{0.6}Br_{0.4})₃. The solutions were stirred overnight at room temperature, and no filtration was required before use.

The perovskite layers were prepared by spin-coating the corresponding WBG perovskite precursor solution initially at 1,000 rpm for 10 s and the second step at 4,000 rpm for 40 s. During the spin-coating process, 180 μL of CB antisolvent was dripped onto the wetted film 25 s before the end of the process and then annealed at 100° C. for 10 min. The passivation layer was applied by spin-coating EDAI₂ (a passivating agent) (0.5 mg/ml in IPA) at 3,000 rpm, followed by annealing at 100° C. for 10 min.

### Single-Junction Bulk Heterojunction (BHJ) Organic Solar Cells (OSCs)

The organic solar cells were configured with a p-i-n configuration, utilizing the device setup of ITO/SAM (CbzNap, with or without POM)/PM6:BTP-eC9/PNDIT-F3N/Ag. The SAM substrate was prepared by reported method. The H₃PW₁₂O₄₀ solution (0.2 mg/mL in IPA) was spin-coated onto the SAM substrate at 3,000 rpm for s, and annealed at 100° C. for 5 min.

To prepare the 1.38-eV organic active layer, the blends of PM6:BTP-eC9 (weight ratio 1:1.2) were dissolved in chloroform with donor concentration of 8.0 mg/mL and stirred at 50° C. for >1 h. A small amount of diiodooctane (0.32 vol %) was added into the solution 10 min ahead of deposition. Then, the blend solution containing active layer materials was spin-coated on the substrates at 3,500 rpm for 35 s, followed by thermal annealing at 85° C. for 5 min, giving an active layer with thickness of ˜100 nm. After cooling, a PNDIT-F3N (0.5 mg/mL in methanol with 0.5 vol % of acetic acid) was spin-coated onto the organic BHJ layer at 1,500 rpm for 40 s. Finally, a 100-nm Ag layer was thermally evaporated in a high-vacuum chamber (<2×10⁻⁶ torr).

### Normal Bandgap Perovskite Solar Modules (PSMs)

The fabrication procedures for the large-area device were similar to those for the small-area normal bandgap devices. Especially for the perovskite module, the P1 line was etched before deposition of charge selective layer, while the P2 and P3 lines were etched after the deposition of BCP and Ag layers, respectively. The geometric fill factor is calculated to be ˜94%.

### Perovskite Organic Tandem Solar Cells (PO-TSCs)

The monolithic PO-TSCs involving the integration of narrow-bandgap organic subcells on top of the WBG perovskite subcells. Initially, after the atomic layer deposition of 20-nm SnO₂ in the wide-bandgap subcells, a 0.5-nm Au (deposited at a rate of 0.05 A s⁻¹) and 10-nm MoOₓ were thermally evaporated onto the SnO₂ to create an interconnecting layer for the tandem cells. Subsequently, the organic BHJ layer was then spin-coated on MoOₓ/SAM/POM. Following this, PNDIT-F3N was spin-coated on the organic BHJ layer at 1,500 rpm for 40 s. Lastly, a 100-nm layer of Ag was thermally evaporated. Thermal evaporation of 100 nm of MgF₂ onto the glass side of the devices was performed to create an antireflection layer.

### Example 1

### Principles of the POM Mediators to Reinforce Perovskite

Polyoxometalates (POMs) represent a class of anionic clusters composed of high-valent early transition metal ions polymerized with terminal or bridging oxygen atoms. It is believed that these nano-sized POM clusters possess versatile structures and unique physicochemical properties, enabling them to be used in perovskite photovoltaics, such as: (1) n-type POMs, with low LUMO and work function values, facilitate carrier tunneling from the photovoltaic layer to the hole-selective layer, potentially enhancing interfacial carrier kinetics; (2) the counter cations in POMs can be tailored to passivate the perovskite structure; (3) the reversible redox activity of POMs, involving high-valent early transition metal ions as electron acceptor, enables the passivation of B-site and X-site defects through an electron-shuttling process that oxidizes Pb⁰ and reduces I⁰ species. POMs and their derivative structures come in various types (e.g., Keggin, Dawson, and Anderson).

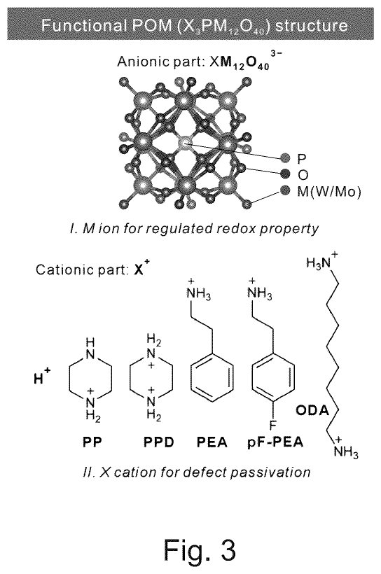

As an exemplary demonstration, this work focuses on the Keggin-type POMs, with a general formula X₃PM₁₂O₄₀, which is believed to be capable of delivering POMs' reliable properties through molecular design. In this structure, the M sits are typically occupied by W⁶⁺ or Mo⁶⁺ ions, and the X site by a positively charged cation (FIG. 3). It is believed that the principle of the POM mediators to reinforce the perovskite may be divided into two parts: (1) the regulation of metal ions in POM which tailor redox potentials and facilitate Pb⁰/I⁰ electron shuttling; and (2) the functionalization of the cationic component in POMs which may effectively passivate vacancy defect in the perovskite film.

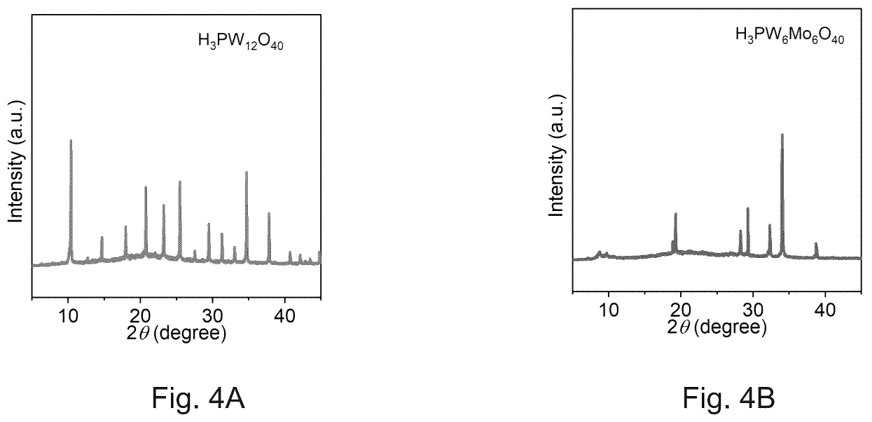

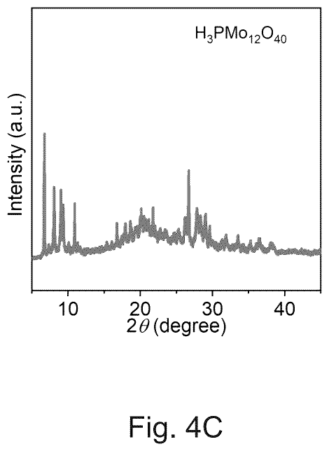

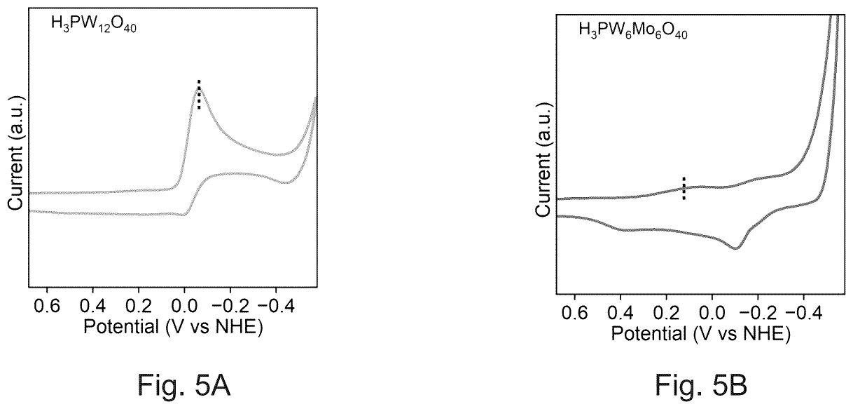

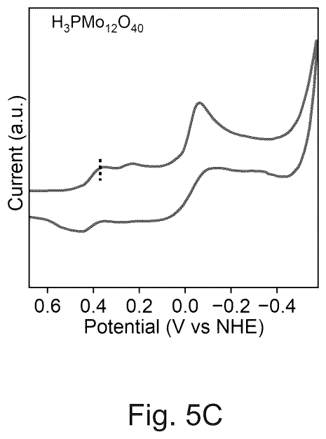

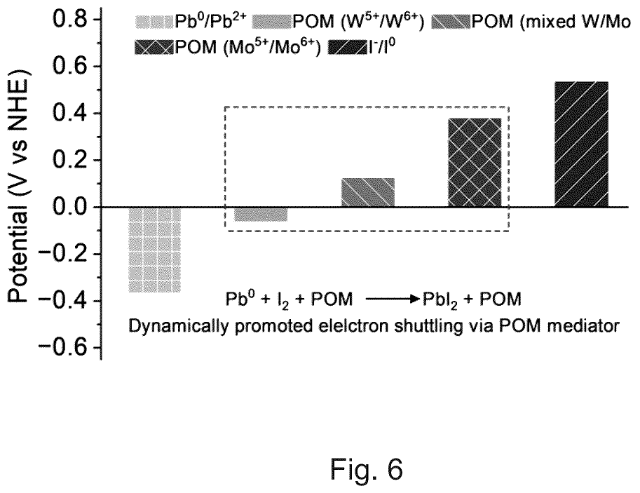

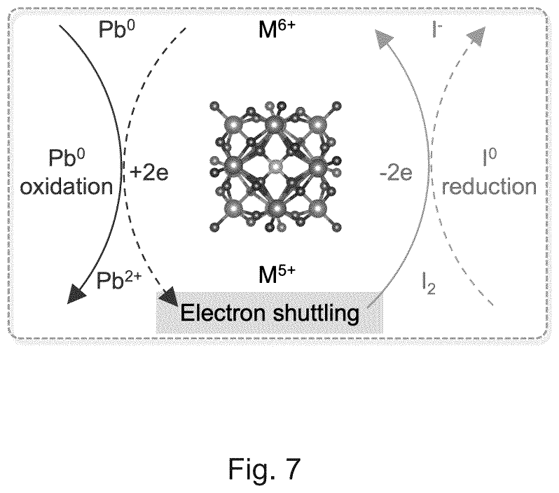

The redox activity of POM with the H₃PM₁₂O₄₀ structure was investigated. For effective electron transfer between Pb⁰ and IO, it is believed that the redox potential (E°) of POM mediator should lie between the Pb⁰/Pb²⁺(−0.365 V versus NHE) and I⁰/I⁻ (0.536 V versus NHE) couples. Without wishing to be bound by theory, it is believed that the first redox peak of POMs may be controlled by varying the ratio of metal ions, thereby fine-tuning the redox potential. Accordingly, H₃PW₁₂O₄₀, H₃PW₆M₆O₄₀, and H₃PMo₁₂O₄₀ materials (FIGS. 4A to 4C) were prepared to explore the efficiency of POM-mediated electron shuttling between Pb⁰ and I⁰. The redox potentials of the H₃PW₁₂O₄₀, H₃PW₆M₆O₄₀, and H₃PMo₁₂O₄₀ materials were measured using cyclic voltammetry curves, which yielded values of −0.06, 0.124, and 0.380 eV, respectively (FIGS. 5A to 5C). These results suggest that POMs substituted with W, Mo and W/Mo alloy can effectively mediate the redox reaction between Pb⁰ and I⁰ (FIG. 6). The proposed electron shuttling mechanism is illustrated in FIG. 7: Pb⁰+POM(M⁶⁺)→Pb²⁺+POM(M⁵⁺); POM(M⁵⁺)+I⁰→POM(M⁶⁺)+I⁻.

To assess the effectiveness of electron transfer, POM, Pb⁰ and I⁰ powders were dispersed in a mixed solvent of dimethylformamide and isopropanol (1:10 volume ratio) by balancing the solubility of the raw powders and the precipitation of the resulting PbI₂. The formation of PbI₂ (FIGS. 8A to 8C) under these reaction conditions confirms that the electron shuttling reaction is thermodynamically favorable, driven by negative Gibbs free energy (ΔG). Further discussion on the reaction kinetics, particularly the impact of metal substitution in POMs, will be provided in the subsequent section.

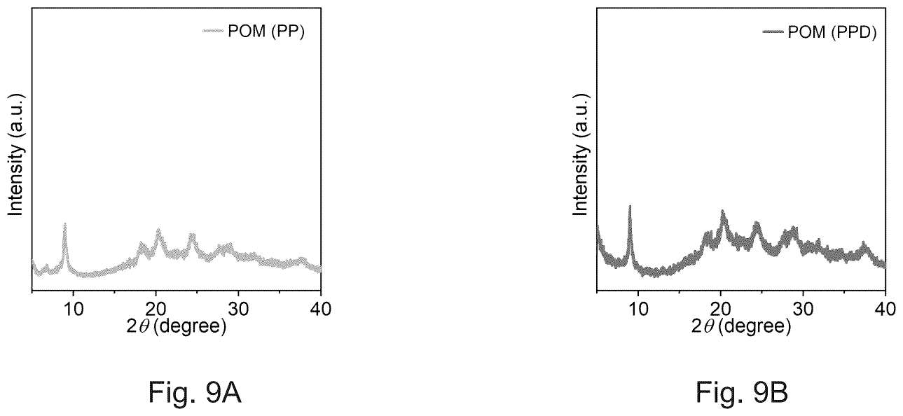

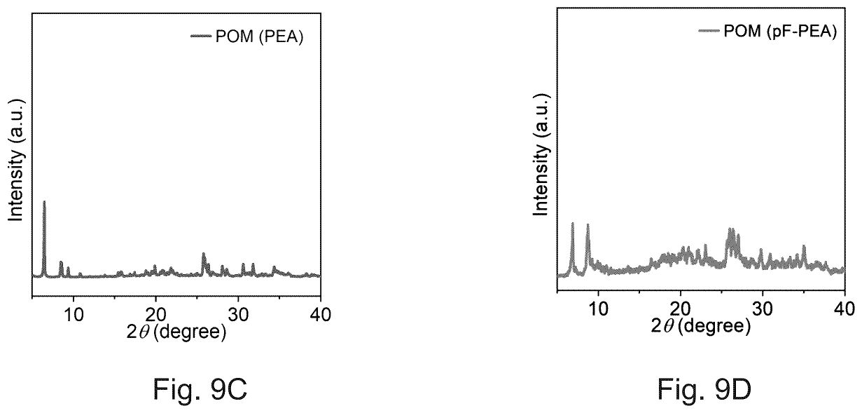

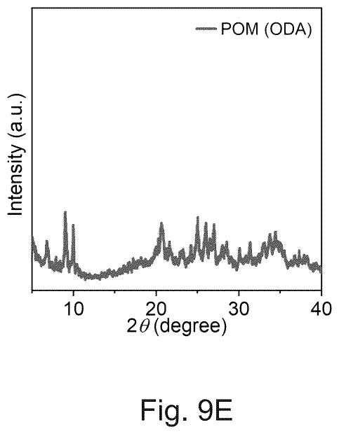

Without wishing to be bound by theory, it is believed that by substituting the H⁺ cation in POMs with functional ammonium cations, it may enhance perovskite structure through chemical and field-effect passivation, thereby suppressing interfacial charge recombination and improving perovskite stability. On this basis, various monoammonium and diammonium ligands were selected for chemical passivation (piperidinium, PPD; phenethylammonium, PEA; 4-fluorophenylammonium, 4F-PEA) and field-effect passivation (piperazinium, PP; octamethylenediammonium (ODA) to modify the cationic component of POMs. These functionalized POMs were synthesized (FIGS. 9A to 9E) starting with H₃PW₁₂O₄₀ and applied to the buried surface of the perovskite layer, enhancing defect passivation and structural stability of the perovskite on the light-incident surface. Optionally, as discussed in the later part of the present disclosure, the functionalized POMs may be applied within the bulk perovskite.

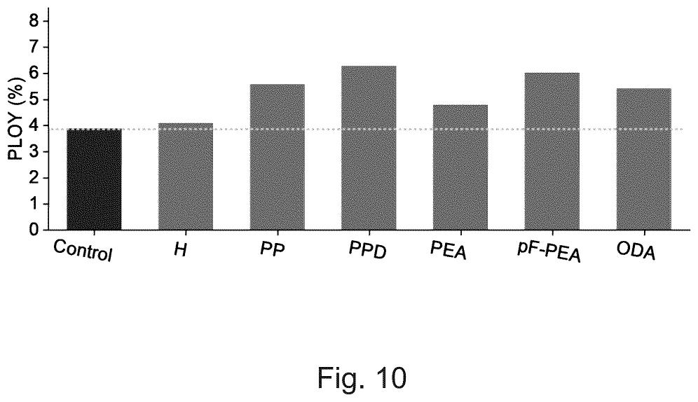

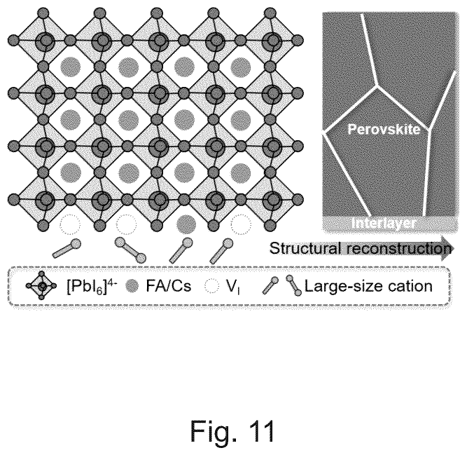

Photoluminescence quantum yield (PLQY) measurements were conducted to evaluate the effectiveness of functional POMs in structural passivation (FIG. 10). A self-assembled monolayer (SAM)-coated glass served as the reference substrate. The PLQY value of the perovskite film on the H₃PW₁₂O₄₀-capped substrate slightly exceeded that of the film on the reference substrate (4.1% vs 3.9%), suggesting that the abundant metal-oxidate framework in POM interacts with [PbI₆]⁴⁻, reducing non-radiative recombination at the buried surface and improving film quality. Functional POMs with ammonium cation further improved the PLQY of the perovskite films on the H₃PW₁₂O₄₀-capped substrate, indicating that the improved film quality likely results from the interaction between cationic component of POMs and the perovskite layer (FIG. 11). These findings suggest that structurally tailored POMs are effective in facilitating electron shuttling between Pb⁰ and I⁰ defects to repair decomposed [PbI₆]⁴⁻ unit and in forming a robust interlayer to stabilize the [PbI₆]⁴⁻ framework. POM-reinforced perovskites are expected to show increased resistance to external forces that cause non-equilibrium phase degradation. The related mechanism behind this stability will be discussed in the following section.

### Example 2

### Enhanced Control of POM-Mediated Electron Shuttling for Stable Perovskites

It is believed that redox mediators may be particularly suitable in mitigating deep-level Pb⁰ and I⁰ defects in [PbI₆]⁴⁻ unit. To explore the POM-mediated electron shuttling and the effectiveness of the redox mediators to reinforce the perovskite structure, focus was made on the H-terminated POM in this part of discussion (i.e., isolating the effect of cation substitution in POM in this part of discussion).

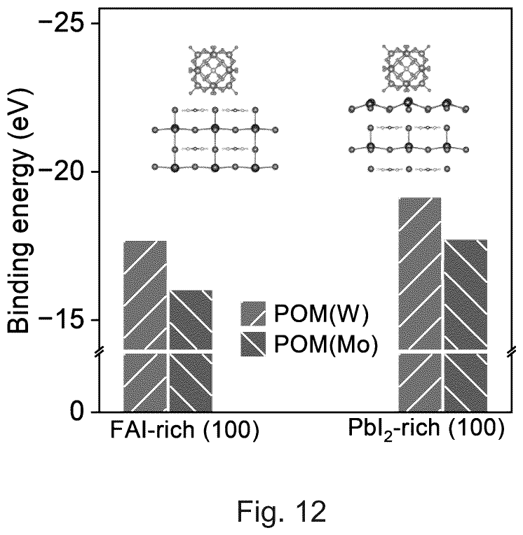

Density functional theory (DFT) calculations were performed on POM/perovskite interfacial models with FAI- and PbI₂-rich (100) termination to identify the reaction sites (FIG. 12). The lower binding energy of POM at the PbI₂-rich termination compared to the FAI-rich termination suggests potential reaction sites between POM and the exposed PbI₂-rich surface in defective perovskite structures, indicating POM's targeted binding to PbI₂-rich surfaces that commonly initiate the formation Pb⁰ and I⁰ defects under external forces.

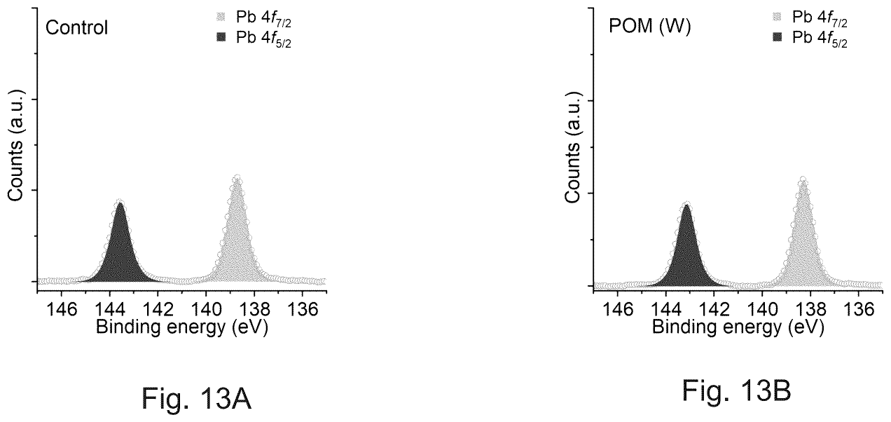

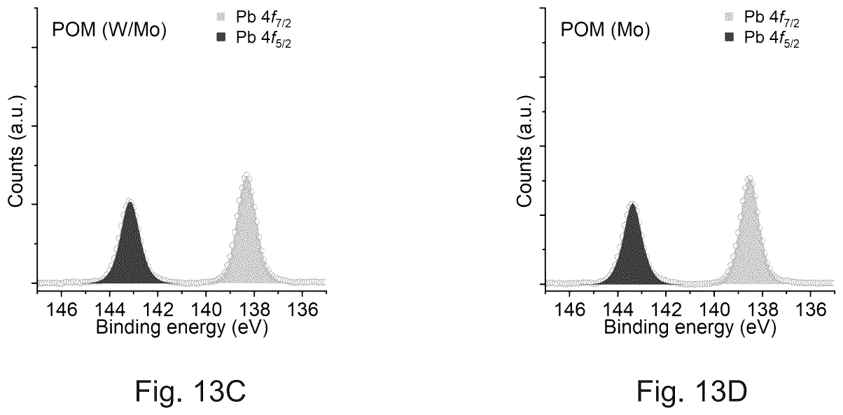

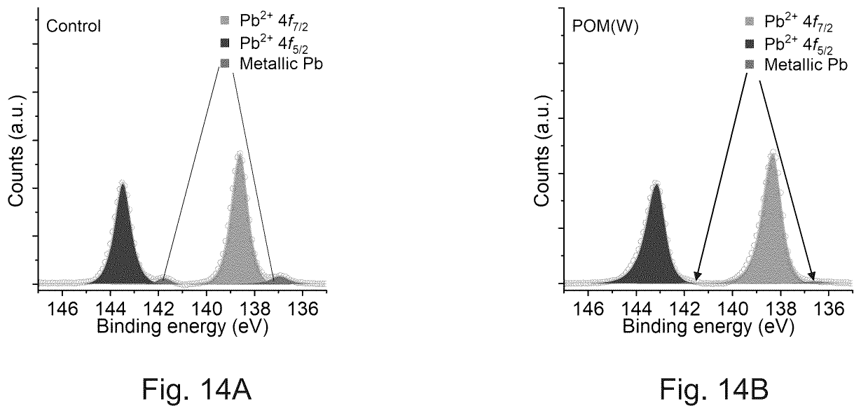

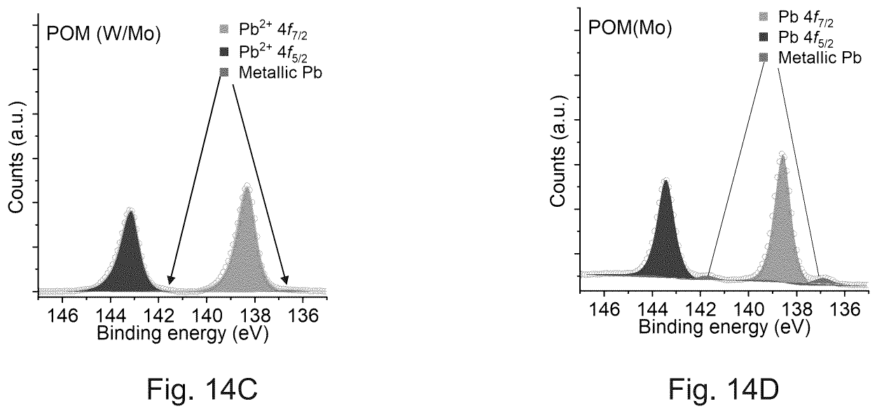

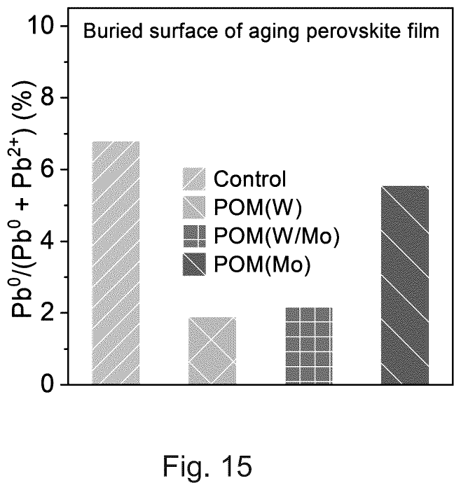

The effectiveness of POMs in stabilizing perovskite films was evaluated by depositing the films onto SAM or POM/SAM substrates. Aged films were analyzed using X-ray photoelectron spectroscopy (XPS) to measure the Pb⁰ concentration on the buried surface. I⁰ species was excluded from the analysis due to its volatility, which can lead to inaccurate measurements. While the original perovskite films showed high quality with minimal detected Pb⁰ defects (FIGS. 13A to 13D), varying levels of Pb⁰ defects were observed in the aged films. All POM variants reduced the Pb⁰ formation in aged films compared to the perovskite film on the SAM substrate, as evidenced by the residual Pb⁰ levels (FIGS. 14A to 14D). Among them, the W-substituted POM was the most effective in preventing the Pb⁰ defects within the [PbI₆]⁴⁻ unit during aging (FIG. 15). Although all POM mediators with redox potential between E⁰(Pb⁰/Pb⁺) and E⁰(I⁰/I⁻) were thermodynamically favorable for targeting these targeted defects, their effectiveness in mitigating defects varied. Therefore, selecting suitable redox mediators based on their redox potential and defect repair capacity is crucial.

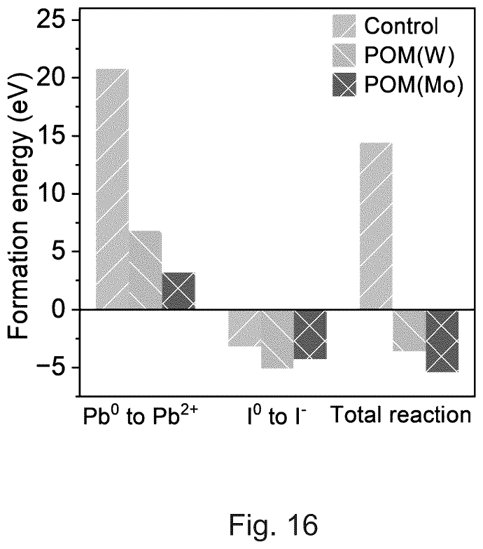

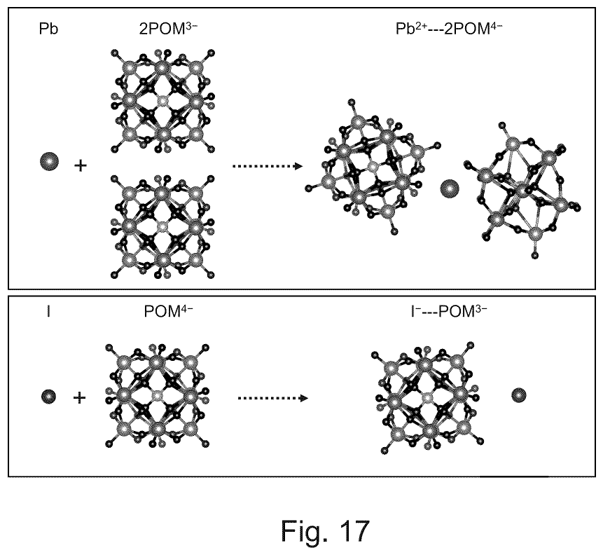

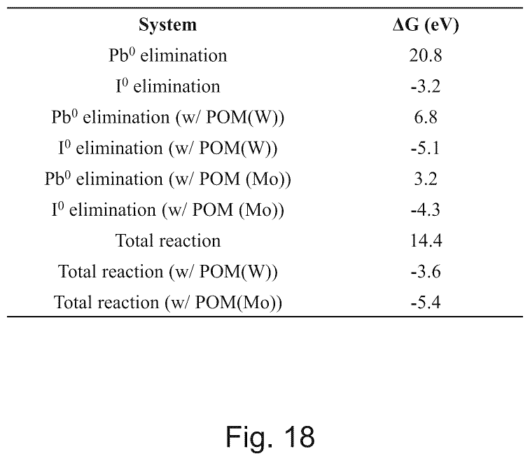

To understand the differences in POM-mediated electron shuttling reaction in defective [PbI₆]⁴⁻ unit, thermodynamic calculations simulating the direct reaction of Pb⁰ and I⁰ species were first conducted. POMs with W and Mo substitutions, representing low and high redox potentials, respectively, were selected. The calculated AG for the half-reactions (FIGS. 16 to 18) illustrated that the redox capacity of POM effectively lowers the formation energy for both ΔG (Pb⁰→Pb²⁺) and to ΔG (I⁰→I⁻), thereby facilitating the electron shuttling. However, the lower reaction energy with POM(Mo) was inconsistent with its limited capacity to mitigate targeted Pb⁰ defects (FIG. 15), suggesting that this defect elimination process is not governed by thermodynamic constraints.

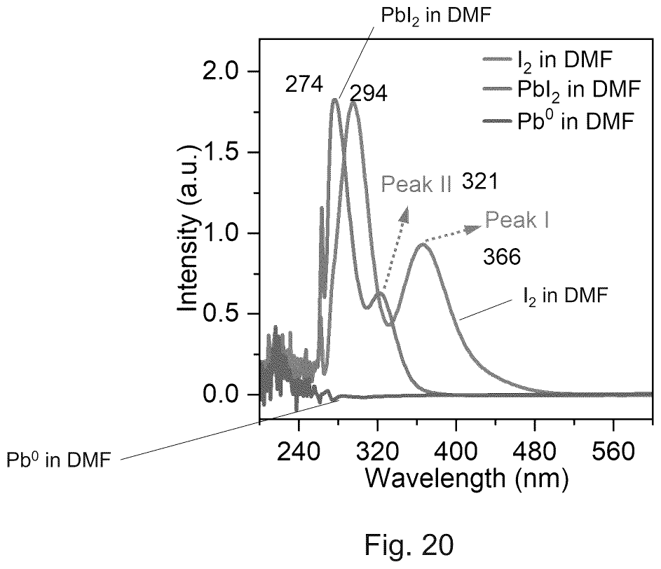

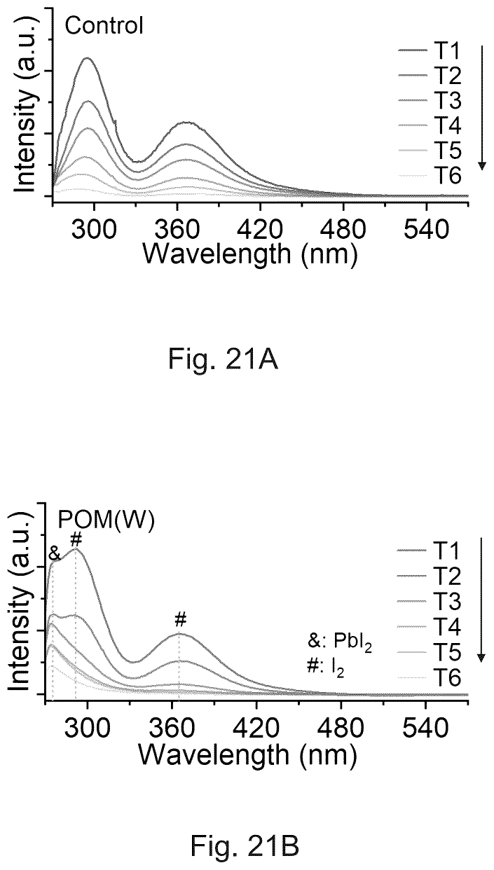

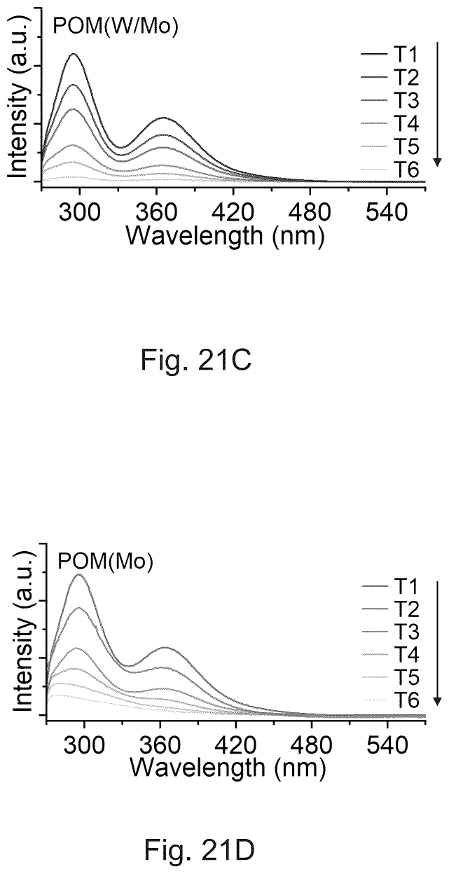

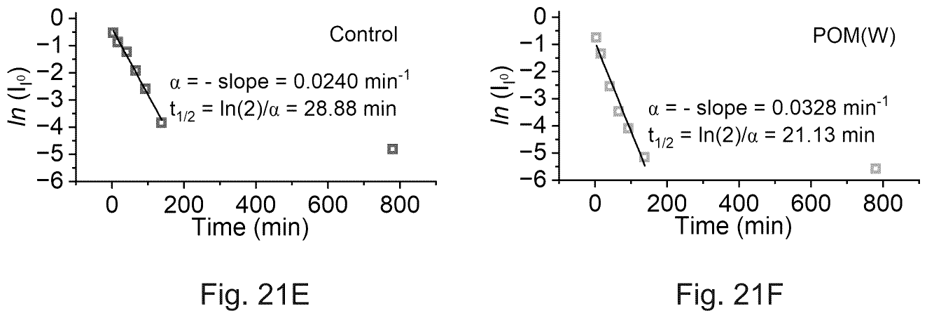

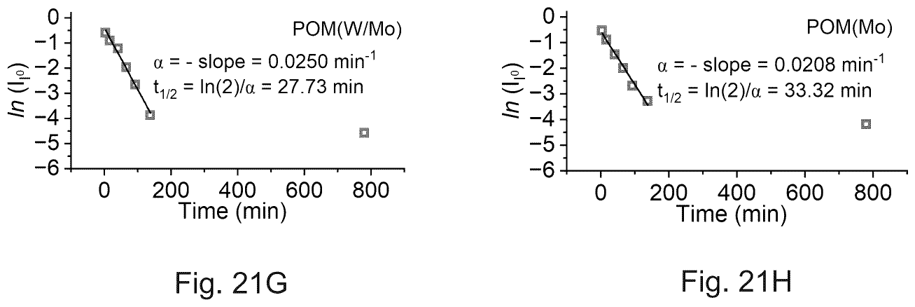

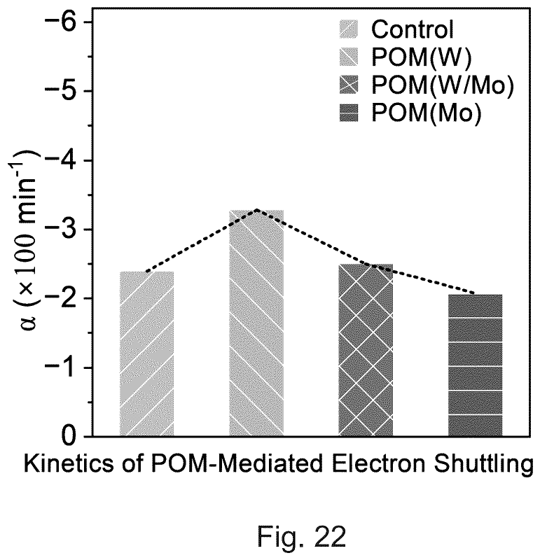

The reaction kinetics was further investigated by monitoring the evolution of I⁰ concentration in suspension solutions with the addition of Pb⁰, I⁰ and POM powders. All reactions reached completion after sufficient time, though at different rates (FIG. 19). The reaction followed first-order exponential decay kinetics, described by the equation I=I₀e^{-αt}, where a represents the reaction rate coefficient (units of 1/time) and I₀ denotes the initial concentration of I⁰ species (FIGS. 20 and FIGS. 21A to 21H). The calculated a values (FIG. 22) revealed that W-substituted POM has the highest reaction rate in facilitating electron shuttling. In contrast, POM mediators with Mo or Mo/W substitutions did not significantly enhance the reaction kinetics, resembling the control case. These kinetic results align the capacity of POMs to mitigate defect formation in aged perovskite film, indicating POM-mediated electron shuttling is kinetically controlled.

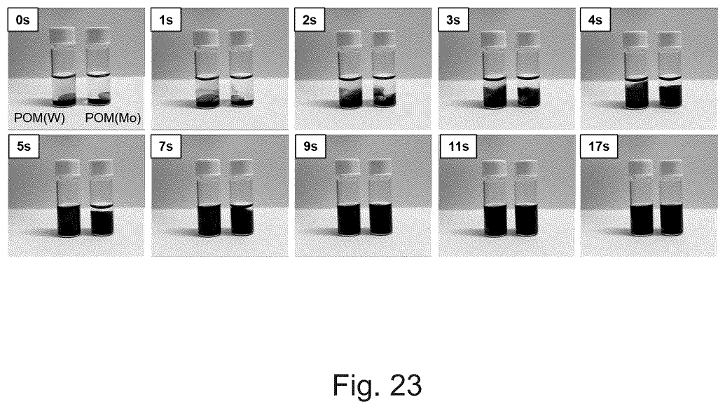

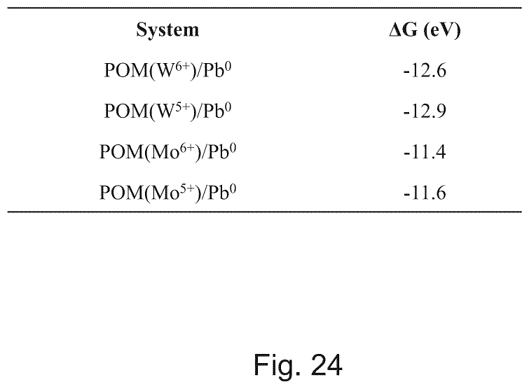

The half-reactions were examined separately to uncover difference in kinetics, with the oxidation of Pb⁰ occurring before the subsequent reduction of I⁰ during electron shutting. Although POM(Mo) has a higher reduction potential than POM(W), the addition of Pb powders to both POM(W) and POM(Mo) solutions resulted in a rapid color change from colorless (M⁶⁺ ion) to blue (M⁵⁺ ion) within a few seconds (FIG. 23). The faster electron shuttling rate in the Pb⁰/POM(W) system is possibly due to its stronger binding interaction compared to POM(Mo) case (FIG. 24). The similar reaction kinetics suggest that the reduction of I⁰, rather than the oxidation of Pb⁰, is the rate-limiting step in the POM-mediated electron shuttling process.

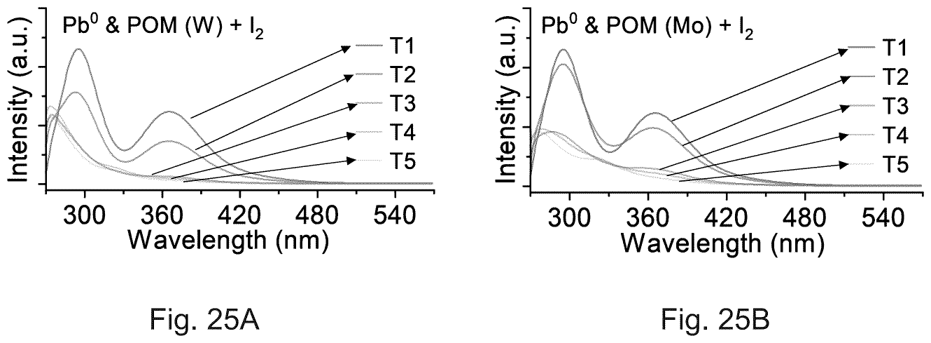

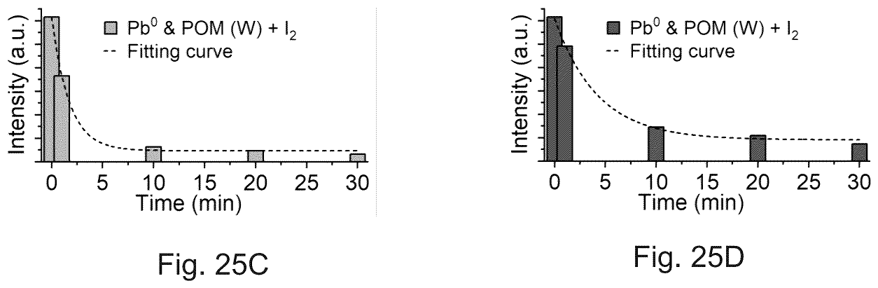

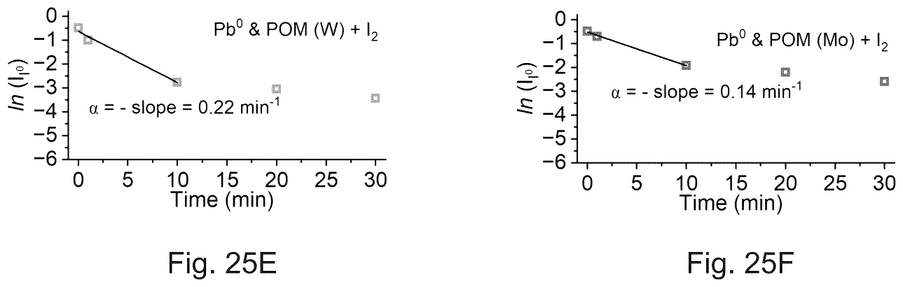

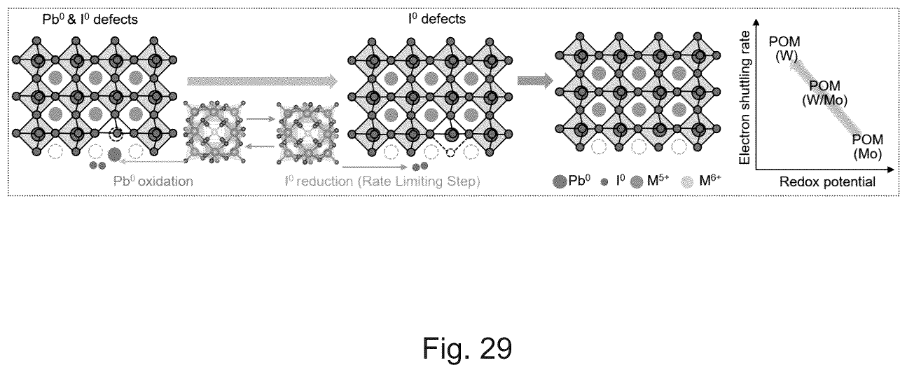

To further investigate, I₂ powders were introduced into the POM solutions containing Pb powders that had reacted for several minutes. The higher reaction rates observed with POM(W) compared to POM(Mo) showed that the I₂ reduction is critical in completing the electron shuttling process (FIGS. 25A to 25F). Thus, a redox mediator with a greater driving force for I₂ reduction is advantageous. Among the Keggin-type POM studied, W-substituted POM shows promise in effectively suppressing the formation of Pb⁰ and I⁰ defects in the [PbI₆]⁴⁻ unit in aged films (FIG. 29), owing to its favorable reaction kinetics.

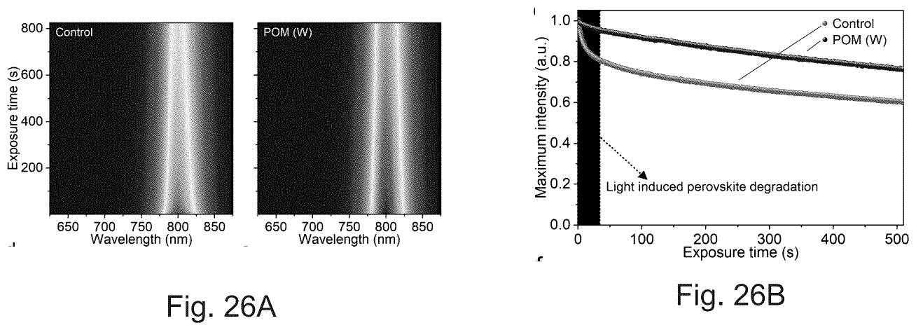

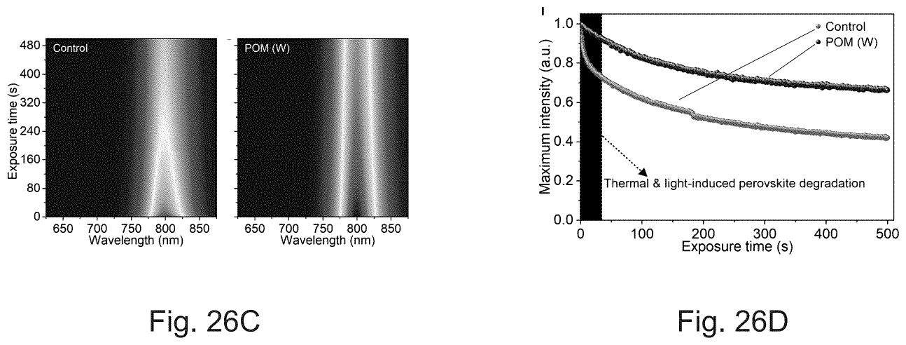

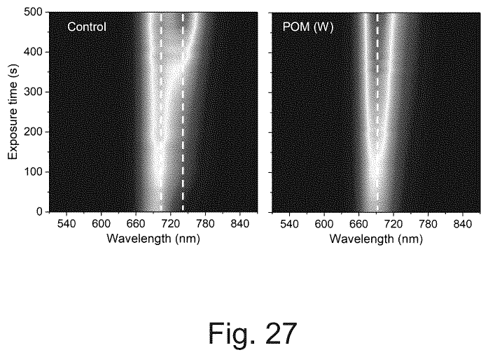

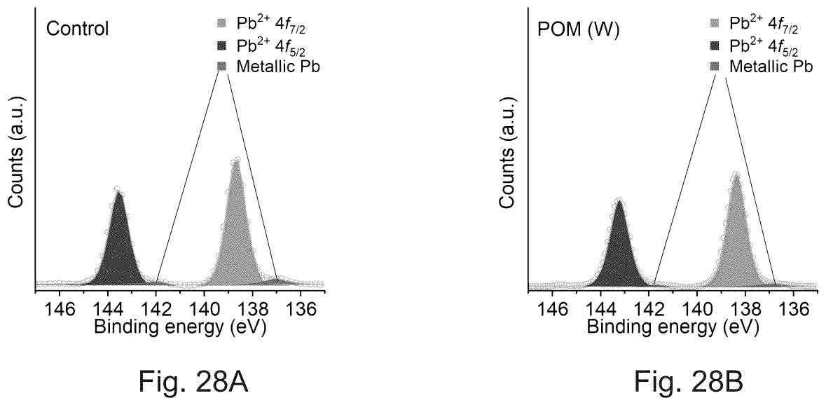

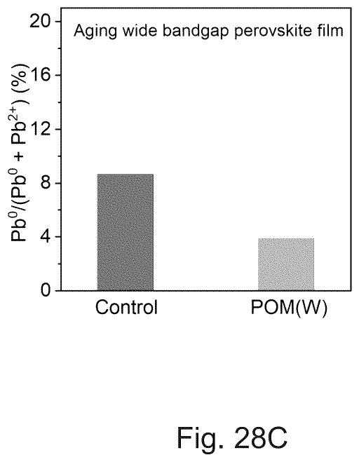

The stability of perovskite films deposited on different substrates was evaluated through continuous laser illumination at room temperature and heating at 85° C. (FIGS. 26A to 26D). The control sample showed a rapid decline in PL intensity at 800 nm, illustrating the gradual degradation of [PbI₆]⁴⁻ units within the perovskite phase. Conversely, the POM mediator effectively stabilized the perovskite structure through its well-designed electron shutting mechanism. The mechanism also suppressed phase segregation in Br/I mixed perovskite structure. Specifically, phase segregation in wide bandgap perovskite films (1.78 eV) could be effectively mitigated by the redox-active POM mediator (FIG. 27). Additionally, aged perovskite film grown on POM substrate showed fewer Pb⁰ defects compared to the control sample (FIGS. 28A to 28C). These findings indicate that functional POMs, particularly W-substituted POMs with effective electron-shutting capabilities, can mitigate deep-level defects of [PbI₆]⁴⁻ units in non-equilibrium states, thereby stabilizing the perovskite phase. However, vacancy defects in A-site cations remain a concern, as illustrated in FIG. 29. It is believed that said vacancy defects may be addressed by the functionalized cation in W-substituted POM structures as discussed in the following part of the present disclosure.

### Example 3

### Promoted Cation Exchange in POMs for Structurally Passivated Perovskites

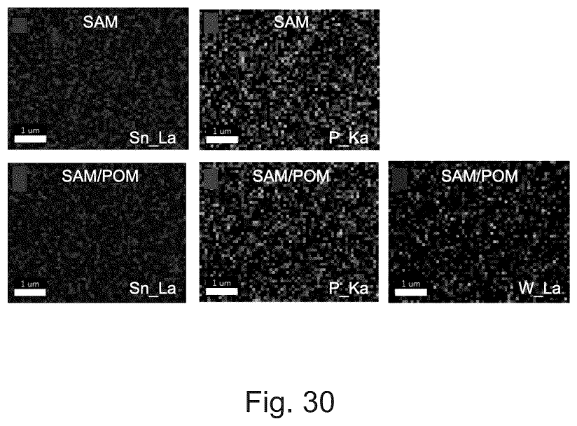

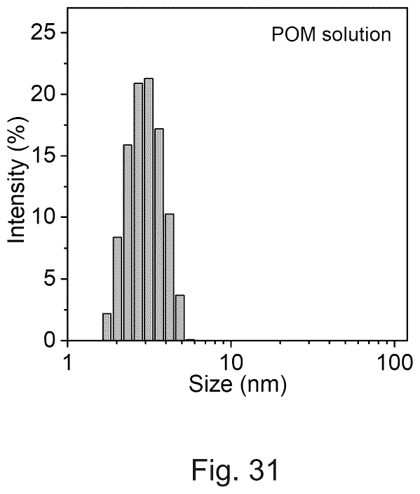

The discussion centers on enhancing the interaction between POMs and perovskites to stabilize the perovskite phase through cation exchange reaction within the POM structure. Before delving into this, the component distribution pattern of the SAM/POM composite was investigated. A POM containing W⁶⁺ metal ions and PPD²⁺ counter cations was selected due to W's rapid electron shuttling ability (as shown in FIG. 29) and PPD cation's defect passivation capability (as seen in FIG. 10). The POM solution was applied to the SAM-covered ITO substrate, and energy-dispersive X-ray spectroscopy (EDS) elemental mapping was conducted (FIG. 30). The observation of fragmented pinholes in the P signal from the SAM film illustrated incomplete coverage of SAM onto the ITO substrate, which worsened slightly after POM deposition, possibly due to partial desorption of SAM during solution processing. These voids could be effectively filled by nano-sized POMs (FIG. 31) to form an intercalated SAM/POM pattern rather than a bilayer configuration, as suggested by the disordered distribution of W element in the SAM/POM sample.

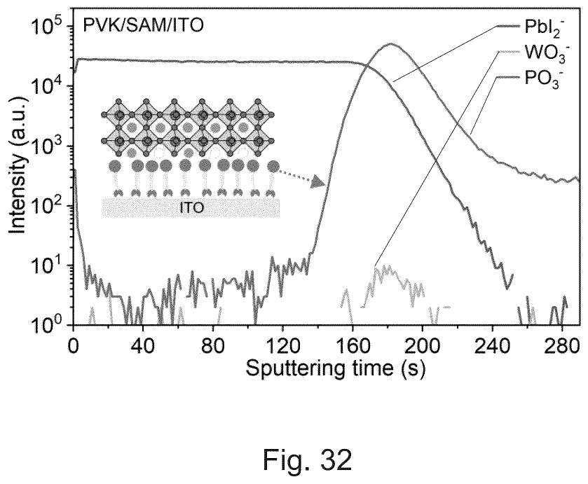

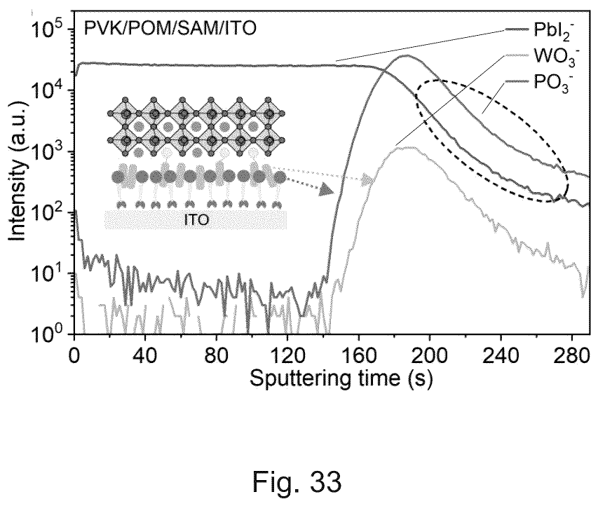

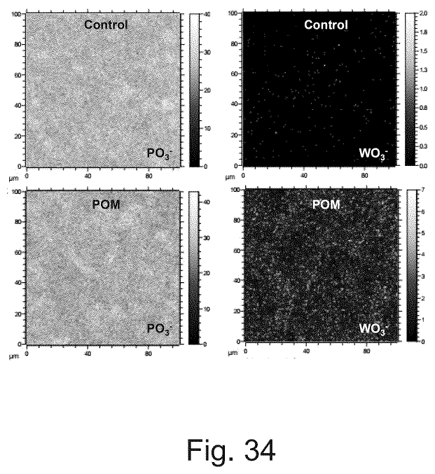

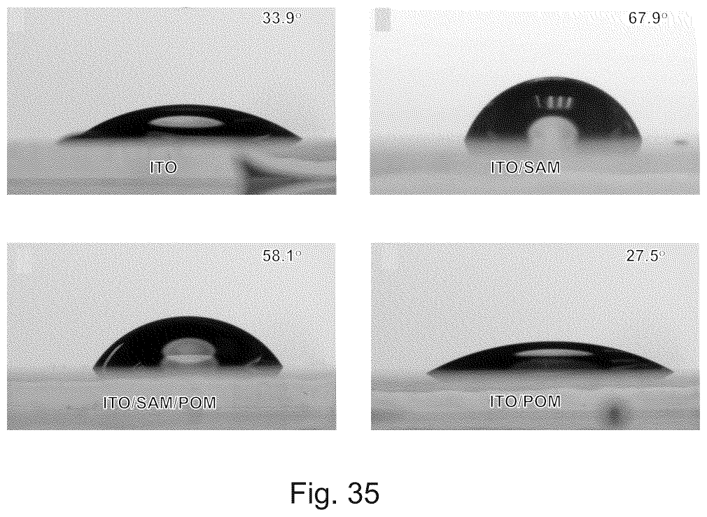

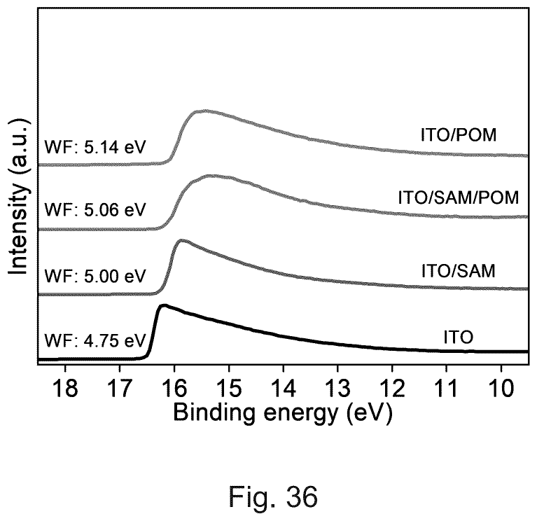

Depth-dependent ToF-SIMS analysis (FIGS. 32 and 33) revealed that the WO₃⁻ and PO₃⁻ signals (representing POM and SAM, respectively) appeared almost simultaneously, confirming the intercalation of POMs into the SAM film to form an intercalated SAM/POM pattern. The uneven distribution of the WO₃⁻ signal in the SAM/POM substrate suggests incomplete POM coverage on the SAM layer (FIG. 34), which does not hinder the contact between the perovskite and SAM layer. The intercalated POM/SAM pattern was further supported by alterations in contact angle (FIG. 35) and work function measurements (FIG. 36), with values positioned between those of the ITO/SAM and ITO/POM configurations. This intercalated structure allows POM to effectively fill voids in the SAM film, thereby stabilizing it against solvent erosion during the perovskite layer's solution processing.

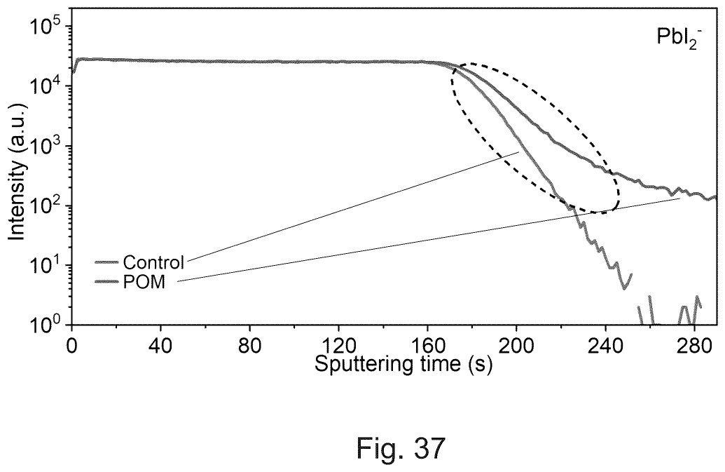

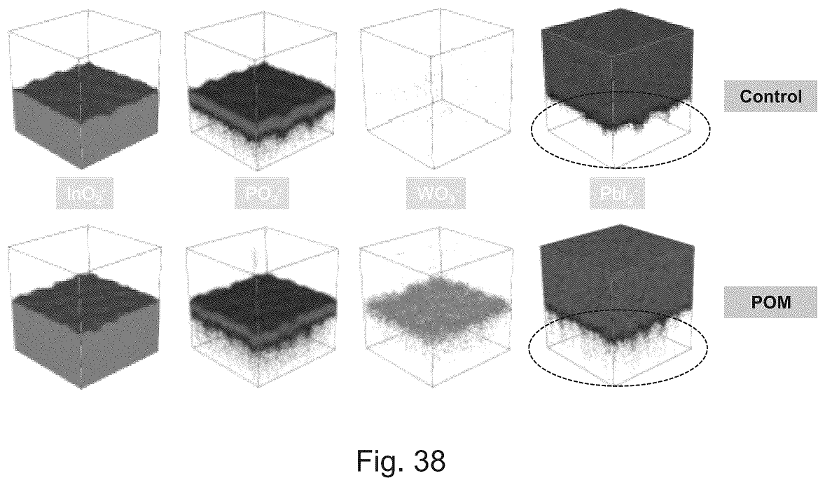

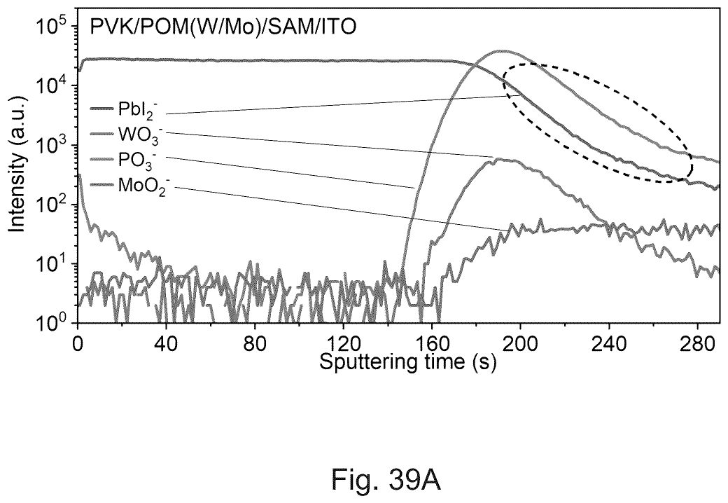

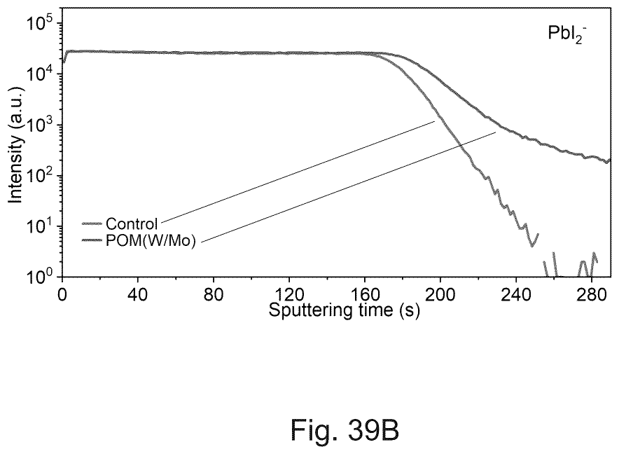

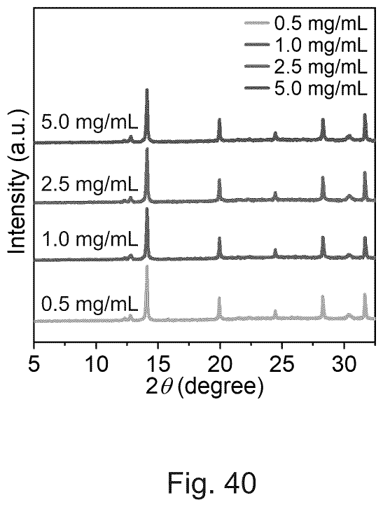

Notably, a significant difference in the perovskite signal (PbI₂⁻) was observed between the ITO/SAM/PVK and ITO/SAM/POM/PVK samples, as indicated by the dashed line in FIGS. 32 and 33. Compared to the control, the slower decrease in the PbI₂⁻ signal near POM in the ITO/SAM/POM/PVK sample suggests an interaction between the perovskite and POM, leading to the formation of an interlayer at the buried interface (FIGS. 37 and 38). Similarly, a delayed signal of PbI₂⁻ was observed when perovskite was deposited on the SAM/POM substrate with POM containing mixed W and Mo metals (FIGS. 39A and 39B). However, increasing the concentration of POM solutions during deposition did not yield additional signals from perovskite-POM adducts (FIG. 40).

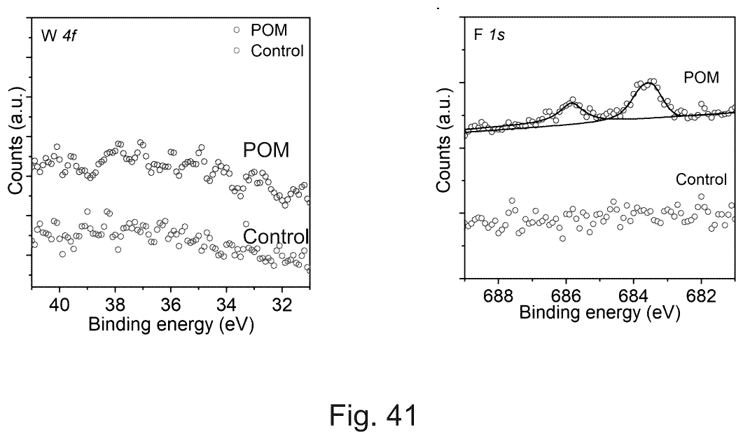

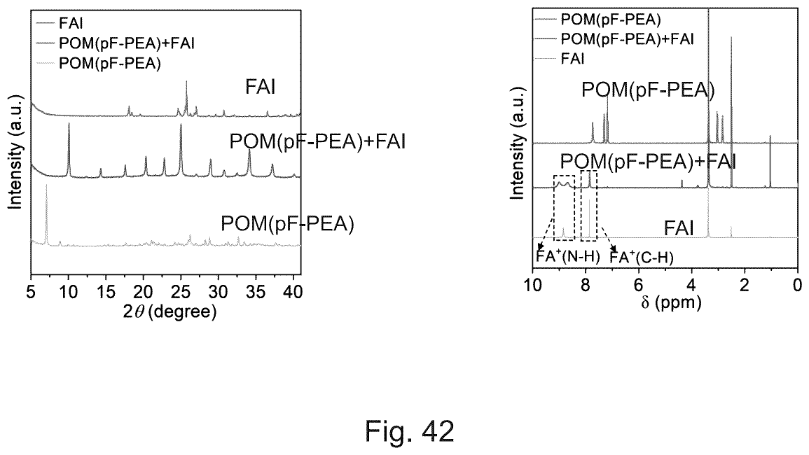

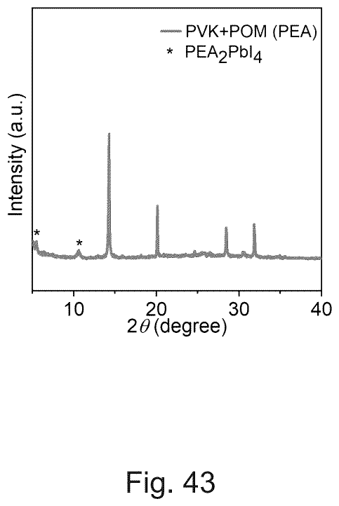

To investigate this interaction, experiments were conducted using POMs with different cations: (1) peeling off the buried perovskite surface from the SAM/POM(4F-PEA) substrate for XPS measurement revealed an F signal without any W signals, suggesting that the 4F-PEA⁺ cation potentially reacted with perovskite and integrated into its lattice (FIG. 41); (2) stirring a dispersion of POM(4F-PEA) and FAI powders produced a new component distinct from the original reactants, with ¹H NMR revealing that a significant amount of FA⁺ cation replaced the 4F-PEA⁺ cation in the POM(4F-PEA) structure (FIG. 42); (3) adding POM(PEA) to the perovskite precursor solution during film preparation led to the formation of low-dimensional PEA₂PbI₄ (FIG. 43). These findings confirm cation exchange between and/or at perovskite/POM interface, leading to the formation of an interlayer that effectively passivates defects and heals the buried surface.

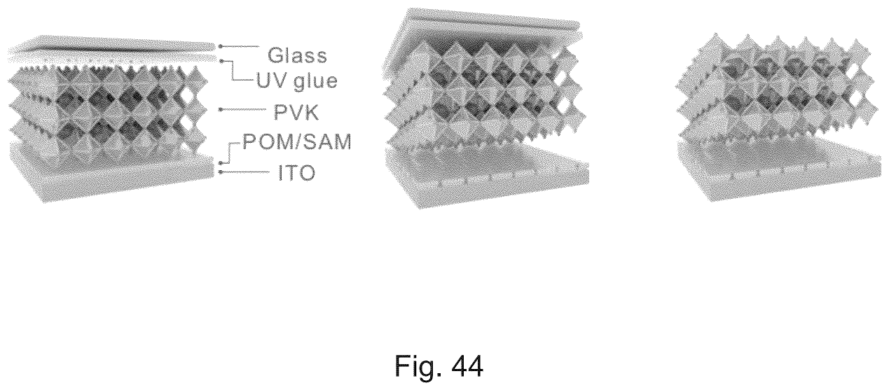

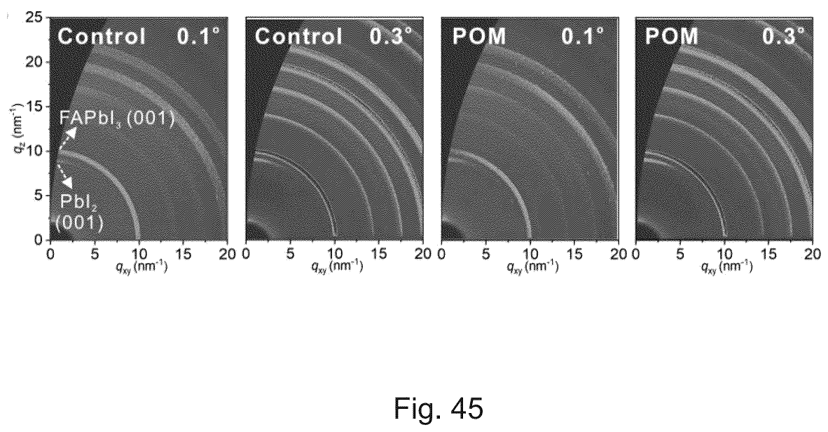

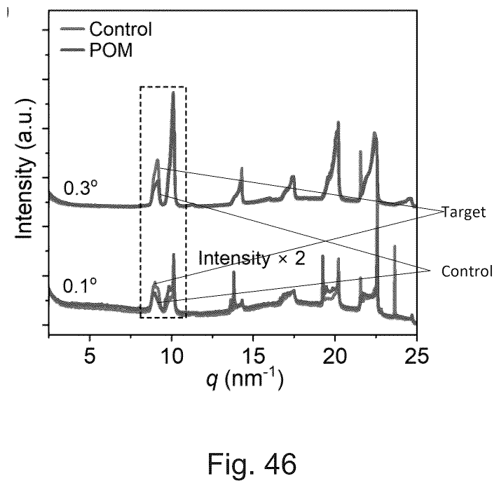

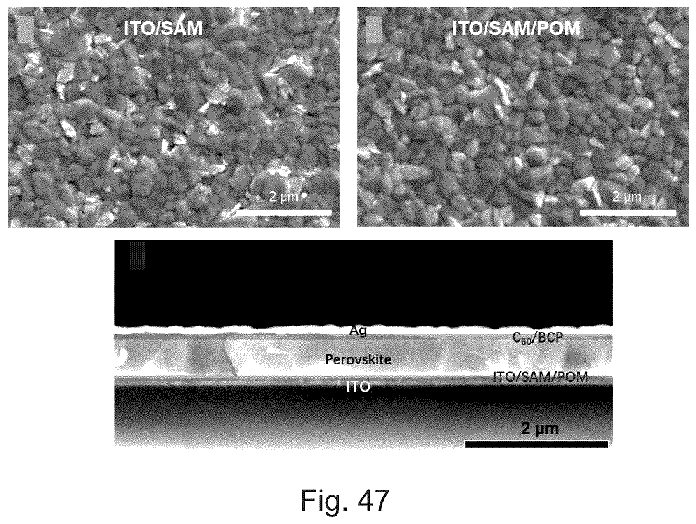

The interlayer formed between the substrates and perovskite films can potentially influence the quality of the films. To investigate this, perovskite films deposited on different substrates were peeled off and analyzed using grazing incidence wide-angle X-ray scattering (GIWAXS; FIG. 44) at two incident angles: 0.1° for surface analysis and 0.3° for bulk analysis. A significant distinction was observed in the Debye-Scherrer-like ring associated with the perovskite and PbI₂ phases (FIG. 45), and the diffraction patterns in the out-of-plane direction were compared. At the 0.1° incident angle, the PbI₂ intensity showed minimal variation, consistent with previous analyses. However, the (001) signal intensity of perovskite on the SAM/POM substrate was notably stronger than in the control sample, indicating that the formed interlayer at the buried interface facilitated the orientated growth of perovskite crystals (FIG. 46). Likewise, the enhanced crystal orientation in the bulk phase facilitated by the SAM/POM substrate resulted in a uniform and compact grain morphology on the top surface of the perovskite films (FIG. 47).

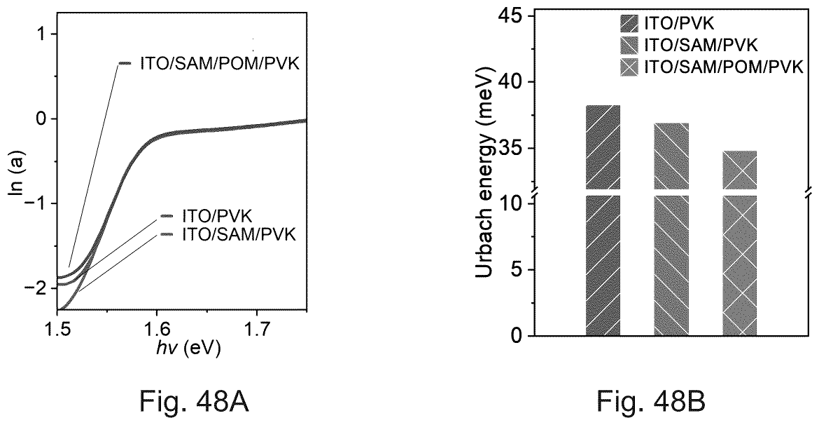

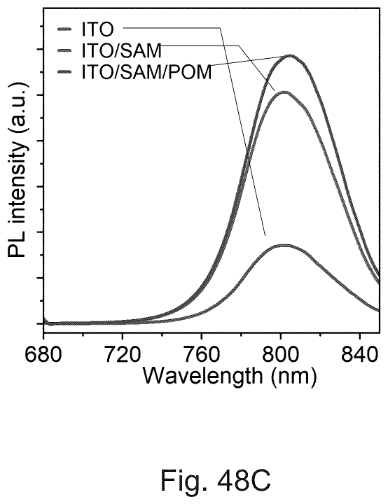

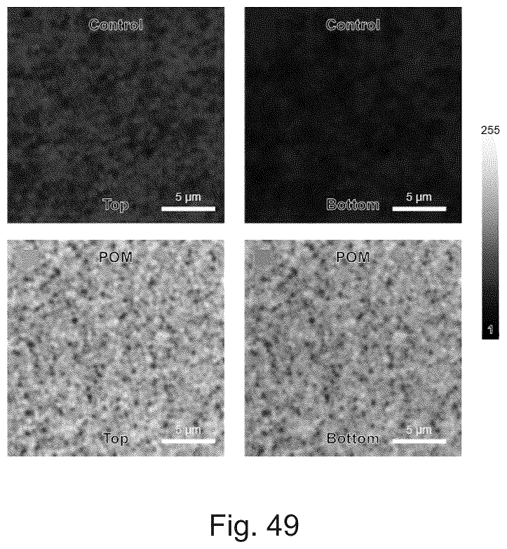

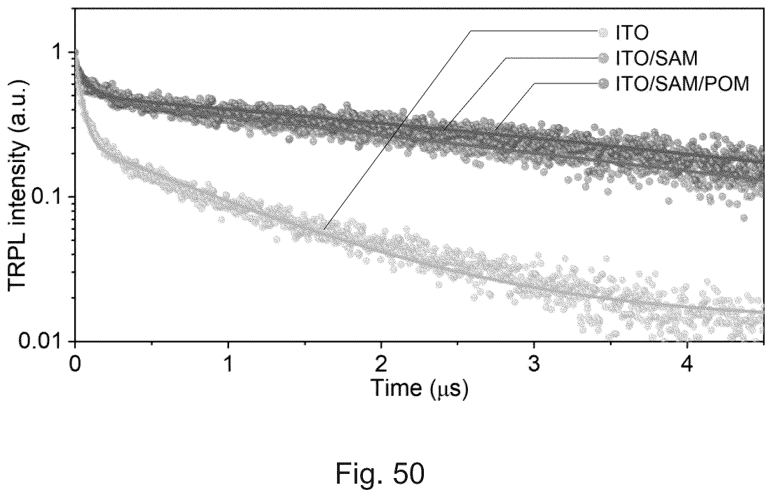

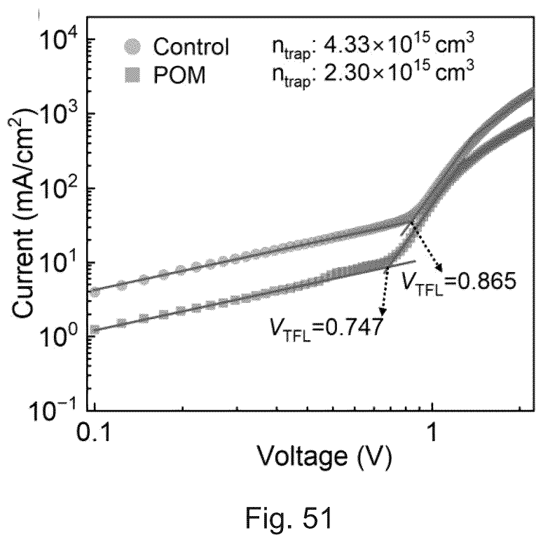

Furthermore, the perovskite film deposited on the SAM/POM substrate demonstrated a low level of energetic disorder at the band edge (FIGS. 48A to 48C). Spectral characterization showed that perovskite on the SAM substrate exhibited higher PL intensity compared to ITO, likely attributed to defect passivated by SAM functional groups. However, the formation of POM/perovskite interlayer on the SAM/POM composite augmented even higher perovskite fluorescence (FIG. 48C). Spatially distributed PL mapping showed that the perovskite film grown on the POM substrate had uniform PL intensity from bottom to top, outperforming the film grown on the SAM substrate (FIG. 49). The improved structural integrity and crystal quality of perovskite films were further supported by the longer carrier lifetime (FIG. 50) and reduced structural defects (FIG. 51).

Based on the analysis of POM's interaction with perovskite, it is believed that two key insights emerge regarding POM-reinforced perovskite phases: (1) the functional groups of POM cations can interact with perovskite to form a robust interlayer to effectively stabilize the [PbI₆]⁴⁻ framework at the buried surface; (2) the redox activity of the metal-oxide framework in POM facilitates electron shuttling, oxidizing Pb⁰ and reducing I⁰ defects generated during aging, thus stabilizing the [PbI₆]⁴⁻ framework in a non-equilibrium state. Therefore, it is believed that the application of POM offers a promising approach for achieving high-performance perovskite solar cells.

### Example 4

### POM-Enhanced Photovoltaic Performance in PSCs

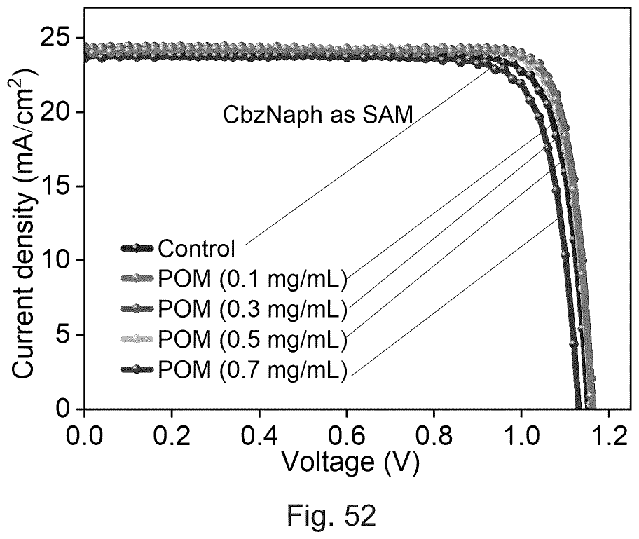

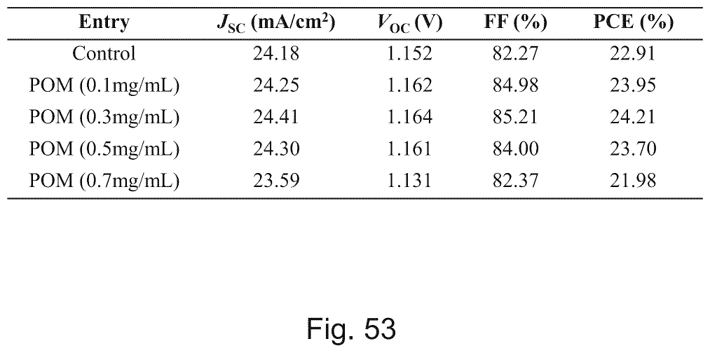

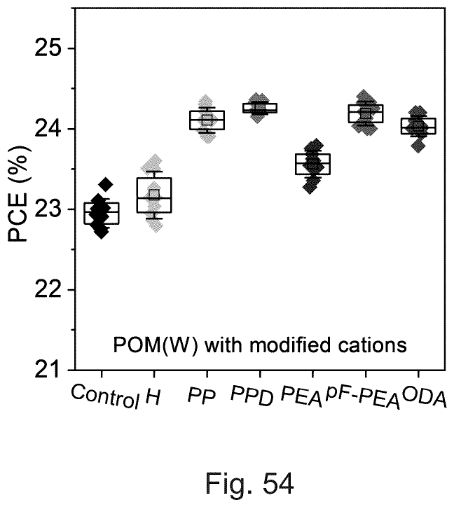

Inverted PSCs were fabricated using the device configuration of ITO/SAM/POM/Perovskite/C₆₀/bathocuproine/Ag to assess their photovoltaic performance, with a POM-free device as the reference. The concentration of POM was optimized (FIGS. 52 and 53), and the device performance with different POM variants is presented in FIG. 54.

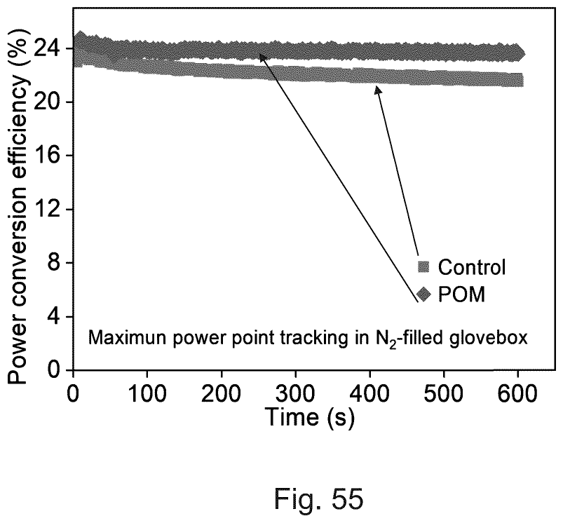

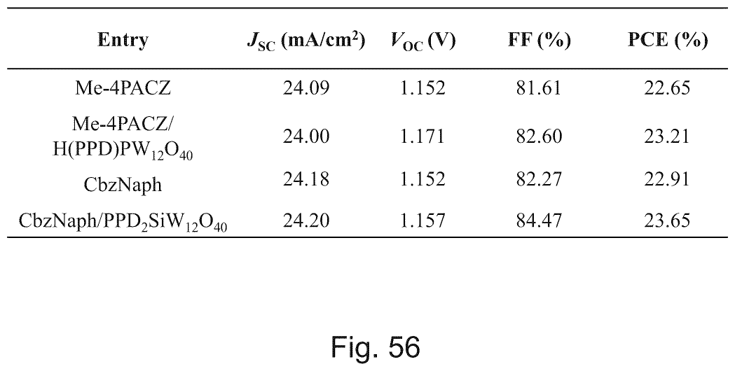

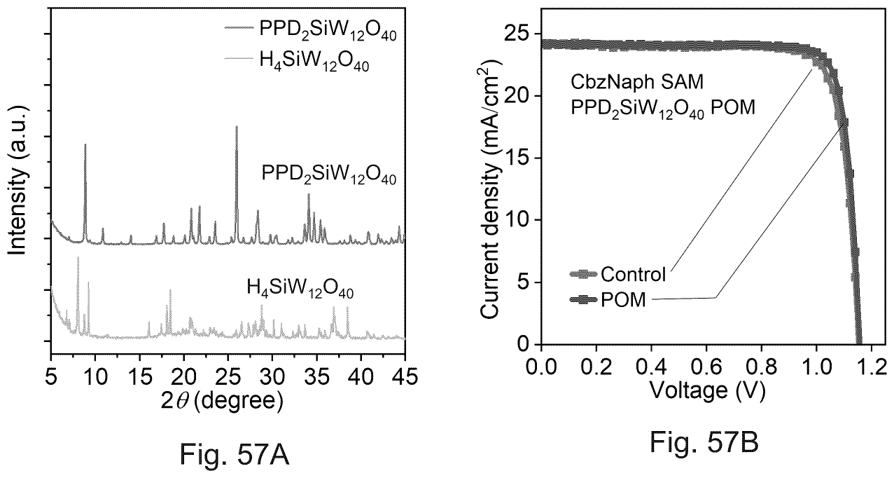

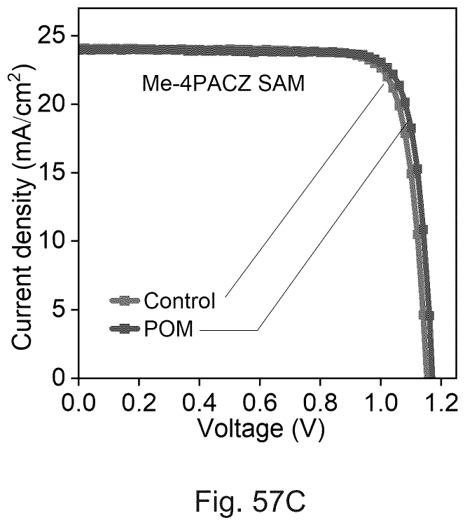

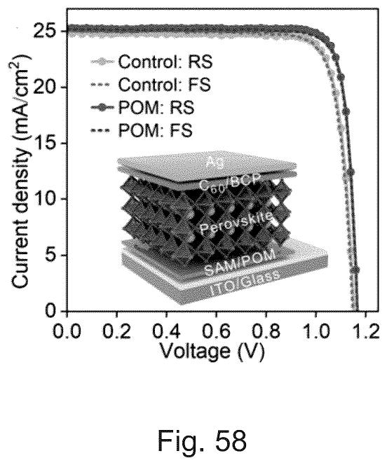

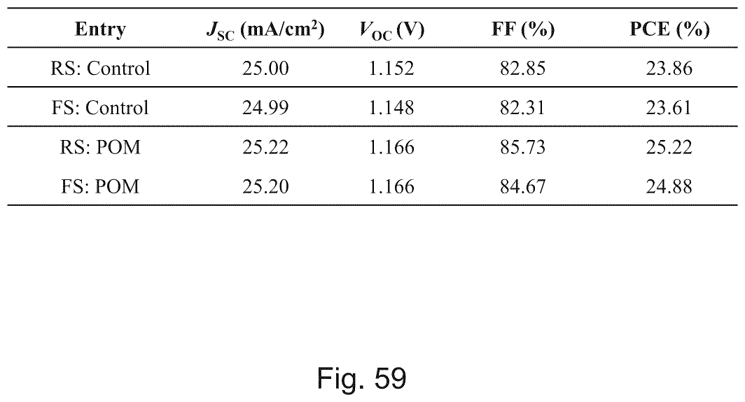

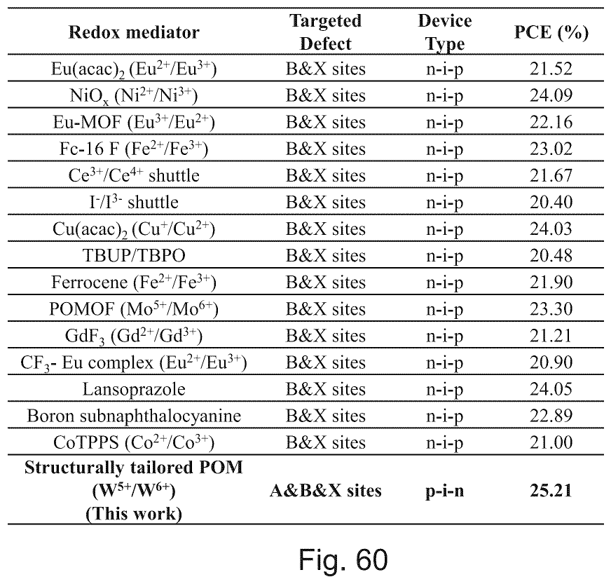

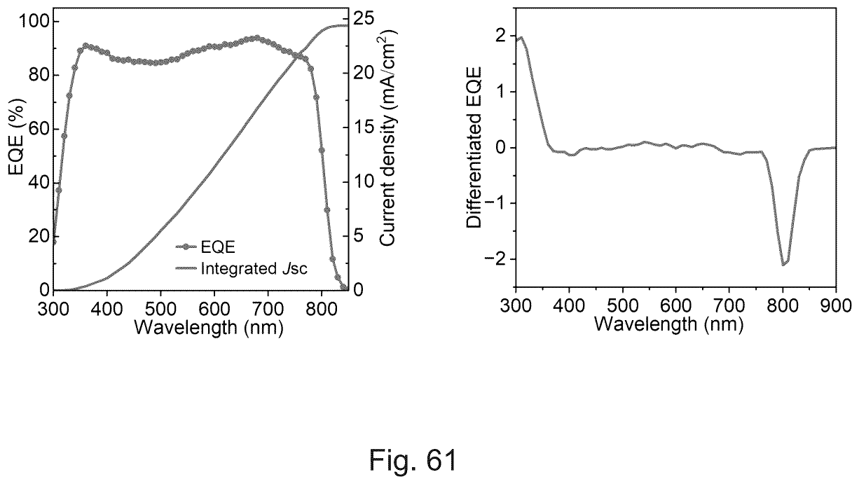

Devices with SAM, SAM/POM(H), SAM/POM(PP), SAM/POM(PPD), SAM/POM(PEA), SAM/POM(4F-PEA), and SAM/POM(ODA) substrates achieved performance values of 22.94±0.14, 23.21±0.23, 24.09±0.12, 24.26±0.07, 23.46±0.14, 24.21±0.10, and 24.04±0.10, respectively, demonstrating that the functional groups in POMs can effectively enhance device performance. The stabilized power output of the devices closely matched the PCEs obtained from J-V measurements (FIG. 55). The SAM/POM configuration also demonstrated broad applicability for enhancing device performance (FIG. 56). Specially, (1) incorporating silicotungstic acid with PPD²⁺ as a cation into the SAM charge-selective layer resulted in improved FF and PCE parameters compared to the control (FIGS. 57A and 57B); (2) a commercially available SAM (i.e., Me-4PACZ) combined with POM can outperform the pure SAM substrate (FIG. 57C). Further performance enhancement was achieved by adding an antireflective layer to the glass substrate and employing a bilayer passivation strategy. The champion device reached a PCE of 25.22% in reverse scan, with a V_{OC} of 1.166 V, J_{SC} of 25.22 mA/cm² and FF of 85.73% (FIGS. 58 and 59), marking the best performance for redox mediator-based PSCs (FIG. 60). The integrated photocurrent derived from the external quantum efficiency (EQE) spectrum closely aligned with the J-V measurements, and the perovskite bandgap was calculated as 1.55 eV using EQE derivative analysis (FIG. 61).

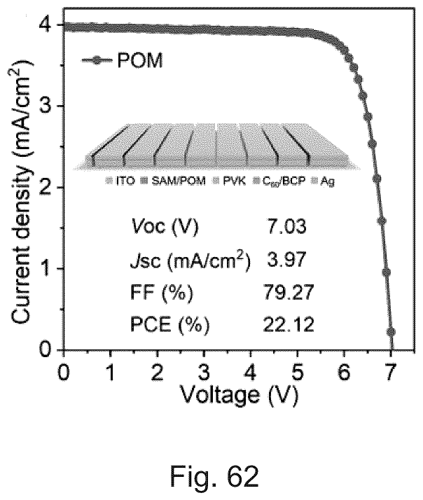

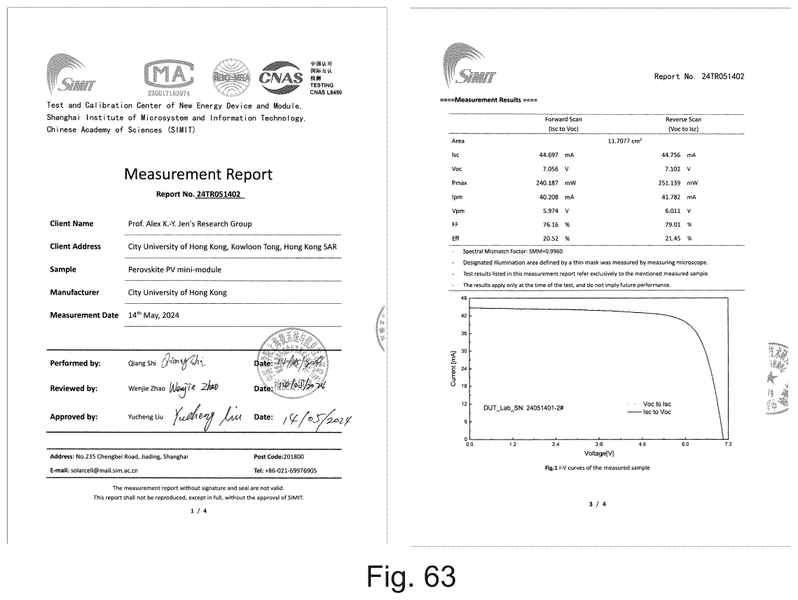

It is believed that depositing perovskite films on hydrophobic SAM substrates typically present challenges, often leading non-uniform films with numerous defects. However, the combined polarity and conductivity of POM with SAM not only significantly improves substrate coverage, but also effectively passivates perovskite defects at the buried interface to enable the achievement of high-performance perovskite solar modules. A perovskite mini-module (11.7-cm² aperture area) using SAM/POM configuration could achieve a high PCE of 22.12% (FIG. 62). This module was also certified through an independent photovoltaic certification laboratory to achieve a PCE of 21.45% (FIG. 63), representing state-of-the-art performance for inverted perovskite mini-modules.

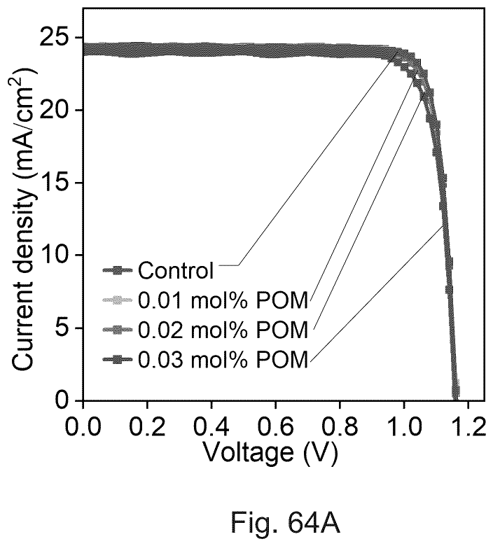

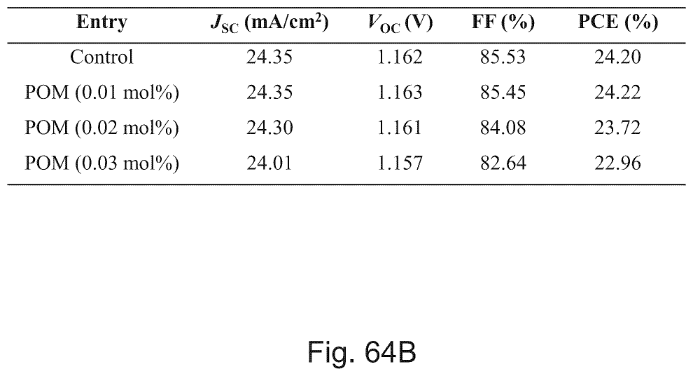

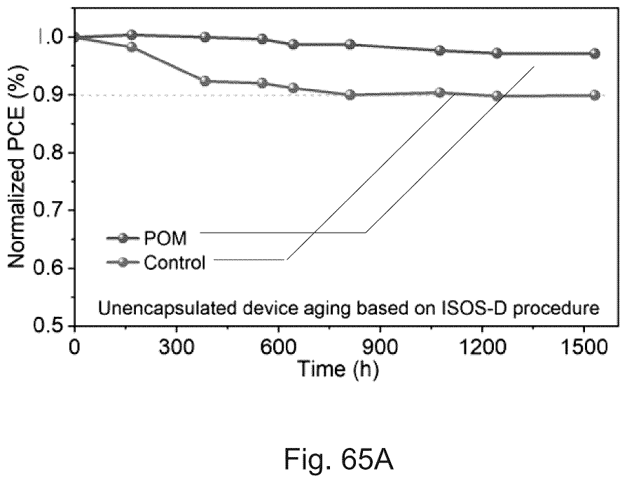

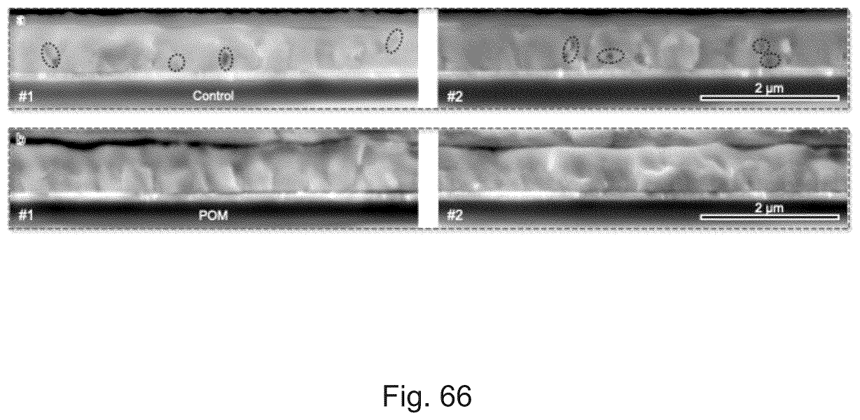

Furthermore, POMs can be incorporated into the perovskite precursor solution during film preparation to passivate defects and enhance device stability under harsh aging conditions (FIGS. 64A and 64B). Devices incorporating POM both at the buried surface and within the bulk, using ALD SnO₂ to replace the thermally unstable BCP as electron-transporting layer, were fabricated to test their stability (i.e., ITO/SAM/POM/Perovskite+POM/C₆₀/ALD SnO₂/Ag). The unencapsulated POM-based device could maintain 97.2% of its initial PCE after 1,500 hours of shelf-life testing at 65° C., compared to 90% of the control device (FIG. 65A). These devices were further encapsulated with UV-curable adhesive and subjected to more rigorous condition (continuous MPP tracking under 1-sun-equivalent LED illumination at 85° C.) (FIG. 65B). Although both the POM-based device and control device showed certain performance degradation during testing, likely due to electrode oxidation, erosion, ion migration (upward migration of I⁻ ion and the downward migration of metal ion), degradation of electron transport layer, and ineffective encapsulation, the POM-based device demonstrated much better stability. Notably, the encapsulated POM-based device could retain nearly 80% of its initial PCE after 495 hours, whereas the control device lost over 40% of its initial PCE after just 230 hours. Cross-sectional SEM images of aged devices revealed noticeable pinhole formation in the active layer of the control sample, while the POM-reinforced perovskite layer maintained better morphology (FIG. 66). These results underscore the advantage of functional POMs in enhancing film quality and stabilizing the perovskite structure.

### Example 5

### Applicability of Functional POMs in Different Bandgap Devices

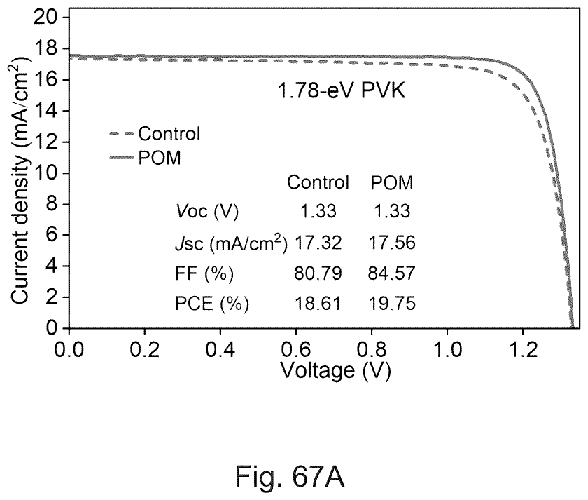

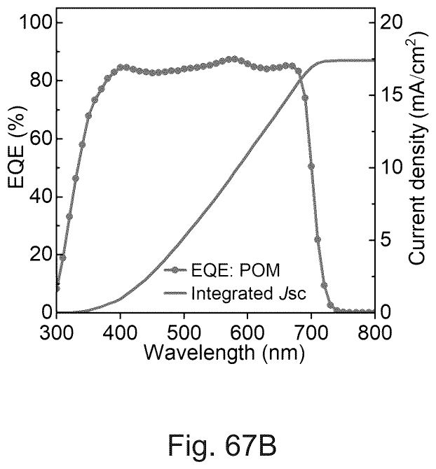

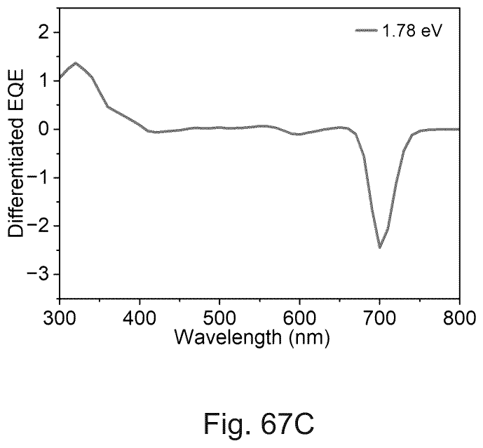

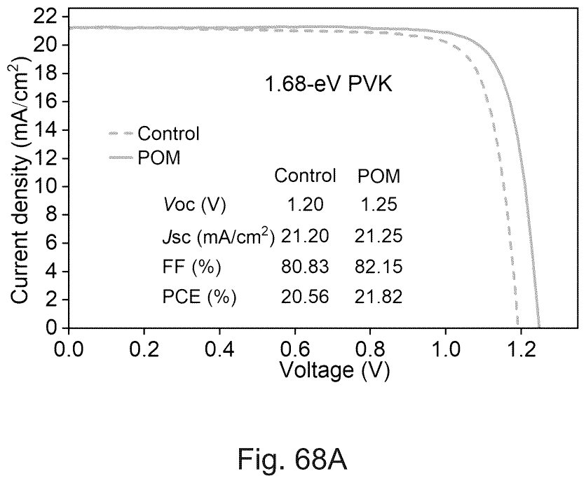

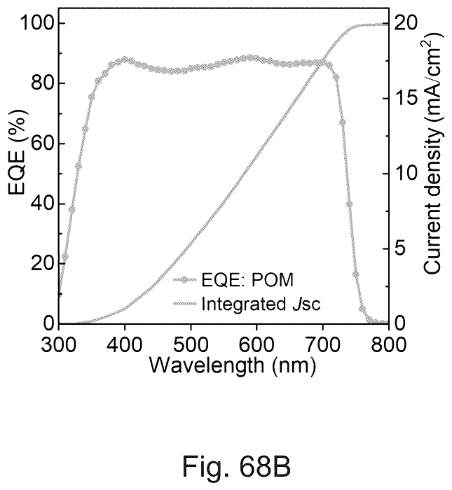

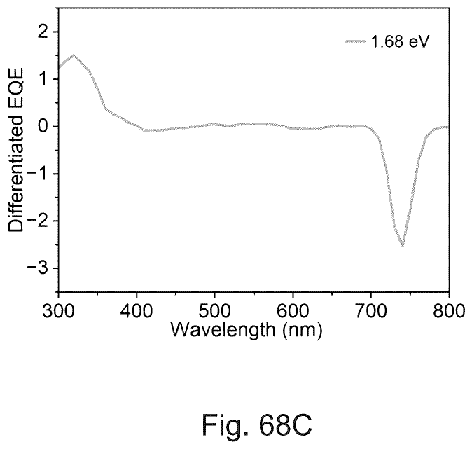

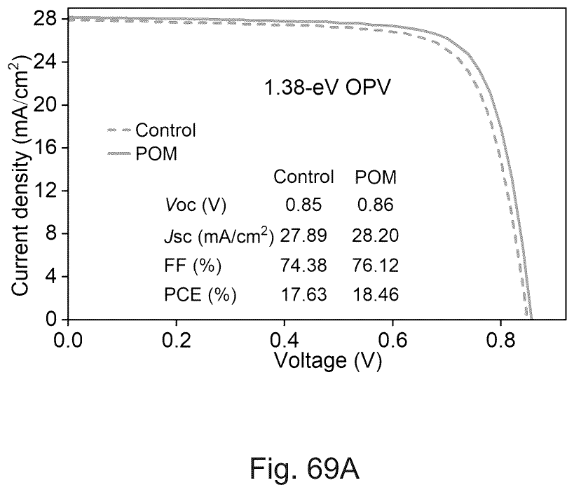

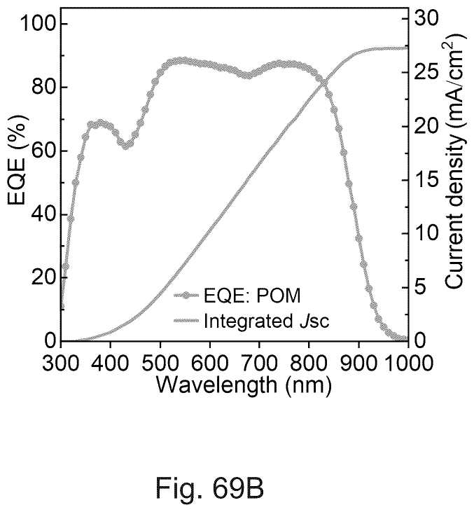

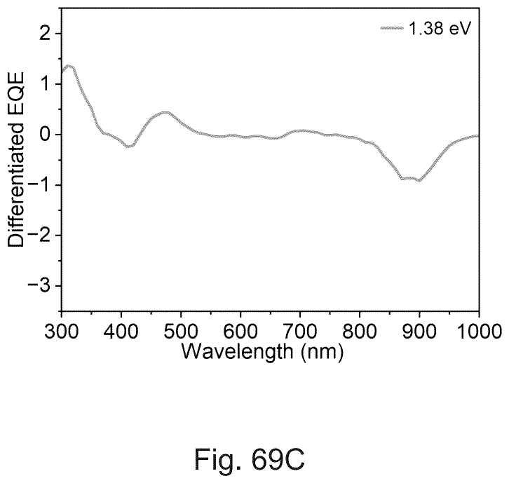

In light of the positive effects of POMs in defect passivation and structural stabilization of the [PbI₆]⁴⁻ unit in perovskite structure, the application of POMs to wide-bandgap (WBG) perovskite films (1.68 and 1.78 eV) has been investigated. Single-junction WBG PSCs were subsequently fabricated. The POM-based devices exhibited higher PCEs than the control case, achieving PCEs of 21.82% and 19.75%, respectively (FIGS. 67A to 67C and 68A to 68C). It is believed that the incorporation of POM may induce p-doping in polymer donor within organic solar cells (OSCs) to increase hole extraction. Without wishing to be bound by theory, an OSC featuring a PM6:BTP-eC9 active layer, a SAM/POM (H₃PW₁₂O₄₀ was utilized) charge-selective layer, and a PNDIT-F3N electron-transporting layer was fabricated, which was found to have a PCE of 18.46% (FIGS. 69A to 69C).

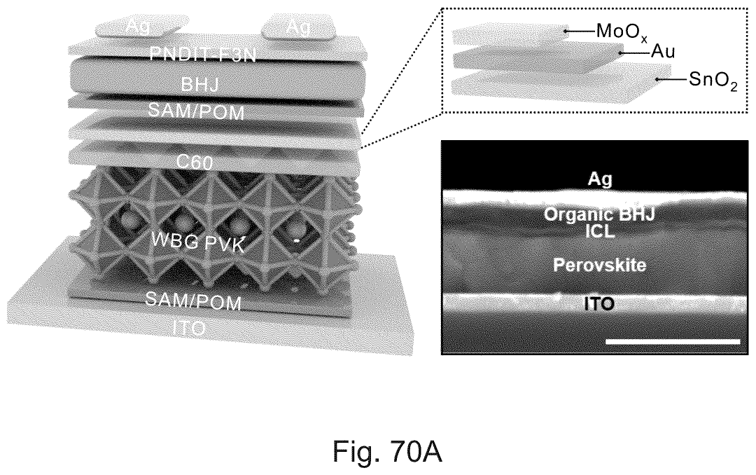

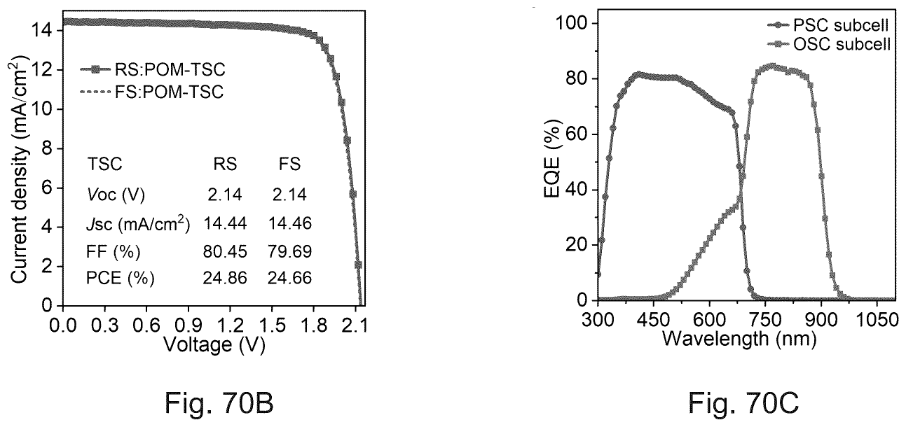

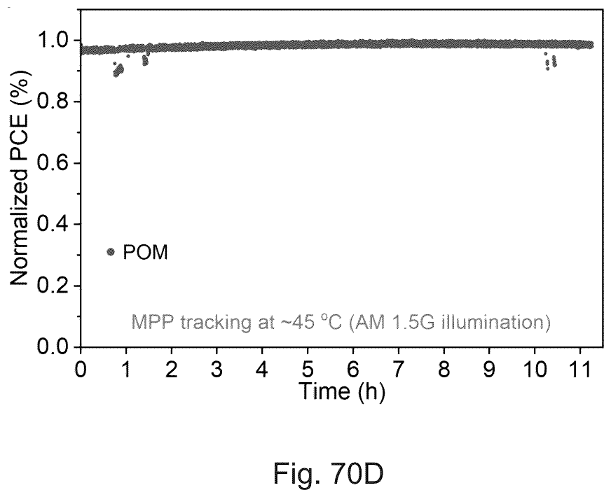

Given POM's effectiveness in enhancing both PSCs and OSCs, it was also applied in the fabrication of perovskite/organic tandem solar cell (PO-TSC). To optimize photon utilization and current matching between the two subcells, a 1.78-eV perovskite active layer was utilized as the bottom (sub)cell, while a 1.38-eV organic active layer served as the top (sub)cell (FIG. 70A). The PO-TSC achieved a remarkable PCE of 24.86% with matched current density between the perovskite and organic subcells (FIGS. 70B and 70C). Moreover, the unencapsulated PO-TSC could maintain 98% of its initial PCE after 11 hours of continuous operation under one-sun illumination at ˜45° C. in an N₂-filled atmosphere (FIG. 70D).

The invention has been given by way of example only, and various other modifications of and/or alterations to the described embodiment may be made by persons skilled in the art without departing from the scope of the invention as specified in the appended claims.

1. A perovskite-containing structure for use as a photoactive layer in a solar cell comprising a halide perovskite structure and a polyoxometalate (POM) cluster arranged to stabilize the halide perovskite structure; wherein the POM cluster includes an ammonium compound having a formula selected from the group consisting of: 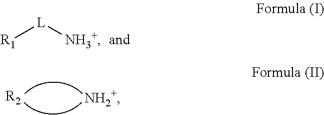
wherein:
R₁ is selected from the group consisting of a hydrogen, an ammonium cation and a halogen;
L is an aliphatic alkyl or an aromatic linker structure having 1 to 26 carbons;
R₂ is selected from the group consisting of amine, substituted or unsubstituted methylene and nitrenium cation; and
the ring in Formula (II) represents an aliphatic 6-membraned to 8-membraned ring, including the R₂ and NH₂⁺.

2. The perovskite-containing structure as claimed in claim 1, wherein:
R₁ is selected from the group consisting of a hydrogen, an ammonium cation, F, Br, Cl, and I;
L has a structure of 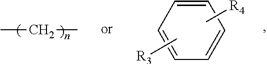
wherein R₃ and R₄ each independently being a point of attachment for Ri or NH₃⁺, and each of the R₃ and R₄ has a structure of 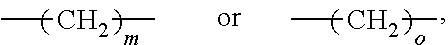
and wherein n is an integer of 1 to 12, m and o each independently being an integer of 0 to 12;
R₂ is selected from the group consisting of amine and nitrenium cation; and
the ring in Formula (II) represents an aliphatic 6-membraned ring, including the substituent R₂ and NH₂⁺.

3. The perovskite-containing structure as claimed in claim 1, wherein the ammonium compound has a formula selected from the group consisting of: 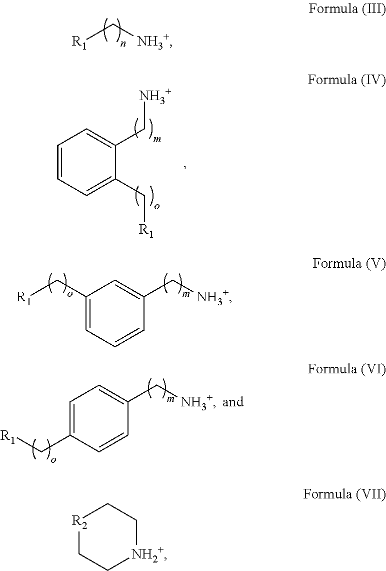
wherein:
R₁ is selected from the group consisting of a hydrogen, an ammonium cation, F, Br, Cl, and I;
n is an integer of 1 to 10; m and o each independently being an integer of 0 to 10; and
R₂ is selected from the group consisting of amine and nitrenium cation.

4. The perovskite-containing structure as claimed in claim 1, wherein the ammonium compound is selected from the group consisting of:

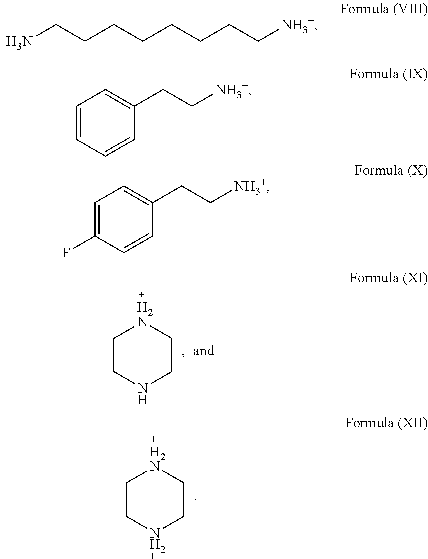

5. The perovskite-containing structure as claimed in claim 1, wherein the POM cluster is a Keggin-type POM or a Dawson-type POM.

6. The perovskite-containing structure as claimed in claim 5, wherein the Keggin-type POM has a formula of (X)ₐ(YMₙM′₁₂₋ₙO₄₀)^{b}, and wherein X is a cation with a charge of +1 or +2 and is selected from one or more of the ammonium compound of Formula (VIII) to Formula (XII), or a combination of H⁺ and one or more of the ammonium compound of Formula (VIII) to Formula (XII); a is a positive integer of 2 to 4, b is a negative integer of (−2) to (−4), and a+b=0; Y is selected from the group consisting of Si and P; M and M′ are selected from the group consisting of W and Mo; and n is 0-12.

7. The perovskite-containing structure as claimed in claim 5, wherein the Dawson-type POM has a formula of (X)_{c}(Y₂M_{n′}M′_{18-n′}O₆₂)^{d}, and wherein X is a cation with a charge of +1 or +2 and is selected from one or more of the ammonium compound of Formula (VIII) to Formula (XII), or a combination of H⁺ and one or more of the ammonium compound of Formula (VIII) to Formula (XII); c is a positive integer of 3 to 8, b is a negative integer of (−3) to (−8), and a+b=0; Y is selected from the group consisting of Si and P; M and M′ are selected from the group consisting of W and Mo; and n′ is 0-18.

8. The perovskite-containing structure as claimed in claim 6, wherein the Keggin-type POM has a formula of (X)₃(PW₁₂O₄₀)³⁻ or (X)₄(SiW₁₂O₄₀)⁴⁻, and wherein X is a cation with a charge of +1 or +2 and is selected from one or more of the ammonium compound of Formula (VIII) to Formula (XII), or a combination of H⁺ and one or more of the ammonium compound of Formula (VIII) to Formula (XII).

9. The perovskite-containing structure as claimed in claim 8, wherein the Keggin-type POM has a formula selected from the group consisting of (PP)₃PW₁₂O₄₀, H(PPD)PW₁₂O₄₀, (PEA)₃PW₁₂O₄₀, (4F-PEA)₃PW₁₂O₄₀, H(ODA)PW₁₂O₄₀, and (PPD)₂SiW₁₂O₄₀.

10. The perovskite-containing structure as claimed in claim 1, wherein the halide perovskite structure has a general formula of ABZ₃, with A being an A-site monovalent cation, B being a B-site divalent cation, and Z being a halide anion.

11. The perovskite-containing structure as claimed in claim 10, wherein the halide perovskite structure has a formula selected from Cs_{0.05}FA_{0.95}PbI₃ and FA_{0.8}MA_{0.1}Cs_{0.1}Pb(I_{0.6}Br_{0.4})₃.

12. The perovskite-containing structure as claimed in claim 1 comprising about 0.01 mol % to about 0.03 mol % of the POM cluster.

13. The perovskite-containing structure as claimed in claim 1, wherein the POM cluster is adapted to form an interlayer by way of interaction with the halide perovskite structure.

14. The perovskite-containing structure as claimed in claim 1, wherein the POM cluster is distributed within the layer of the halide perovskite structure.

15. A method for preparing the perovskite-containing structure as claimed in claim 1, comprising the steps of:
(a) providing a first solution containing a POM cluster including an ammonium compound having a formula selected from the group consisting of: 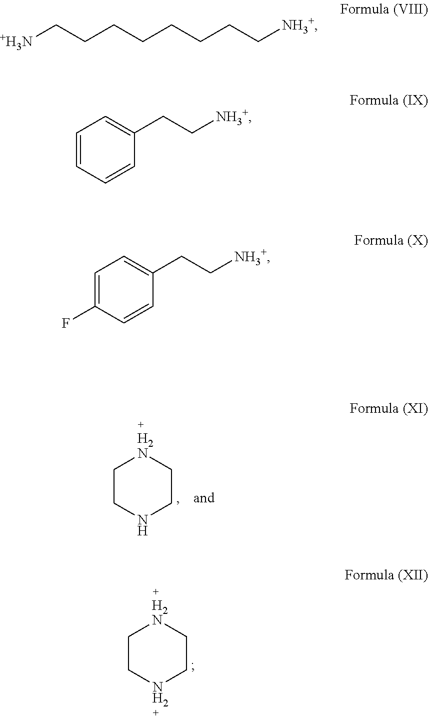
(b) providing a halide perovskite precursor solution comprising halides of formamidinium, methylammonium, cesium, and lead;
(c) spin-coating the first solution and the halide perovskite precursor solution on a substrate; and
(d) annealing the spin-coated solutions to form the perovskite-containing structure.

16. The method as claimed in claim 15, wherein step (a) is carried out by cation substitution of a precursor POM cluster with an ammonium salt corresponding to the ammonium compound.

17. The method as claimed in claim 16, wherein the precursor POM cluster is selected from H₃PW₁₂O₄₀ and H₄SiW₁₂O₄₀.

18. The method as claimed in claim 17, wherein the ammonium salt is selected from the group consisting of PI, PDAI₂, PEAI, 4F-PEAI, and ODAI₂.

19. The method as claimed in claim 16, wherein the precursor POM cluster and the ammonium salt have a molar ratio from about 1:1 to about 1:4.

20. The method as claimed in claim 15, wherein the first solution contains about 0.05 mg/mL to about 5 mg/mL of the POM cluster.

21. The method as claimed in claim 15, wherein the halides in step (b) comprise CsI, FAI, MAI, PbI₂, and PbBr₂, and are provided in accordance with a formula Cs_{0.05}FA_{0.95}PbI₃ or FA_{0.8}MA_{0.1}Cs_{0.1}Pb(I_{0.6}Br_{0.4})₃.

22. The method as claimed in claim 15, wherein the first solution and the halide perovskite precursor solution in step (c) are sequentially spin-coated on the substrate.

23. A solar cell comprising:
a hole transport layer;
an electron transport layer; and
a perovskite-containing structure disposed between the hole transport layer and the electron transport layer;
wherein the perovskite-containing structure includes a halide perovskite structure; and a polyoxometalate (POM) cluster which includes an ammonium compound having a formula selected from the group consisting of: 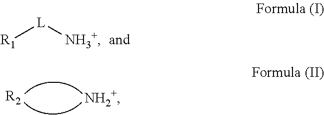
wherein:
R₁ is selected from the group consisting of a hydrogen, an ammonium cation and a halogen;
L is an aliphatic alkyl or an aromatic linker structure having 1 to 26 carbons;
R₂ is selected from the group consisting of amine, substituted or unsubstituted methylene and nitrenium cation;
the ring in Formula (II) represents an aliphatic 6-membraned to 8-membraned ring, including the R₂ and NH₂⁺.

24. The solar cell as claimed in claim 23, wherein the POM cluster is disposed between the halide perovskite structure and the hole transport layer.

25. The solar cell as claimed in claim 23, wherein the perovskite-containing structure comprises the POM cluster dispersed within the halide perovskite structure, the perovskite-containing structure is disposed on the hole transport layer.

26. The solar cell as claimed in claim 25, wherein the hole transport layer is in contact with an additional POM cluster, said additional POM cluster is in the form of a layer disposed between the perovskite-containing structure and the hole transport layer.

27. The solar cell as claimed in claim 23 further comprising a transparent conductive layer in contact with both a transparent substrate and the hole transport layer; a metal layer and a blocking layer arranged sequentially with the electron transport layer.

28. The solar cell as claimed in claim 27, wherein the transparent substrate is selected from the group consisting of glass, PC (polycarbonate), PET (polyethylene glycol terephthalate), PEN (polyethylene naphthalate), PA (polyamide), PMMA (polymethyl methacrylate), PS (polystyrene), ABS (acrylonitrile butadiene styrene copolymer), PDMS (polydimethylsiloxane), and a combination thereof.

29. The solar cell as claimed in claim 27, wherein the transparent conductive layer is selected from the group consisting of Indium Tin Oxide (ITO), Aluminum Zinc Oxide (AZO), graphene, PH1000 poly(3,4-ethylenedioxythiophene):poly(styrene sulfonate) (PH1000 PEDOT:PSS), Ag nanowire and a combination thereof.

30. The solar cell as claimed in claim 27, wherein the hole transport layer is a self-assembled monolayer (SAM) of CbzNaph or Me-4PACZ.

31. The solar cell as claimed in claim 23, wherein the electron transport layer is selected from the group consisting of C₆₀, and its derivatives; the blocking layer is selected from the group consisting of bathocuproine (BCP), SnO₂, and MoOₓ.

32. The solar cell as claimed in claim 27, wherein the metal layer is selected from the group consisting of Ag, Cu, Au, Al, Pt and a combination thereof.

33. The solar cell as claimed in claim 27 is configured as a subcell that is arranged in contact with an additional subcell, thereby forming a tandem structure.

34. The solar cell as claimed in claim 33, wherein the additional subcell comprises:
a hole transport layer;
an electron transport layer; and
an organic photovoltaic material disposed between the hole transport layer and the electron transport layer of the additional subcell.

35. The solar cell as claimed in claim 34, wherein the hole transport layer of the additional subcell is in contact with an additional POM cluster.

36. The solar cell as claimed in claim 34, wherein the organic photovoltaic material comprises PM6:BTP-eC9; the electron transport layer comprises PNDIT-F3N.

37. The solar cell as claimed in claim 33, wherein the subcell and the additional subcell have a bandgap of about 1.78 eV and about 1.38, respectively.
